(19) United States
(12) Patent Application Publication
(10) Pub. No.: US 2012/0268978 A1
(43) Pub. Date: Oct. 25, 2012

(54) SEMICONDUCTOR MEMORY DEVICE IN WHICH CAPACITANCE BETWEEN BIT LINES IS REDUCED, AND METHOD OF MANUFACTURING THE SAME

(76) Inventor: Noboru SHIBATA, Kawasaki-shi (JP)

(21) Appl. No.: 13/538,797

(22) Filed: Jun. 29, 2012

Related U.S. Application Data
(63) Continuation-in-part of application No. 13/218,723, filed on Aug. 26, 2011.

(30) Foreign Application Priority Data
Feb. 4, 2011 (JP) 2011-023214
Nov. 11, 2011 (JP) 2011-247803
Feb. 3, 2012 (JP) 2012-022289

(51) Int. Cl. G11C 5/06; H01L 21/336

(52) U.S. Cl. 365/63; 438/270; 257/E21.41

(57) ABSTRACT

According to one embodiment, a semiconductor memory device includes a plurality of memory cells arranged in a matrix, a plurality of word lines for selecting a plurality of memory cells, and a plurality of bit lines for selecting a plurality of memory cells. Of the plurality of bit lines, first bit lines and second bit lines are arranged in different layers.

### CROSS REFERENCE TO RELATED APPLICATIONS

This application is a Continuation-in-Part Application of U.S. patent application Ser. No. 13/218,723, filed Aug. 26, 2011 and based upon and claiming the benefit of priority from prior Japanese Patent Applications No. 2011-023214, filed Feb. 4, 2011; No. 2011-247803, filed Nov. 11, 2011; and No. 2012-022289, filed Feb. 3, 2012, the entire contents of all of which are incorporated herein by reference.

### FIELD

Embodiments described herein relate generally to a semiconductor memory device, e.g., a NAND flash memory.

### BACKGROUND

In a NAND flash memory, all or half of a plurality of memory cells arranged in the row direction are connected to a plurality of bit lines. These bit lines are connected to a plurality of latch circuits for write and read to data of the memory cell. A write or read operation is performed at once for all or half of the memory cells arranged in the row direction.

Also, in a NAND flash memory, the number of cells connected to one bit line is increased as the capacity increases. In this case, the length of the bit line increases, the capacitance between the bit lines increases, and the CR time constant undesirably increases.

### BRIEF DESCRIPTION OF THE DRAWINGS

FIG. 1 is a block diagram schematically showing an example of a NAND flash memory applied to an embodiment;

FIG. 2 is a circuit diagram schematically showing the arrangement of a part of FIG. 1;

FIG. 3 is a circuit diagram schematically showing the arrangement of the part of FIG. 1, as an example different from that shown in FIG. 2;

FIGS. 4A and 4B are sectional views showing a memory cell and selection transistor;

FIG. 5 is a sectional view showing the NAND flash memory;

FIG. 6 is a view showing examples of voltages to be applied to individual regions shown in FIG. 5;

FIG. 7 is a circuit diagram showing an example of a data storage circuit shown in FIGS. 2 and 3;

FIGS. 8A, 8B, and 8C are views showing the relationship between data and a threshold voltage when storing two-bit data in a memory cell;

FIG. 9 is a flowchart showing the programming operation of the first page;

FIG. 10 is a flowchart showing the programming operation of the second page;

FIG. 11A is an exploded view of a semiconductor memory device according to the first embodiment, and FIG. 11B is a sectional view of FIG. 11A;

FIG. 12 is a plan view showing the floor plan of the semiconductor memory device according to the first embodiment;

FIG. 13 is a plan view showing the floor plan of a general semiconductor memory device;

FIG. 14 is a sectional view schematically showing the relationship between bit lines BLO and BLE and contacts shown in FIGS. 11A and 11B;

FIG. 15 is a sectional view schematically showing the first modification of FIG. 14;

FIG. 16 is a sectional view schematically showing the second modification of FIG. 14;

FIG. 17A is an exploded view of a semiconductor memory device according to the second embodiment, and FIG. 17B is a sectional view of FIG. 17A;

FIG. 18 is a sectional view schematically showing the relationship between bit lines BLO and BLE and contacts in the second embodiment;

FIG. 19 is a sectional view schematically showing the first modification of FIG. 18;

FIG. 20 is a sectional view schematically showing the second modification of FIG. 18;

FIGS. 21A, 21B, 21C, 21D, 21E, 21F, 21G, 21H, 21I, and 21J are sectional views schematically showing a method of manufacturing the semiconductor memory devices according to the first and second embodiments;

FIG. 22 is a sectional view schematically showing a modification of FIGS. 14, 15, and 16;

FIG. 23 is a sectional view schematically showing a modification of FIGS. 14, 15, and 16;

FIG. 24 is a sectional view schematically showing a modification of FIGS. 18, 19, and 20;

FIG. 25 is a sectional view schematically showing a modification of FIGS. 18, 19, and 20;

FIG. 26 is a sectional view schematically showing a modification of FIGS. 24 and 25;

FIG. 27 is a sectional view schematically showing a modification of FIGS. 24 and 25;

FIG. 28 is a sectional view schematically showing a modification of FIGS. 24 and 25;

FIG. 29 is a circuit diagram showing a modification of FIG. 3;

FIG. 30A is an exploded view of a semiconductor memory device according to the third embodiment, and FIG. 30B is a sectional view of FIG. 30A;

FIG. 31 is an exemplary sectional view showing the relationship between bit lines BLO and BLE and contacts in the third embodiment;

FIG. 32 is a sectional view showing the first modification of FIG. 31;

FIG. 33 is a sectional view showing the second modification of FIG. 31;

FIG. 34 is a sectional view showing the third modification of FIG. 31;

FIG. 35 is a sectional view showing the fourth modification of FIG. 31;

FIG. 36A is an exploded view of a semiconductor memory device according to the fourth embodiment, and FIG. 36B is a sectional view of FIG. 36A;

FIG. 37 is an exemplary sectional view showing the relationship between bit lines BLO and BLE and contacts in the fourth embodiment;

FIG. 38 is a sectional view showing the first modification of FIG. 37;

FIG. 39 is a sectional view showing the second modification of FIG. 37;

FIG. 40 is a sectional view showing the fifth embodiment;

FIG. 41 is an exemplary sectional view showing the relationship between bit lines BLO and BLE and contacts in the fifth embodiment;

FIG. 42 is an exploded view showing the sixth embodiment;

FIG. 43 is a sectional view showing the sixth embodiment;

FIG. 44 is an exemplary sectional view showing the relationship between bit lines BLO and BLE and contacts in the sixth embodiment;

FIG. 45 is a sectional view showing a modification of the sixth embodiment;

FIG. 46 is an exemplary sectional view showing the relationship between bit lines BLO and BLE and contacts in the modification of the sixth embodiment;

FIG. 47 is an exploded view showing the seventh embodiment;

FIG. 48 is a sectional view showing the seventh embodiment;

FIG. 49 is an exemplary sectional view showing the relationship between bit lines BLO and contacts in the seventh embodiment;

FIG. 50 is a sectional view showing the first modification of FIG. 49;

FIG. 51 is a sectional view showing the second modification of FIG. 49;

FIG. 52 is a sectional view showing the third modification of FIG. 49;

FIG. 53 is a sectional view showing the fourth modification of FIG. 49;

FIG. 54 is an exemplary sectional view showing the relationship between bit lines BLE and contacts in the seventh embodiment;

FIG. 55 is a sectional view showing the first modification of FIG. 54;

FIG. 56 is a sectional view showing the second modification of FIG. 54;

FIG. 57 is a sectional view showing the third modification of FIG. 54;

FIG. 58 is a sectional view showing the fourth modification of FIG. 54;

FIG. 59 is an exploded view showing the eighth embodiment;

FIG. 60 is a sectional view showing the eighth embodiment;

FIG. 61 is an exploded view showing the ninth embodiment;

FIG. 62 is a sectional view showing the ninth embodiment;

FIG. 63 is a circuit diagram showing a modification of FIG. 2;

FIG. 64 is a circuit diagram showing a modification of FIG. 2;

FIG. 65 is a circuit diagram showing a modification of FIG. 2;

FIGS. 66A, 66B, and 66C are views showing a method of manufacturing the bit line structure shown in FIGS. 30A and 30B;

FIGS. 67A, 67B, 67C, and 67D are views showing another method of manufacturing the bit line structure shown in FIGS. 30A and 30B;

FIG. 68 is an exploded view showing the 10th embodiment;

FIG. 69 is a sectional view showing the 10th embodiment;

FIGS. 70A and 70B are a timing chart showing the peak currents of bit lines according to the 10th embodiment;

FIGS. 71A and 71B are a timing chart showing the charge timings of bit lines according to the 10th embodiment;

FIG. 72 is an exemplary sectional view showing the relationship between bit lines BLO and contacts in the 10th Embodiment;

FIG. 73 is a sectional view showing the first modification of FIG. 72;

FIG. 74 is a sectional view showing the second modification of FIG. 72;

FIG. 75 is a sectional view showing the third modification of FIG. 72;

FIG. 76 is an exemplary sectional view showing the relationship between bit lines BLE and contacts in the 10th Embodiment;

FIG. 77 is a sectional view showing the first modification of FIG. 76;

FIG. 78 is a sectional view showing the second modification of FIG. 76;

FIG. 79 is a sectional view showing the third modification of FIG. 76;

FIG. 80 is an exploded view showing the 11th embodiment;

FIG. 81 is a sectional view showing the 11th embodiment;

FIG. 82 is an exemplary sectional view showing the relationship between bit lines BLO and contacts in the 11th Embodiment;

FIG. 83 is a sectional view showing the first modification of FIG. 82;

FIG. 84 is a sectional view showing the second modification of FIG. 82;

FIG. 85 is a sectional view showing the third modification of FIG. 82;

FIG. 86 is an exemplary plan view showing the 12th embodiment;

FIG. 87 is an exploded view showing the 13th embodiment;

FIG. 88 is a sectional view taken along a line A-A in FIG. 87;

FIG. 89 is a sectional view taken along a line B-B in FIG. 87;

FIG. 90 is a sectional view taken along a line C-C in FIG. 87;

FIG. 91 is a sectional view taken along a line D-D in FIG. 87;

FIG. 92 is an exploded view showing the 14th embodiment;

FIG. 93 is a sectional view taken along a line A-A in FIG. 92;

FIG. 94 is a sectional view taken along a line B-B in FIG. 92;

FIG. 95 is a sectional view taken along a line C-C in FIG. 92;

FIG. 96 is a sectional view taken along a line D-D in FIG. 92;

FIG. 97 is a sectional view showing the 16th embodiment;

FIG. 98 is a sectional view showing the 17th embodiment; and

FIG. 99 is an exemplary plan view showing the 18th embodiment.

### DETAILED DESCRIPTION

In general, according to one embodiment, a semiconductor memory device includes a plurality of memory cells arranged in a matrix, a plurality of word lines for selecting a plurality of memory cells, and a plurality of bit lines for selecting a plurality of memory cells. Of the plurality of bit lines, first bit lines and second bit lines are arranged in different layers.

An embodiment will be explained below with reference to the accompanying drawing.

In this embodiment, adjacent bit lines are formed in different interconnection layers in order to reduce the capacitance between the bit lines.

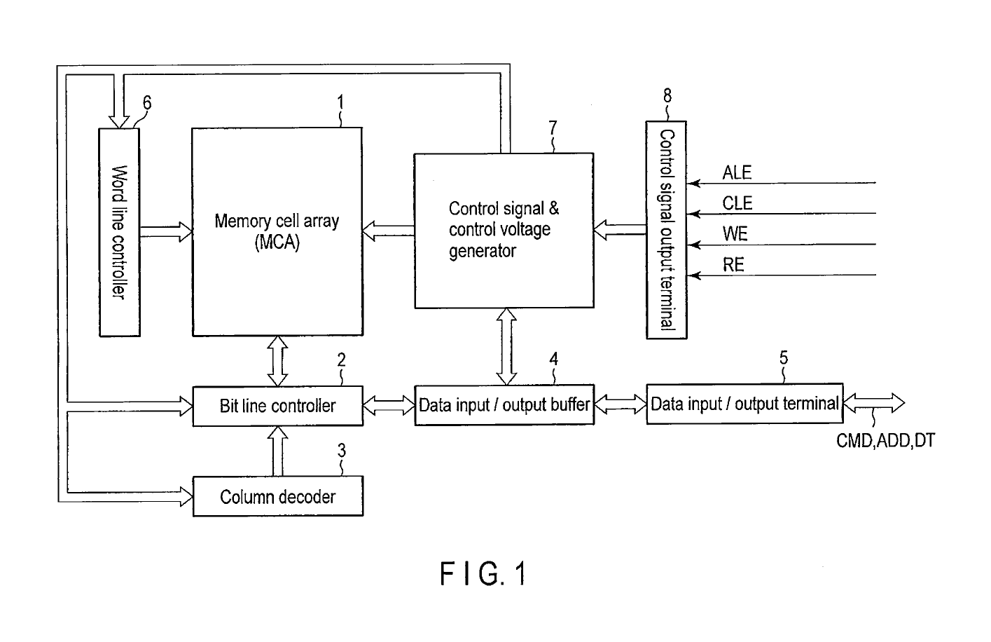

FIG. 1 shows an outline of the arrangement of a NAND flash memory for storing, e.g., two-bit quaternary data according to this embodiment.

A memory cell array 1 includes a plurality of bit lines, a plurality of word lines, a common source line, and electrically programmable memory cells such as EEPROM cells arranged in a matrix. The memory cell array 1 is connected to a bit line controller 2 for controlling the bit lines and a word line controller 6.

The bit line controller 2 reads out data from a memory cell in the memory cell array 1 via a bit line, detects the state of a memory cell in the memory cell array 1 via a bit line, and writes data in a memory cell in the memory cell array by applying a write control voltage to the memory cell via a bit line. The bit line controller 2 is connected to a column decoder 3 and data input/output buffer 4. The column decoder 3 selects an internal data storage circuit of the bit line controller 2. Memory cell data read out to the data storage circuit is output outside from a data input/output terminal 5 via the data input/output buffer 4. Various commands CMD for controlling the operation of the NAND flash memory, an address ADD, and data DT, all of which are externally supplied, are input to the data input/output terminal 5. Write data input to the data input/output terminal 5 is supplied to a data storage circuit selected by the column decoder 3 via the data input/output buffer 4, and commands and addresses are supplied to a control signal & control voltage generator 7.

The word line controller 6 is connected to the memory cell array 1. The word line controller 6 selects a word line in the memory cell array 1, and applies a voltage necessary for read, write, or erase to the selected word line.

The memory cell array 1, bit line controller 2, column decoder 3, data input/output buffer 4, and word line controller 6 are connected to the control signal & control voltage generator 7, and controlled by the control signal & control voltage generator 7. The control signal & control voltage generator 7 is connected a control signal input terminal 8, and controlled by control signals address latch enable (ALE), command latch enable (CLE), write enable (WE), and read enable (RW) externally input via the control signal input terminal 8.

The bit line controller 2, column decoder 3, word line controller 6, and control signal & control voltage generator 7 form a write circuit and read circuit.

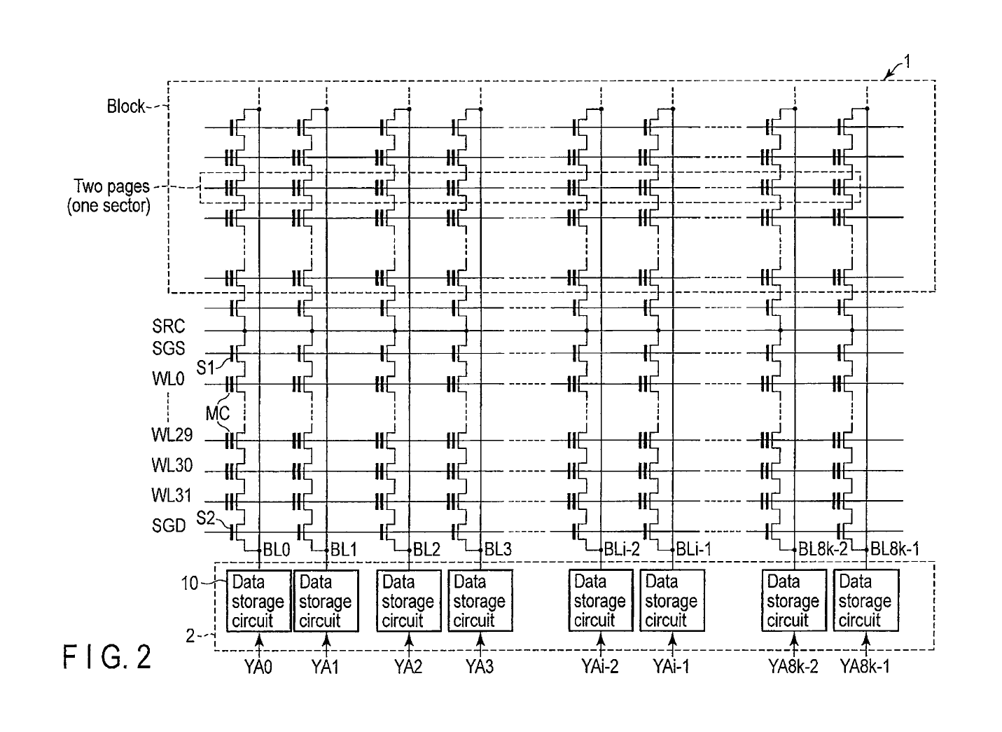

FIG. 2 shows an example of the configuration of the memory cell array 1 and bit line controller 2 shown in FIG. 1. A plurality of NAND cells are arranged in the memory cell array 1. Each NAND cell includes, e.g., 32 series-connected EEPROM memory cells MC, and select gates S1 and S2. The select gate S2 is connected to a bit line BL0e, and the select gate S1 is connected to a source line SRC. The control gates of the memory cells MC arranged in each row are connected together to a corresponding one of word lines WL0 to WL29, WL30, and WL31. Also, the select gates S2 are connected together to a select line SGD, and the select gates S1 are connected together to a select line SGS.

The bit line controller 2 includes a plurality of data storage circuits 10. Bit lines BL0, BL1, . . . , BLi−1, BLi, . . . , BLk−2, and BLk−1 are connected to corresponding data storage circuits 10.

The memory cell array 1 includes a plurality of blocks as indicated by the broken lines. Each block includes a plurality of NAND cells, and data is erased for, e.g., each block. Also, an erase operation is performed for bit lines connected to the data storage circuits 10 at once.

Furthermore, a plurality of memory cells connected to each word line (i.e., memory cells within the range enclosed by the broken lines) form a sector. Data is written in and read out from each sector. That is, the write or read operation is executed for all memory cells arranged in the row direction.

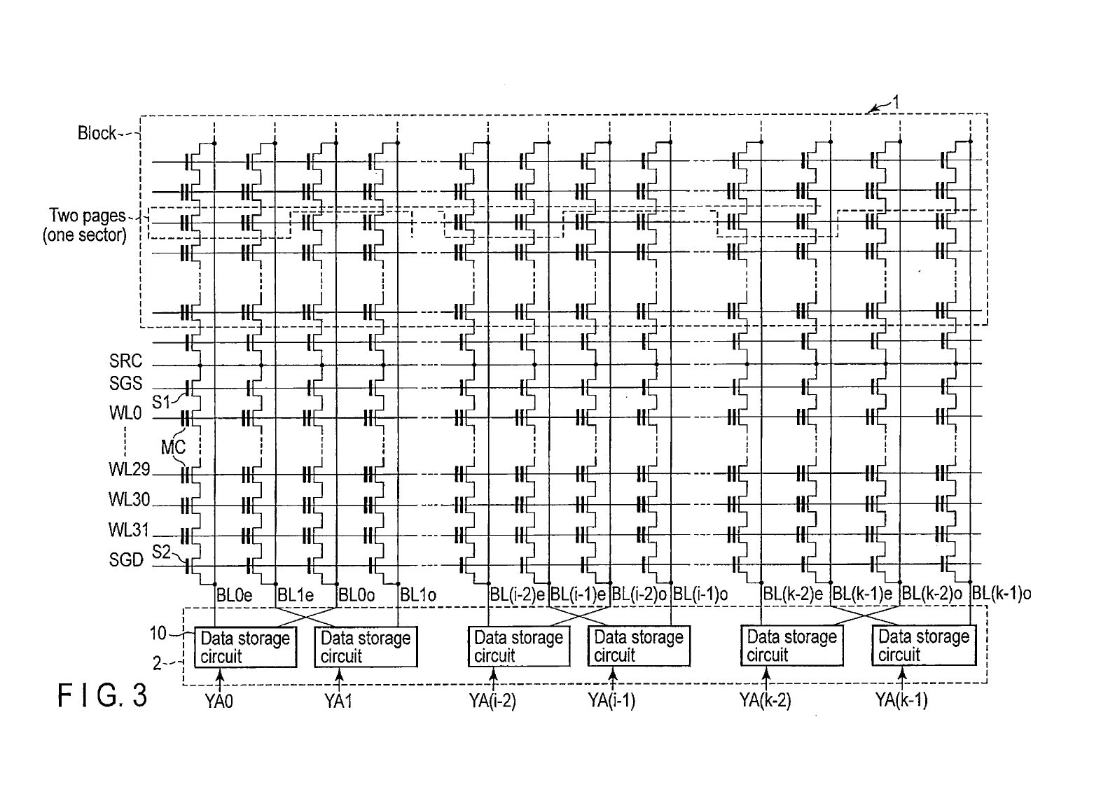

FIG. 3 shows an arrangement in which half of a plurality of memory cells arranged in the row direction are connected to one data storage circuit 10 via a bit line in read and programming. When half bit lines are connected to one data storage circuit, BL(i−2)e, BL(i−2)o, BLie, BLio, . . . , (even-numbered bit lines) and BL(i−3)e, BL(i−3)o, BL(i−1)e, BL(i−1)o, . . . , (odd-numbered bit lines) are arranged in different layers, the even-numbered bit lines are arranged in the same layer, and the odd-numbered bit lines are arranged in the same layer. Therefore, the bit lines BL(i−2)e and BL(i−2)o arranged in the same layer are connected to one data storage circuit 10, and the bit lines BL(i−1)e and BL(i−1)o arranged in the same layer are connected to one data storage circuit 10.

BL0e, BL1e, BL2e, BL3e, . . . , BL(i−2)e, BL(i−1)e, . . . are selected as one page, and BL0o, BL1o, BL2o, BL3o, . . . , BL(i−2)o, BL(i−1)o, . . . are selected as another page. In this configuration, adjacent bit lines in the same layer are shielded.

In a read operation, program verify operation, and programming operation, one of two bit lines (BL0e and BL0o, . . . , BL(i−2)e and BL(i−2)o, BL(i−1)e and BL(i−1)o, . . . , BL(k−1)e and BL(k−1)o) connected to each data storage circuit 10 is selected in accordance with an externally supplied address signal. In addition, one word line is selected in accordance with the external address, and two pages (one sector) indicated by the broken lines are selected. These two pages are switched by the address.

As another example of the arrangement in which half bit lines are connected to one data storage circuit, BL(i−2)e, BL(i−1)e, BLie, . . . shown in FIG. 3 are arranged in the first layer, and BL(i−2)o, BL(i−1)o, BLio, . . . shown in FIG. 3 are arranged in the second layer different from the first layer. When the bit lines in the first layer are selected, the bit lines in the second layer are unselected; when the bit lines in the second layer are selected, the bit lines in the first layer are unselected. Although adjacent bit lines on the same layer are selected or unselected together, bit lines in vertically adjacent layers can be shielded from each other.

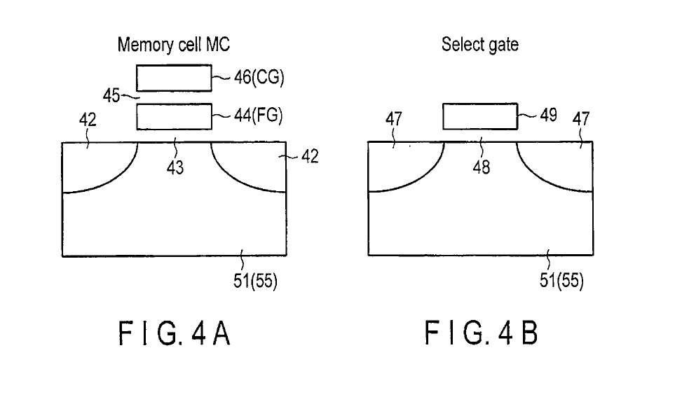

FIGS. 4A and 4B are sectional views of the memory cell and selection transistor. FIG. 4A shows the memory cell. N-type diffusion layers 42 as the source and drain of the memory cell are formed in a substrate 51 (a p-type well region 55 to be described later). A floating gate (FG) 44 is formed on an insulating film 43 on the p-type well region 55. A control gate (CG) 46 is formed on an insulating film 45 on the floating gate 44. FIG. 4B shows the select gate. N-type diffusion layers 47 as the source and drain are formed in the p-type well region 55. A control gate 49 is formed on a gate insulating film 48 on the p-type well region 55.

FIG. 5 is a sectional view of the NAND flash memory. N-type well regions 52, 53, and 54 and a p-type well region 56 are formed in, e.g., the p-type semiconductor substrate 51. The p-type well region 55 is formed in the n-type well region 52. Memory cells Tr forming the memory cell array 1 are formed in the p-type well region 55. In addition, a low-voltage p-channel transistor LVPTr and low-voltage n-channel transistor LVNTr forming the data storage circuit 10 are respectively formed in the n-type well region 53 and p-type well region 56. A high-voltage n-channel transistor HVNTr for connecting a bit line and the data storage circuit 10 is formed in the substrate 51. Also, a high-voltage p-channel transistor HVPTr forming, e.g., a word line driver is formed in the n-type well region 54. As shown in FIG. 5, the high-voltage transistors HVNTr and HVPTr have gate insulating films thicker than those of the low-voltage transistors LVNTr and LVPTr.

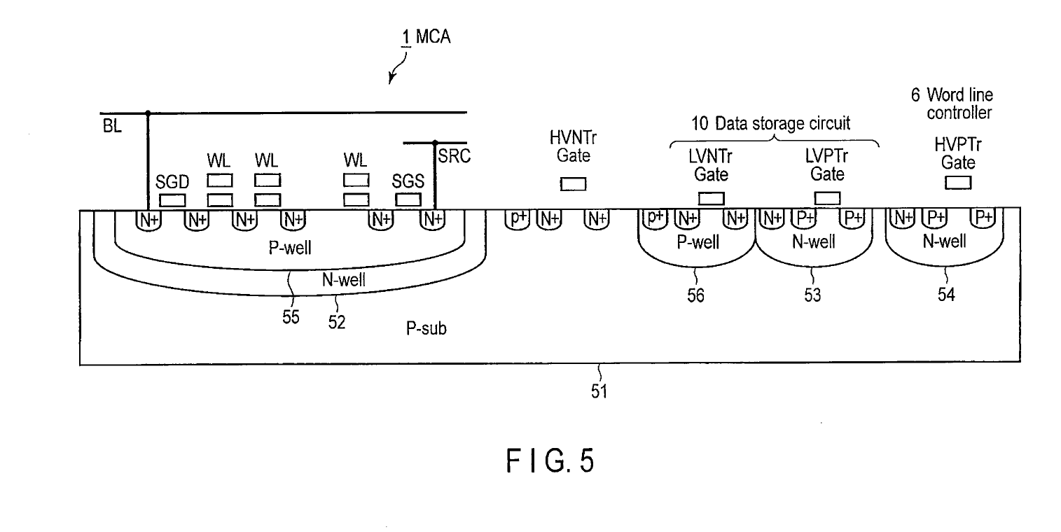

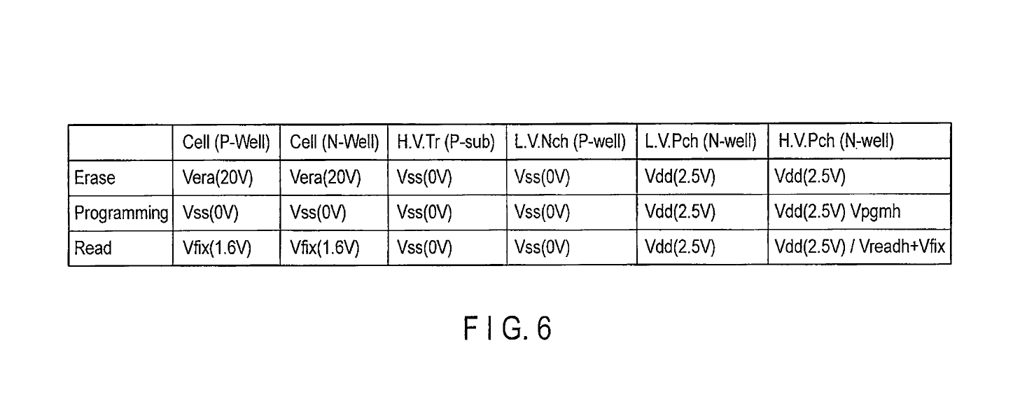

FIG. 6 shows examples of voltages to be applied to the individual regions shown in FIG. 5. In erase, programming, and read, the voltages as shown in FIG. 6 are applied to the individual regions. Vera is a voltage to be applied to the substrate when erasing data. Vss is a ground voltage. Vdd is a power supply voltage. Vpgmh is a voltage Vpgm+Vth to be applied to a word line when writing data. Vreadh is a voltage Vread+Vth to be applied to a word line when reading out data.

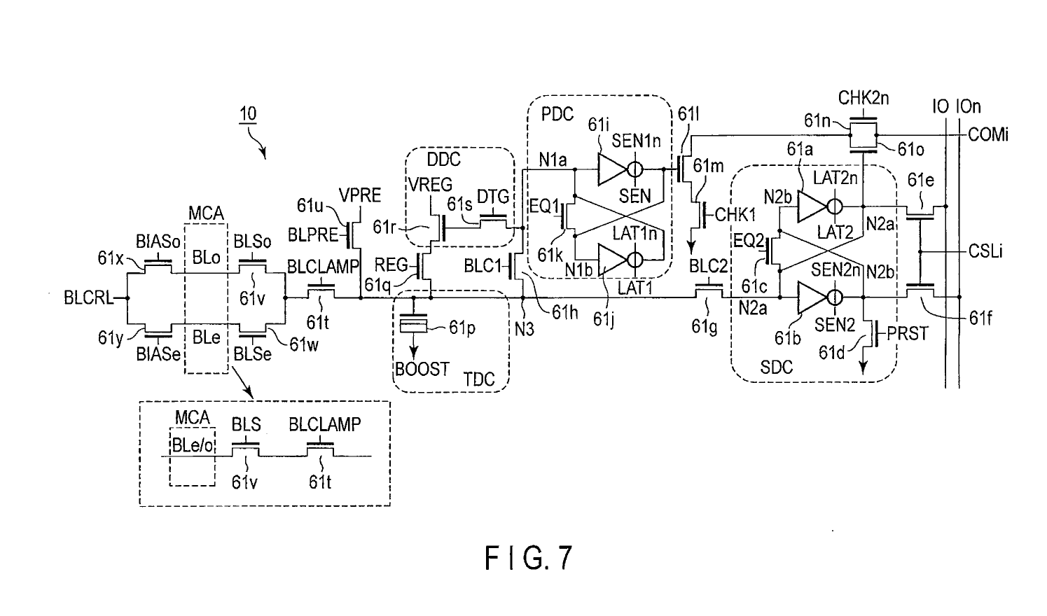

FIG. 7 is a circuit diagram showing an example of the data storage circuit 10 shown in FIG. 3.

The data storage circuit 10 includes a primary data cache (PDC), secondary data cache (SDC), dynamic data cache (DDC), and temporary data cache (TDC). The SDC, PDC, and DDC hold input data in a write operation, hold readout data in a read operation, temporarily hold data in a verify operation, and are used to manipulate internal data when storing multilevel data. The TDC amplifies and temporarily holds bit line data in data read, and is used to manipulate internal data when storing multilevel data.

The SDC includes clocked inverter circuits 61a and 61b forming a latch circuit, and transistors 61c and 61d. The transistor 61c is connected between the input terminal of the clocked inverter circuit 61a and the input terminal of the clocked inverter circuit 61b. A signal EQ2 is supplied to the gate of the transistor 61c. The transistor 61d is connected between the output terminal of the clocked inverter circuit 61b and ground. A signal PRST is supplied to the gate of the transistor 61d. A node N2a of the SDC is connected to an input/output data line IO via a column selection transistor 61e. A node N2b of the SDC is connected to an input/output data line IOn via a column selection transistor 61f. A column selection signal CSLi is supplied to the gates of the transistors 61e and 61f. The node N2a of the SDC is connected to a node N1a of the PDC via transistors 61g and 61h. A signal BLC2 is supplied to the gate of the transistor 61g. A signal BLC1 is supplied to the gate of the transistor 61h.

The PDC includes clocked inverter circuits 61i and 61j and a transistor 61k. The transistor 61k is connected between the input terminal of the clocked inverter circuit 61i and the input terminal of the clocked inverter circuit 61j. A signal EQ1 is supplied to the gate of the transistor 61k. A node N1b of the PDC is connected to the gate of a transistor 611. One end of the current path of the transistor 611 is grounded via a transistor 61m. A signal CHK1 is supplied to the gate of the transistor 61m. The other end of the current path of the transistor 611 is connected to one end of the current path of transistors 61n and 610 forming a transfer gate. A signal CHK2n is supplied to the gate of the transistor 61n. The gate of the transistor 610 is connected to the output terminal of the clocked inverter circuit 61a. A line COMi is connected to the other end of the current path of the transistors 61n and 610. The line COMi is a common line for all the data storage circuits 10. The potential of the line COMi changes to High level when verify of all the data storage circuits 10 is complete. That is, the node Nib of the PDC changes to Low level when verify is complete, as will be described later. When the signals CHK1 and CHK2n are changed to High level in this state, the potential of the line COMi changes to High level if verify is complete.

The TDC includes a MOS capacitor 61p. The capacitor 61p is connected between a connection node N3 of the transistors 61g and 61h and ground. The DDC is connected to the connection node N3 via a transistor 61q. A signal REG is supplied to the gate of the transistor 61q.

The DDC includes transistors 61r and 61s. A signal VREG is supplied to one end of the current path of the transistor 61r, and the other end of the current path is connected to the current path of the transistor 61q. The gate of the transistor 61r is connected to the node N1a of the PDC via the transistor 61s. A signal DTG is supplied to the gate of the transistor 61s.

Furthermore, one end of the current path of transistors 61t and 61u is connected to the connection node N3. A signal VPRE is supplied to the other end of the current path of the transistor 61u, and a signal BLPRE is supplied to the gate of the transistor 61u. A signal BLCLAMP is supplied to the gate of the transistor 61t. The other end of the current path of the transistor 61t is connected to one end of the bit line BLo via a transistor 61v, and connected to one end of the bit line BLe via a transistor 61w. The other end of the bit line BLo is connected to one end of the current path of a transistor 61x. A signal BIASo is supplied to the gate of the transistor 61x. The other end of the bit line BLe is connected to one end of the current path of a transistor 61y. A signal BIASe is supplied to the gate of the transistor 61y. A signal BLCRL is supplied to the other end of the current path of the transistors 61x and 61y. The transistors 61x and 61y are complementarily turned on with respect to the transistors 61v and 61w in accordance with the signals BIASo and BIASe, thereby supplying the potential of the signal BLCRL to an unselected bit line.

The control signal & control voltage generator 7 shown in FIG. 1 generates the above-mentioned signals and voltages, and controls the following operation.

The data storage circuit 10 shown in FIG. 2 has the same configuration as that shown in FIG. 7, except for the connection to a bit line. That is, as shown in FIG. 7, only the transistor 61v, for example, is connected to the other terminal of the transistor 61t, and the bit line BLe or BLo is connected via the transistor 61v.

This memory is a multilevel memory and can store two-bit data in one cell. Two bits are switched by addresses (first page and second page). When storing two bits in one cell, two pages are necessary. When storing three bits in one cell, the three bits are switched by addresses (first page, second page, and third page). When storing four bits in one cell, the four bits are switched by addresses (first page, second page, third page, and fourth page).

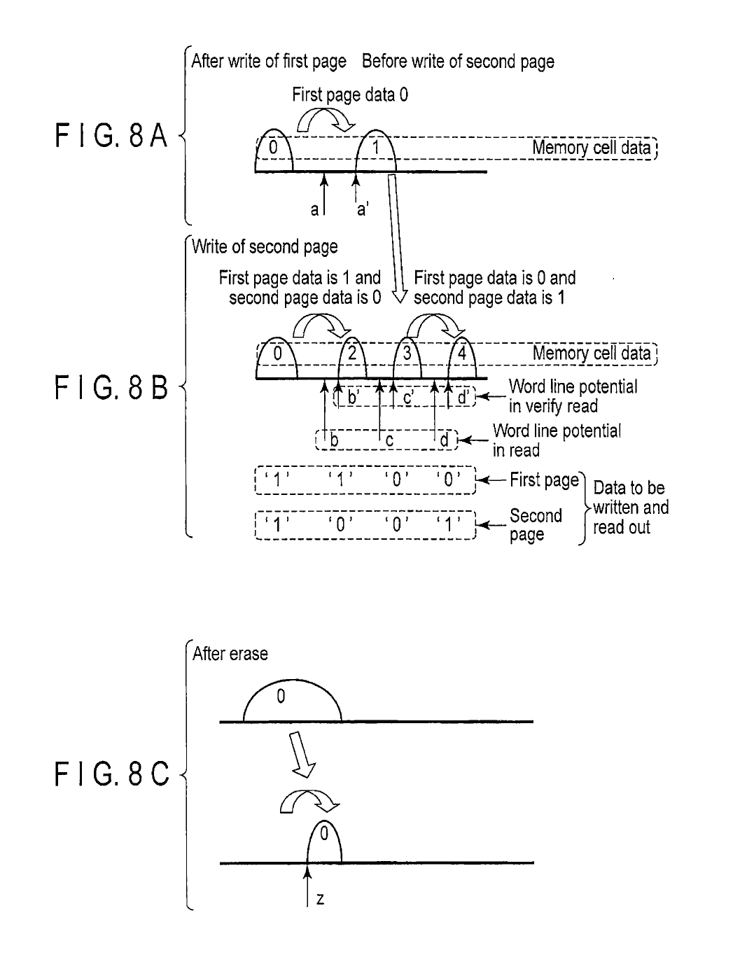

FIGS. 8A, 8B, and 8C illustrate the relationship between data and a threshold voltage when storing two-bit data in a memory cell. When performing an erase operation, the memory cell data becomes “0” as shown in FIG. 8C. After erase, write is performed using, e.g., verify level “z” in order to narrow the spread of the threshold distribution. This data “0” is set in, e.g., a negative threshold voltage distribution.

As shown in FIG. 8A, when write data is “1” in write of the first page, the memory cell data remains “0”. When the write data is “0”, the memory cell data becomes “1”.

As shown in FIG. 8B, after write of the second page, the memory cell data becomes one of “0”, “2”, “3”, and “4” in accordance with the write data. That is, when the memory cell data after write of the first page is “0” and the write data of the second page is “1”, the memory cell data remains “0”. When the write data is “0”, the memory cell data becomes “2”. Also, when the memory cell data after write of the first page is “1” and the write data is “0”, the memory cell data becomes “3”. When the write data is “1”, the memory cell data becomes “4”. In this embodiment, the memory cell data is defined from a low threshold voltage to a high threshold voltage. Also, data “1”, “2”, “3”, and “4” are, e.g., positive threshold voltages.

### (Read Operation)

As shown in FIG. 8A, after write of the first page, the memory cell data is data “0” or “1”. Accordingly, a read operation need only be performed at level “a”. Also, as shown in FIG. 8B, after write of the second page, the memory cell data is “0”, “2”, “3”, or “4”. Therefore, a read operation need only be performed at level “b”, “c”, or “d”. In this embodiment, assume that data “0” and data “2” are set on the negative side.

A read operation at each level will now be explained. First, the control signal & control voltage generator 7 applies a voltage Vfix (e.g., 1.6 V) to the well of a selected memory cell, the source line, an unselected bit line, and the select gate of an unselected block. Note that Vfix is 0 V if the threshold distribution is not set on the negative side.

A read potential Vfix+“a”, “b”, “c”, or “d” (Vfix+“a” is 1.1 V when, e.g., “a”=−0.5 V) is applied to a selected word line. Simultaneously, Vread+Vfix is applied to an unselected word line of a selected block, Vsg (Vdd+Vth)+Vfix (Vth is the threshold voltage of an n-channel MOS transistor) is applied to the select line SGD of the select gate S2 of the selected block, and Vfix is applied to the select line SGS of the select gate S1. Vfix is applied to the source line (SRC), and to the well in which a cell is formed.

Then, the signals VPRE, BLPRE, and BLCLAMP of the data storage circuit 10 shown in FIG. 7 are respectively once set at Vdd (e.g., 2.5 V), Vsg (Vdd+Vth), and, e.g., (0.6 V+Vth)+Vfix, and the bit line is precharged to, e.g., 0.6 V+Vfix=2.2 V.

Subsequently, Vsg (Vdd+Vth)+Vfix is applied to the select line SGS on the source side of the memory cell. Since the well and source are at Vfix, the memory cell is turned off if the threshold voltage of the memory cell is higher than level “a”, “b”, “c”, or “d” (e.g., “a”=−0.5 V). Accordingly, the bit line remains at High level (e.g., 2.2 V). Also, the memory cell is turned on if the threshold voltage of the memory cell is lower than level “a”, “b”, “c”, or “d”. Consequently, the bit line is discharged to the same potential as that of the source, i.e., Vfix (e.g., 1.6 V).

After that, the signal BLPRE of the data storage circuit 10 shown in FIG. 7 is once set at Vsg (Vdd+Vth), the node of the TDC is precharged to Vdd, and a signal BOOST is changed from Low level to High level, thereby setting TDC=αVdd (e.g., α=1.7, and αVdd=4.25 V). In this state, the signal BLCLAMP is set at, e.g., (0.45 V+Vth)+Vfix. The node N3 of the TDC changes to Low level (Vfix (e.g., 1.6 V)) when the bit line potential is lower than 0.45 V+Vfix, and remains at High level (αVdd (e.g., 4.25 V)) when the bit line potential is higher than 0.45 V.

After signal BLCLAMP=Vtr (e.g., 0.1 V+Vth) is set, the signal BOOST is changed from High level to Low level. At Low level, the TDC decreases from Vfix (e.g., 1.6 V). Since signal BLCLAMP=Vtr (e.g., 0.1 V+Vth), however, the potential of the node N3 does not become lower than 0.1 V. Also, when the TDC is at Low level, the potential of the node N3 changes from αVDD (e.g., 4.25 V) to Vdd.

In this state, the signal BLC1 is set at Vsg (Vdd+Vth), and the potential of the TDC is read out to the PDC. Accordingly, the PDC changes to Low level when the threshold voltage of the memory cell is lower than level “a”, “b”, “c”, or “d”, and changes to High level when the threshold voltage is higher than level “a”, “b”, “c”, or “d”. Thus, a negative threshold value can be read out without setting a word line at a negative voltage.

### (Programming)

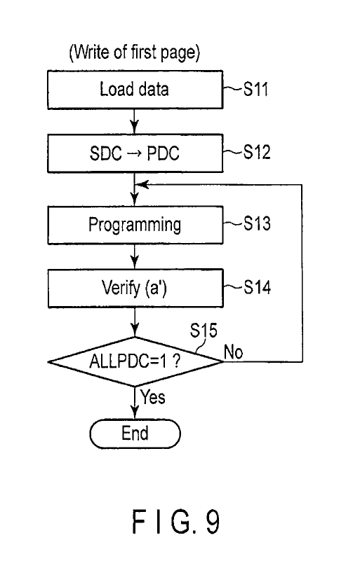

FIG. 9 is a flowchart of a programming operation.

In the programming operation, addresses are first designated to select, e.g., two pages shown in FIG. 2. This embodiment will be explained by taking, as an example, a programming operation performed in the order of the first page and second page of these two pages. First, the first page is selected by the address.

Then, write data is externally input and stored in the SDCs of all the data storage circuits 10 (S11). When a write command is input in this state, the data of the SDCs in all the data storage circuits 10 are transferred to the PDCs (S12). The node N1a of the PDC changes to High level if data “1” (no write is performed) is externally input, and changes to Low level if data “0” (write is performed) is externally input. After that, the data of the PDC is set at the potential of the node N1a of the data storage circuit 10, and the data of the SDC is set at the potential of the node N2a of the data storage circuit 10.

### (Programming Operation) (S13)

When the signal BLC1 of the data storage circuit 10 has the voltage Vdd+Vth, the bit line potential is Vdd if data “1” is stored in the PDC, and Vss if data “0” is stored in the PDC. Also, no data should be written in a memory cell of an unselected page (for which the bit line is unselected), which is connected to a selected word line. Therefore, Vdd is applied to the bit line connected to these cells, like cells in each of which data “1” is stored in the PDC.

When Vdd, Vpgm (20 V), and Vpass (10 V) are respectively applied to the select line SGS of a selected block, a selected word line, and an unselected word line in this state, write is performed if the bit line is at Vss because the channel of the cell is at Vss and the word line is at Vpgm.

On the other hand, if the bit line is at Vdd, the channel of the cell is not at Vss, but Vpgm, so about Vpgm/2 is obtained by coupling. Accordingly, no programming is performed.

In write of the first page, the memory cell data becomes data “0” or “1”. After write of the second page, the memory cell data becomes data “0”, “2”, “3”, or “4”.

### (Program Verify Read) (S14)

Program verify is performed at level “a” on the first page. The program verify operation is almost the same as the read operation.

First, the control signal & control voltage generator 7 applies the voltage Vfix (e.g., 1.6 V) to the well of a selected memory cell, the source line, an unselected bit line, and the select gate of an unselected block. A potential Vfix+“a′” (e.g., Vfix+“a′” is 1.2 V when “a′”=−0.4 V) (“′” indicates the verify voltage hereinafter and is slightly higher than the read voltage) slightly higher than the read potential Vfix+“a” is applied to a selected word line.

By applying the verify voltage Vfix+“a′” to the selected word line, a negative potential is apparently applied to the gate electrode of the memory cell. At the same time, Vread+Vfix is applied to an unselected word line of the selected block, Vsg (Vdd+Vth)+Vfix is applied to the select line SGD of the select gate S2 of the selected block, and Vfix is applied to the select line SGS of the select gate S1. In addition, Vfix is applied to the source line (SRC) and the well of the cell.

Then, the signals VPRE, BLPRE, and BLCLAMP of the data storage circuit 10 are respectively once set at Vdd (e.g., 2.5 V), Vsg (Vdd+Vth), and, e.g., (0.6 V+Vth)+Vfix, and the bit line is precharged to, e.g., 0.6 V+Vfix=2.2 V.

Subsequently, the select line SGS on the source side of the memory cell is set at Vsg (Vdd+Vth)+Vfix. Since the well and source are at Vfix, the memory cell is turned off if the threshold voltage of the memory cell is higher than verify level “a′” (e.g., a′=−0.4 V). Therefore, the bit line remains at High level (e.g., 2.2 V). Also, the memory cell is turned on if the threshold voltage of the memory cell is lower than verify level “a′”. Consequently, the bit line is discharged to the same potential as that of the source, i.e., Vfix (e.g., 1.6 V).

In this bit line discharge period, the signal DTG is once set at Vsg (Vdd+Vth), and data of the PDC is copied to the DDC.

After that, the signal BLPRE of the data storage circuit 10 is once set at Vsg (Vdd+Vth), and the node N3 of the TDC is precharged to Vdd. Then, the signal BOOST is changed from Low level to High level, and the node N3 of the TDC is set at αVdd (e.g., α=1.7, and αVdd=4.25 V). In this state, the signal BLCLAMP is set at, e.g., (0.45 V+Vth)+Vfix. The node N3 of the TDC changes to Low level (Vfix (e.g., 1.6V)) if the bit line potential is lower than 0.45 V+Vfix, and remains at High level (αVdd (e.g., 4.25 V)) if the bit line potential is higher than 0.45 V.

Subsequently, after signal BLCLAMP=Vtr (e.g., 0.1 V+Vth) is set, the signal BOOST is changed from High level to Low level. If the TDC is at Low level, the potential of the node N3 decreases from Vfix (e.g., 1.6 V). However, the potential of the node N3 does not become lower than 0.1 V because the signal BLCLAMP is set at Vtr (e.g., 0.1 V+Vth).

On the other hand, if the TDC is at High level, the potential of the node N3 changes from αVdd (e.g., 4.25 V) to Vdd. In this state, the signal BLC1 is set at Vsg (Vdd+Vth), and the potential of the TDC is read out to the PDC. Then, the signals VREG and REG are respectively set at Vdd and Vsg (Vdd+Vth). If the DDC is at High level (non write), the TDC is forcedly set at High level. If the DDC is at Low level (non write), however, the value of the TDC remains unchanged.

In this state, the signal BLC1 is set at Vsg (Vdd+Vth), and the potential of the TDC is read out to the PDC. Accordingly, if the PDC is originally at Low level (write) and the threshold voltage of the memory cell is lower than verify level “a′”, the PDC is set at Low level (write) again. If the threshold voltage of the memory cell is higher than verify level “a′”, the PDC is set at High level. Accordingly, this memory cell is not written from the next programming loop. Also, if the PDC is originally at High level (non write), the PDC changes to High level, and the memory cell is not written from the next programming loop.

The above-mentioned operation is repeated (S15-S13) until the PDCs of all the data storage circuits 10 change to High level (“1”).

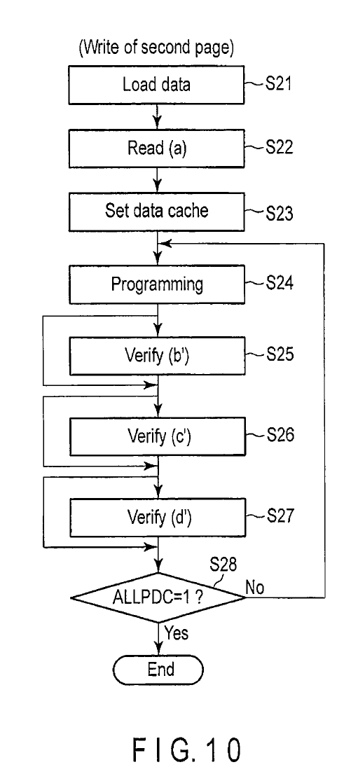

On the other hand, the write operation of the second page shown in FIG. 10 is almost the same as that of the first page. However, after externally supplied write data is set in the PDC, a read operation is performed at level “a” in order to check the data written in the first page (S21 and S22). After that, data is set in the PDC by using the readout data and externally supplied write data (S23). That is, as shown in FIG. 8B, data “0” is set in the PDC when the data of the first page is “1” and that of the second page is “0” and when the data of the first page is “0” and that of the second page is “1”, and data “1” is set in the PDC in other cases.

In this state, the programming operation described above is executed (S24).

After that, program verify is executed (S25, S26, and S27). Program verify of the second page is executed in almost the same manner as that performed at verify level “a′” by sequentially setting verify levels “b”, “c′”, and “d′”.

When the program verify operation is performed at verify level “b′” when writing the second page, cells to be written to levels “c” and “d” are not written by program verify at level “b′”. Therefore, when, e.g., performing write at verify levels “c′” and “d′”, the node N2a of the data storage circuit 10 is set at High level. When performing write at verify level “b′”, the node N2a is set at High level, and the signal REG is set at Vsg. When writing no data, the signal BLC2 is set at Vtr (0.1 V+Vth) before the operation of forcedly changing the TDC to High level. When writing data at verify levels “c′” and “d′”, the TDC is forcedly changed to Low level, so as not to complete write by program verify at verify level “b′”.

Also, when the above-mentioned operation is performed as program verify at verify level “c′” when writing the second page, cells to be written to level “d” are not written by program verify at verify level “c′”. Therefore, when writing data to level “c”, for example, the node N1a of the data storage circuit 10 is set at Low level. In other cases, the node N1a of the data storage circuit 10 is set at Low level, and the signal REG is set at Vsg. Also, when writing no data, the signal BLC1 is set at Vtr (0.1 V+Vth) before the operation of forcedly changing the TDC to High level. Furthermore, when writing data at verify level “d′”, the TDC is forcedly set at Low level, so as not to complete write by program verify at verify level “d”.

When the PDC is at Low level, the write operation is performed again, and the programming operation and verify operation are repeated until the PDC data of all the data storage circuits 10 change to High level (S28-S24).

### (Erase Operation)

An erase operation is performed for each block indicated by, e.g., the broken lines in FIG. 2. After erase, the threshold voltage of the memory cell becomes data “0” as shown in FIG. 8C.

After the erase operation, programming and program verify read are executed by selecting all word lines in the block, and a write operation is performed to level “z” as shown in FIG. 8C. In the programming operation and program verify read operation, all word lines are selected, and the potential of a selected word line is set at level “z”+Vfix (e.g., 0 V) in verify. The rest of the operation is exactly the same as normal programming and program verify read.

### First Embodiment

In this embodiment as described previously, adjacent bit lines are formed in different interconnection layers in order to reduce the capacitance of the bit lines.

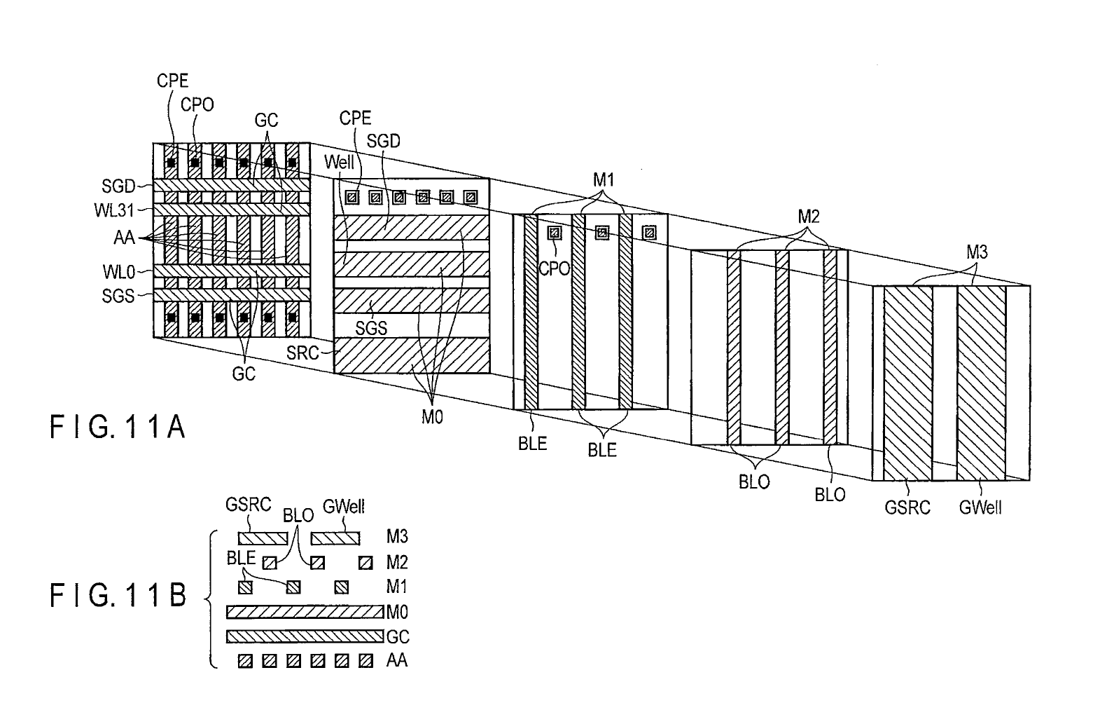

FIGS. 11A and 11B schematically show the arrangements of a memory cell and select gate of a NAND flash memory according to this embodiment. For descriptive convenience, interlayer dielectric films and the like are omitted.

As shown in FIGS. 11A and 11B, gate electrodes GC of memory cell transistors forming word lines are formed above active areas AA as the source and drain regions formed in a semiconductor substrate (not shown). Select lines SGS and SGD of select gates, a source line SRC, and an interconnection Well for supplying a potential to the well are formed above the gate electrodes GC by first metal interconnection layers M0. However, when the time constants of the select lines SGS and SGD of the select gates are small, for example, the interconnections M0 as shunts are unnecessary, and the interconnection well may also be omitted.

Above the first metal interconnection layers M0, even-numbered bit lines BLE are formed by second metal interconnection layers M1, and odd-numbered bit lines BLO are formed by third metal interconnection layers M2. In the following description, the bit lines BLE represent BL0, BL2, . . . , BL(i−2), BLi, . . . , BL(k−2) shown in FIG. 2, and BL0e, BL0o, BL2e, BL2o, . . . , BL(i−2)e, BL(i−2)o, BLie, BLio, . . . , BL(k−2)e, and BL(k−2)o shown in FIG. 3. Also, the bit lines BLO represent BL1, BL3, . . . , BL(i−1), BL(i+1), . . . , BL(k−1) shown in FIG. 2, and BL1e, BL1o, BL3e, BL3o, . . . , BL(i−1)e, BL(i−1)o, BL(i+1)e, BL(i+1)o, . . . , BL(k−1)e, and BL(k−1)o. However, when the resistance of the interconnection Well for supplying a potential to the source line SRC and well is low, for example, the interconnections M2 as shunts are unnecessary and can also be omitted. That is, the even-numbered bit lines BLE are arranged to face every other active area AA, and the odd-numbered bit lines BLO are arranged above the spacings between the even-numbered bit lines BLE. That is, the odd-numbered bit lines BLO are also arranged to face every other active area AA.

Furthermore, a global source line GSRC and global interconnection GWell are formed above the third metal interconnection layers M2 by fourth metal interconnection layers M3. The global source line GSRC and the global interconnection GWell are respectively connected to the source line SRC and the interconnection Well for supplying a potential to the well.

The bit lines BLE and BLO are arranged above the active areas AA. Contact plugs CPE and CPO are arranged on the active areas AA outside the select line SGS of the select gates (the side opposite to the side on which word lines WL0 to WL31 are arranged). The bit lines BLE are electrically connected to the active areas AA by the contact plugs CPE. The bit lines BLO are electrically connected to the active areas AA by the contact plugs CPO. That is, the contact plugs CPO extend between the bit lines BLE.

The distance between the bit lines BLE is equal to a distance obtained by adding the width of the active area AA and the double of the distance between the active areas AA. Likewise, the distance between the bit lines BLO is equal to a distance obtained by adding the width of the active area AA and the double of the distance between the active areas AA.

As described above, the even-numbered bit lines BLE are formed by the second metal interconnection layers M1, and the odd-numbered bit lines BLO are formed by the third metal interconnection layers M2. When the widths of the bit lines BLE and BLO are the same, for example, the distance between adjacent bit lines BLE and the distance between adjacent bit lines BLO can be made about three times the distance when the bit lines BLE and BLO are arranged adjacent to each other in the same interconnection layer. This makes it possible to reduce the capacitance between the bit lines BLE to about ⅓, and reduce the CR time constant of the bit line to about ⅓.

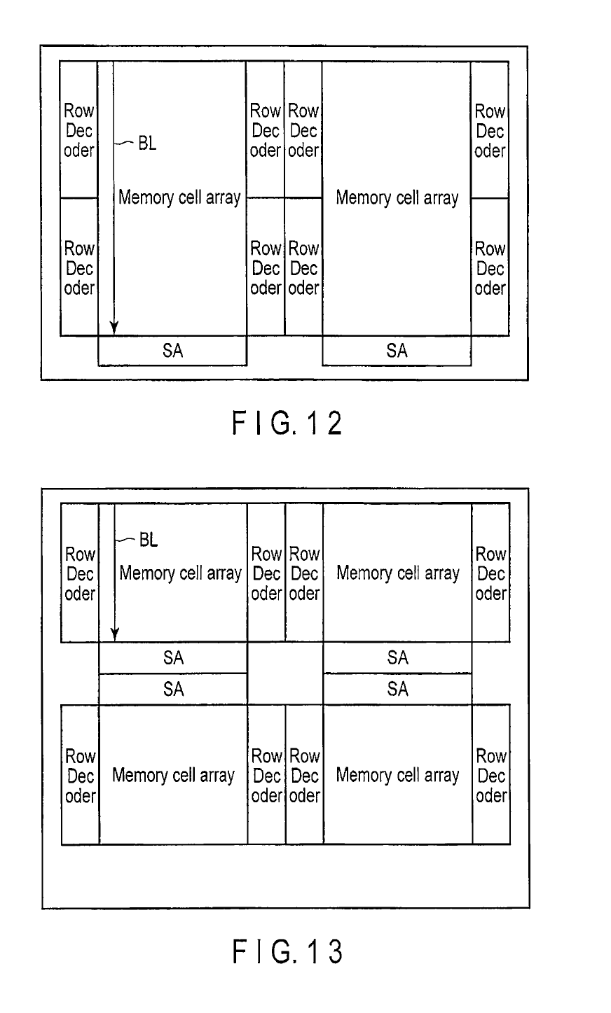

FIG. 12 shows the floor plan of the semiconductor memory device according to this embodiment. FIG. 13 shows the floor plan of a general semiconductor memory device. Referring to FIG. 13, odd-numbered bit lines and even-numbered bit lines are formed in the same interconnection layer. Assume that the storage capacities of the semiconductor memory devices shown in FIGS. 12 and 13 are almost equal.

That is, when the CR time constant is large, the length of the bit lines BL is decreased in order to increase the operation speed. When the length of the bit lines BL is decreased, the distance the bit lines BL can run on the memory cell array shortens. Consequently, the memory cell array is divided in the direction in which the bit lines BL run. That is, the number of bit lines BL in the semiconductor device increases. In the example shown in FIG. 13, for example, each bit line BL is divided into two parts in the direction in which the bit lines BL run, when compared to the example shown in FIG. 12. That is, the number of bit lines BL doubles. Since the number of sense amplifiers SA is proportional to the number of bit lines BL, the number of sense amplifiers SA in the semiconductor device increases.

The above-mentioned arrangement of this embodiment can reduce the bit line capacitance and CR time constant. Accordingly, the length of the bit lines BL can be made about twice that in the example shown in FIG. 13. This makes it possible to decrease the number of sense amplifiers SA (data storage circuits) when compared to the example shown in FIG. 13. Therefore, the semiconductor memory device shown in FIG. 13 is formed by four planes including four memory cell arrays, whereas the semiconductor memory device according to this embodiment can be formed by two planes including two memory cell arrays. As a consequence, the chip size can be made smaller than that shown in FIG. 13, so the manufacturing cost can be reduced. Especially in a multi-chip package (MCP) in which a plurality of chips are accommodated in one package, pads are desirably arranged on one side of the chip. When pads PA are arranged along, e.g., the lower sides in FIGS. 12 and 13 of the chips, a power supply line is extended to the central portion of the chip in the arrangement shown in FIG. 13, but that is unnecessary in the arrangement shown in FIG. 12. This makes it possible to suppress the increase in length of the power supply line.

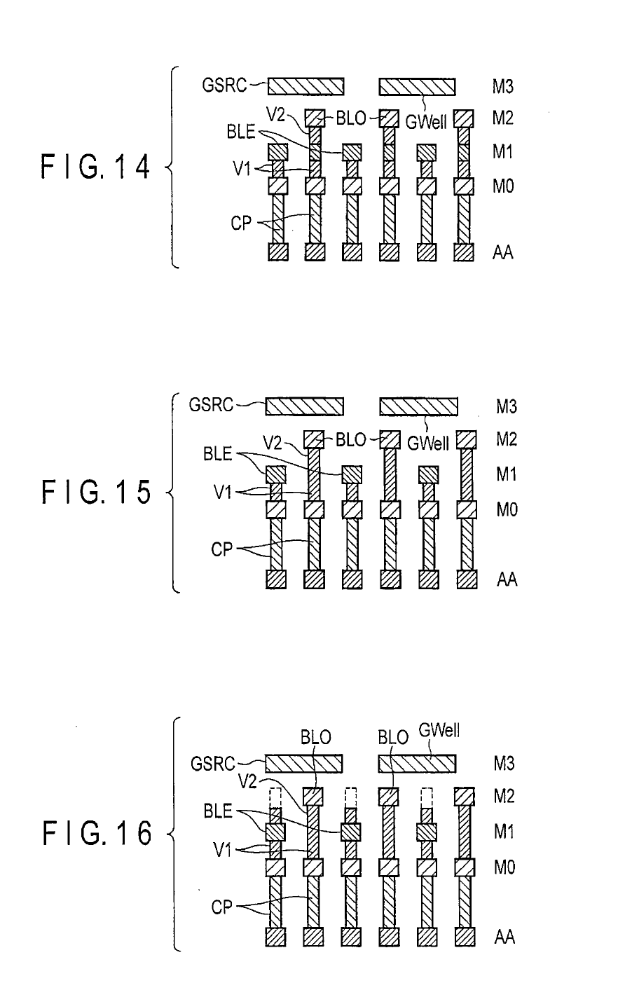

FIG. 14 shows the relationship between the bit lines BLO and BLE and the contacts shown in FIGS. 11A and 11B. The first metal interconnection layers M0 are connected to the active areas AA via the contact plugs CP. The even-numbered bit lines BLE are connected to the first metal interconnection layers M0 via first vias V1. The odd-numbered bit lines BLO are connected to the first metal interconnection layers M0 via second vias V2, the second metal interconnection layers M1, and the first vias V1.

The contact plugs CP are made of, e.g., polysilicon. The first vias V1 are formed by so-called dual damascene by using, e.g., the second metal interconnection layers M1. The second vias V2 are formed by dual damascene together with, e.g., the odd-numbered bit lines BLO by using, e.g., the third metal interconnection layers M2.

FIG. 15 shows the first modification of FIG. 14. FIG. 16 shows the second modification of FIG. 14. The same reference symbols as in FIG. 14 denote the same parts in FIGS. 15 and 16, and only different portions will be explained below.

In the first modification shown in FIG. 15, the odd-numbered bit lines BLO are connected to the first metal interconnection layers M0 by the second vias V2. The second vias V2 are formed by dual damascene together with, e.g., the odd-numbered bit lines BLO and first vias V1 by using, e.g., the third metal interconnection layers M2.

The first modification can also form the planar structure shown in FIGS. 11A and 11B.

In the second modification shown in FIG. 16, the even-numbered bit lines BLE are formed by the second metal interconnection layers M1. The second vias V2 are formed by, e.g., the third metal interconnection layers M2 (the same material as that of the third metal interconnection layers M2), and connect the odd-numbered bit lines BLO and first metal interconnection layers M0. The first vias V1 are formed to extend through the even-numbered bit lines BLE, and connect the even-numbered bit lines BLE and first metal interconnection layers M0.

The second modification can also form the planar structure shown in FIGS. 11A and 11B.

Note that in FIG. 16, the vias on the even-numbered bit lines BLE can also be formed by the third metal interconnection layers M2. In this case, these vias can also be formed to the same level as that of the third metal interconnection layers M2 as indicated by the broken lines in FIG. 16.

In the above-mentioned first embodiment, the even-numbered bit lines BLE and odd-numbered bit lines BLO are formed in different interconnection layers. Therefore, the spacing between bit lines formed in the same interconnection layer can be made larger than that when the even-numbered bit lines BLE and odd-numbered bit lines BLO are formed in the same interconnection layer. This makes it possible to reduce the capacitance between the bit lines, and reduce the CR time constant of the bit lines. Since the bit line length can be increased accordingly, the number of memory cells connected to one bit line can be increased. Therefore, it is possible to decrease the number of sense amplifiers and reduce the chip area. In this embodiment, the first or second vias V1 or V2 are connected to the contact plugs CP via the first metal interconnection layers M0. However, the first or second vias V1 or V2 can also be connected directly to the contact plugs CP without the first metal interconnection layers M0.

### Second Embodiment

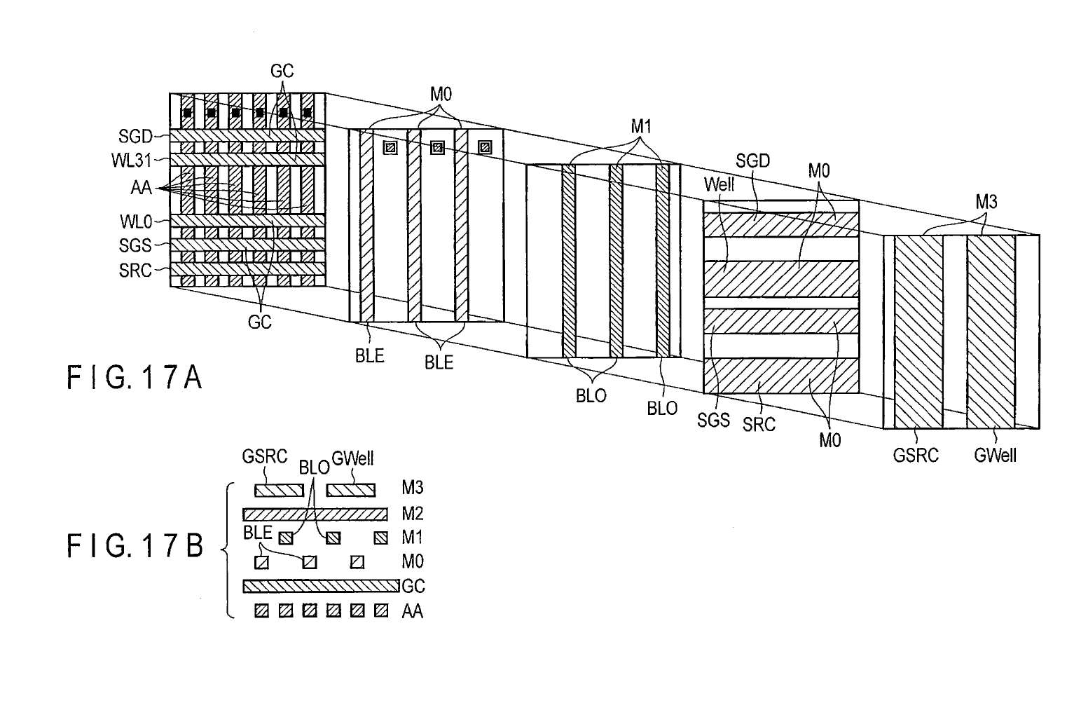

FIGS. 17A and 17B illustrate the second embodiment. In the second embodiment, the same reference symbols as in the first embodiment denote the same parts.

In the first embodiment shown in FIGS. 11A and 11B, the even-numbered bit lines BLE are formed in the second metal interconnection layer M1, and the odd-numbered bit lines BLO are formed in the third metal interconnection layer M2.

By contrast, in the second embodiment shown in FIGS. 17A and 17B, even-numbered bit lines BLE are formed in a first metal interconnection layer M0, and odd-numbered bit lines BLO are formed in a second metal interconnection layer M1. A source line SRC, select lines SGS and SGD, and an interconnection Well for supplying power to the well are formed in a third metal interconnection layer M2.

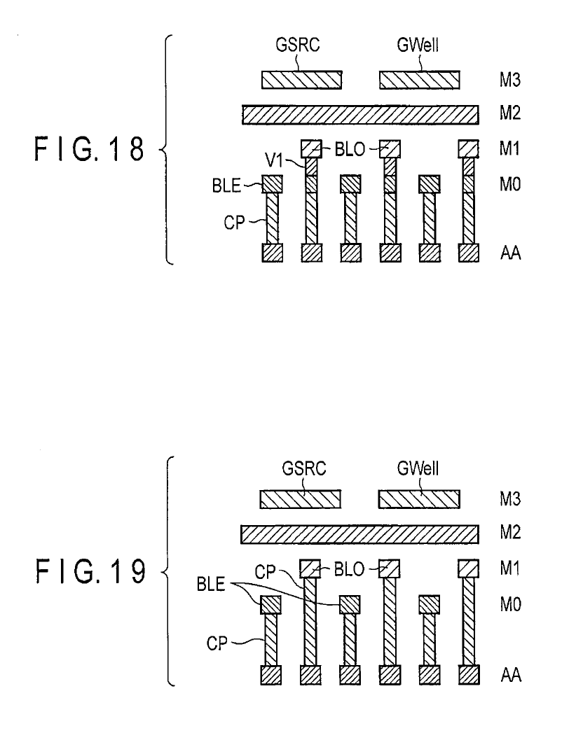

FIG. 18 shows the relationship between the bit lines BLO and BLE and contacts in the second embodiment. The even-numbered bit lines BLE are connected to active areas AA via contact plugs CP. The odd-numbered bit lines BLO are connected to the active areas AA via the contact plugs CP and first vias V1. The contact plugs CP are made of, e.g., polysilicon. The first vias V1 are formed by so-called dual damascene by using, e.g., the second metal interconnection layer M1. The contact plugs CP are formed by so-called dual damascene by using, e.g., the first metal interconnection layer M0. The first vias V1 can also be formed by dual damascene by using, e.g., the second metal interconnection layer M1.

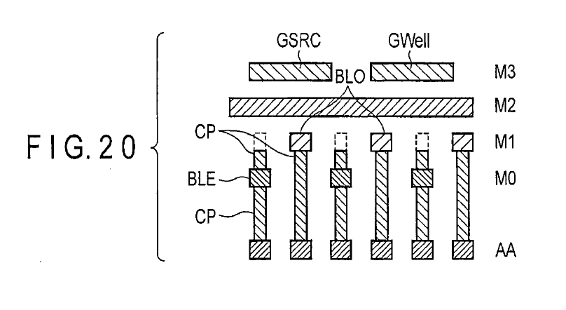

FIG. 19 shows the first modification of the arrangement shown in FIG. 18. FIG. 20 shows the second modification of the arrangement shown in FIG. 18. The same reference symbols as in FIG. 18 denote the same parts in FIGS. 19 and 20, and only different portions will be explained.

In the first modification shown in FIG. 19, the odd-numbered bit lines BLO are also connected to the active areas AA via the contact plugs CP, like the even-numbered bit lines BLE. The first modification can also implement an arrangement similar to that shown in FIG. 18.

In the second modification shown in FIG. 20, the contact plugs CP are formed to extend through the even-numbered bit lines BLE. Therefore, the contact plugs CP to be connected to the odd-numbered bit lines BLO and even-numbered bit lines BLE can be formed at the same time. This makes it possible to reduce manufacturing steps.

Note that in FIG. 20, the vias on the even-numbered bit lines BLE may also be formed by the second metal interconnection layer M1. In this case, the vias can be formed to the same level as that of the second metal interconnection layer M1 as indicated by the broken lines in FIG. 16.

The above-mentioned second embodiment can also achieve the same effects as those of the first embodiment.

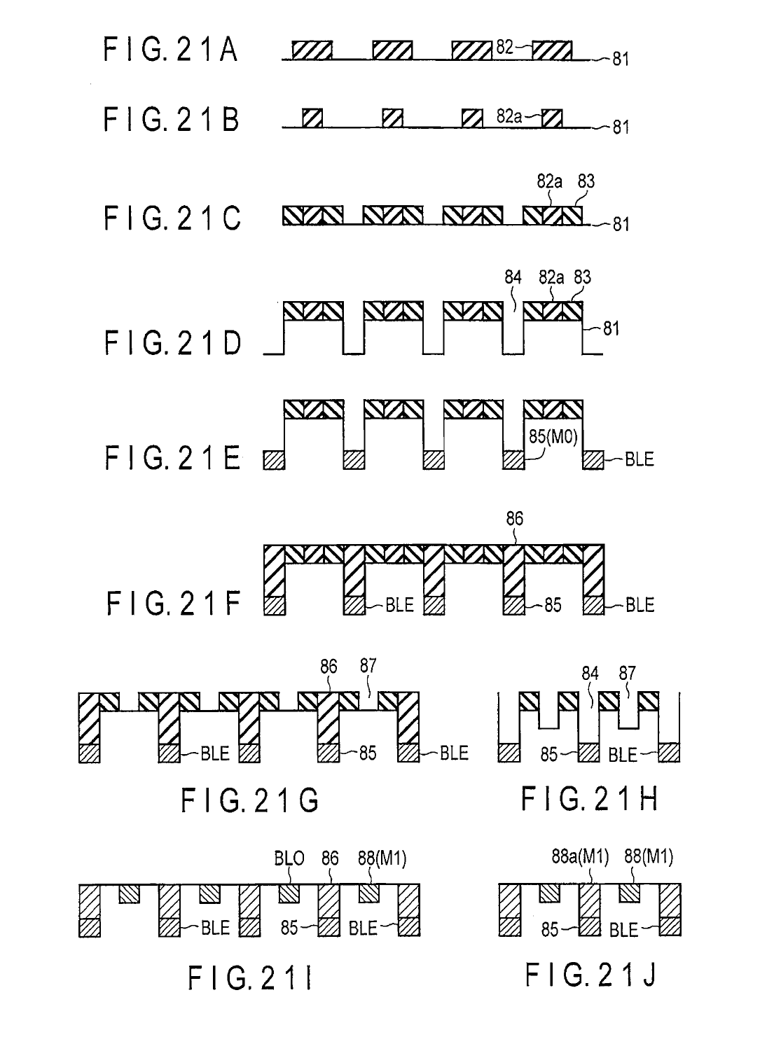

FIGS. 21A, 21B, 21C, 21D, 21E, 21F, 21G, 21H, 21I, and 21J show examples of manufacturing steps when forming even-numbered bit lines BLE and odd-numbered bit lines BLO in different metal interconnection layers as described above.

As shown in FIG. 21A, resist films 82, for example, as patterned core materials are formed on an interlayer dielectric film 81. The width of the resist film 82 is formed to have a pitch about twice the width (to be referred to as a target width hereinafter) of a bit line to be formed. The width of the resist film 82 and the space between the resist films 82 are preferably equal. Note that hard masks may also be formed by transferring the resist films 82 onto a mask material or the like.

As shown in FIG. 21B, resist films 82a each having the target width (almost the same width as that of an active area AA) are formed by slimming the resist films 82.

As shown in FIG. 21C, sidewalls 83 are formed on the two sides of each slimmed resist film 82a. The width of the sidewall is set to be equal to the target width. That is, the total width of the resist film 82a and the sidewalls 83 on the two sides of the resist film 82a is about three times the target width. Also, the distance between the sidewalls 83 is almost equal to the target width.

As shown in FIG. 21D, the interlayer dielectric film 81 is etched by using the resist films 82a and sidewalls 83 as masks, thereby forming trenches 84. The depth of the trench 84 is set to be, e.g., about three times the target width.

As shown in FIG. 21E, even-numbered bit lines BLE are formed by forming first metal interconnection layers M0 in the trenches 84. In this step, it is possible to simultaneously bury a conductor for forming the first metal interconnection layers M0 in holes of contact plugs CP connected to the bottoms of the trenches 84. The contact plugs CP and first metal interconnection layers M0 are formed by dual damascene, so a manufacturing step can be omitted. In this case, after the conductor is deposited on the entire surface, the conductor remaining on the upper surfaces of the resist films 82a and sidewalls 83 is removed by anisotropic etching or the like, so that the first metal interconnection layers M0 only remain on the bottoms of the trenches 84 and in the holes of the contact plugs CP.

As shown in FIG. 21F, insulting films 86 are buried in the trenches 84. The insulating films 86 are formed by a material having an etching rate higher than those of the interlayer dielectric film 81 and insulating films 83. The insulating films 86 can protect the upper portions of the first metal interconnection layers M0 from being oxidized, and further decrease the resistance of bit lines BL. In this step, it is favorable to remove the insulating films 86 formed on the resist films 82a as shown in FIG. 21F. Also, the insulating films 86 are not buried in, for example, those positions of the trenches 84, in which vias are to be formed. Note that vias may also be formed by once burying the insulating films 86 and then removing the buried materials from the via formation positions.

As shown in FIGS. 21G and 21H, the resist films 82a are removed, and the interlayer dielectric film 81 is etched by using the insulating films 83 as masks, thereby forming trenches 87 for forming bit lines. In this step, as shown in FIG. 21H, the insulating films 86 are also etched in the via portions like the insulating dielectric film 81. In this step, the bottom of each trench 87 is made shallower than the upper surface of the first metal interconnection layer M0 by controlling the etching rates of the insulating films 86 and interlayer dielectric film 81. As a consequence, a manufacturing step can be omitted.

As shown in FIGS. 21I and 21J, odd-numbered bit lines BLO are formed by removing the insulating films 83, and burying second metal interconnection layers M1. In this step, as shown in FIG. 21J, vias 88a are formed by the second metal interconnection layers M1. A semiconductor memory device can be manufactured by the well-known manufacturing method.

Note that it is also possible to simultaneously form the odd-numbered bit lines BLO and vias by using a dual damascene process, instead of a so-called single damascene process.

In the above-mentioned manufacturing method, the even-numbered and odd-numbered bit lines are respectively formed in the first and second metal interconnection layers M0 and M1. However, this manufacturing method is also applicable when respectively forming the even-numbered and odd-numbered bit lines in the second and third metal interconnection layers M1 and M2.

A plurality of metal interconnection layers are normally formed by forming interlayer dielectric films between them so that the metal interconnection layers do not contact each other. In this embodiment, however, the capacitance between adjacent bit lines arranged in the same layer can be reduced. This obviates an interlayer dielectric film formed between bit lines in different layers.

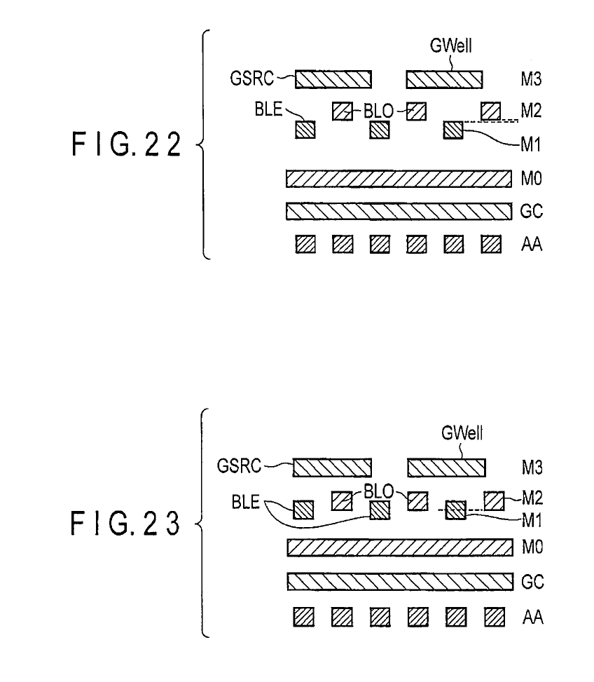

For example, in an arrangement shown in FIG. 22 as a modification of FIGS. 14, 15, and 16, interlayer dielectric film is not formed between the bit lines BLE in the first layer (the second metal interconnection layer M1) and the bit lines BLO in the second layer (the third metal interconnection layer M2).

More specifically, in the arrangement shown in FIG. 22, between the bit lines BLE in the first layer (the second metal interconnection layer M1) and the bit lines BLO in the second layer (the third metal interconnection layer M2), an interlayer dielectric film thinner than those shown in FIGS. 14, 15, and 16 and FIGS. 18, 19, and 20 is formed, or interlayer dielectric film is not formed.

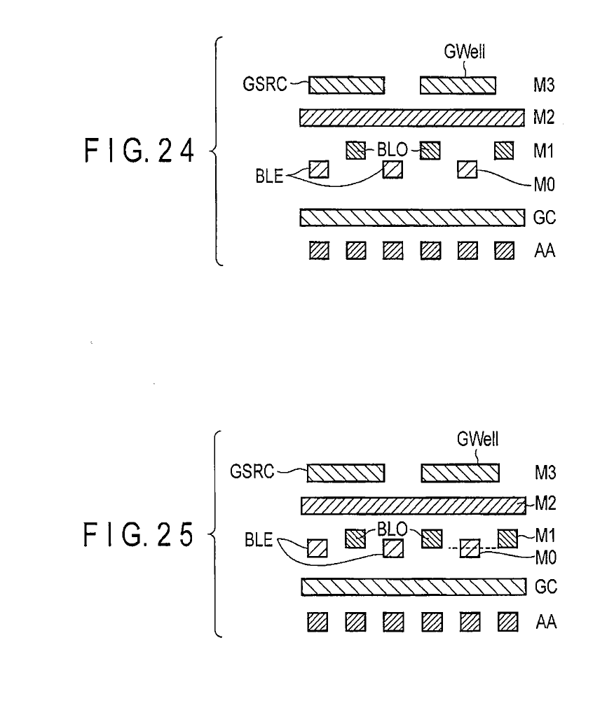

Also, in an arrangement shown in FIG. 24 as a modification of FIGS. 18, 19, and 20, interlayer dielectric film is not formed between the bit lines BLE in the first layer (the first metal interconnection layer M0) and the bit lines BLO in the second layer (the second metal interconnection layer M1).

That is, a thin interlayer dielectric film is formed or no interlayer dielectric film is formed between the bit lines BLE in the first layer (the first metal interconnection layer M0) and the bit lines BLO in the second layer (the second metal interconnection layer M1) in the arrangement shown in FIG. 24 as well. When omitting an interlayer dielectric film, the upper surfaces of the bit lines BL in the first layer may be higher than the lower surfaces of the bit lines BLO in the second layer.

In the arrangements shown in FIGS. 22 and 24, therefore, the thicknesses of the whole semiconductor memory devices can be made very small.

Furthermore, it is also possible not to form interlayer dielectric film between the bit lines BLE in the first layer (the second metal interconnection layer M1) and the bit lines BLO in the second layer (the third metal interconnection layer M2) as in a modification shown in FIG. 23, and not to form interlayer dielectric film between the bit lines BLE in the first layer (the first metal interconnection layer M0) and the bit lines BLO in the second layer (the second metal interconnection layer M1) as in a modification shown in FIG. 25. That is, the upper surfaces of the bit lines BLE in the first layer are higher than the lower surfaces of the bit lines BLO in the second layer.

In the arrangements shown in FIGS. 23 and 25, the bit lines BLO in the second layer are partially arranged between the bit lines BLE in the first layer. Therefore, the thicknesses of the whole semiconductor memory devices can be made farther smaller than those shown in FIGS. 22 and 24. This makes it possible to decrease the aspect ratio of the contact hole for connecting the interconnections. Accordingly, the processing accuracy can be increased.

Note that in the modifications shown in FIGS. 22, 23, 24, and 25, peripheral circuits can be formed by using only one of the metal interconnection layers of the bit lines BLE in the first layer and the bit lines BLO in the second layer, or by using a thick metal interconnection layer by combining the metal interconnection layers of the bit lines BLE in the first layer and the bit lines BLO in the second layer. When using a thick metal interconnection layer, the resistance of the metal interconnection can be decreased.

In the above embodiments, the bit lines BL in the lower layer are BLE, and the bit lines BL in the upper layer are BLO. However, the bit lines BL in the lower layer may be formed as BLO, and the bit lines BL in the upper layer may be formed as BLE.

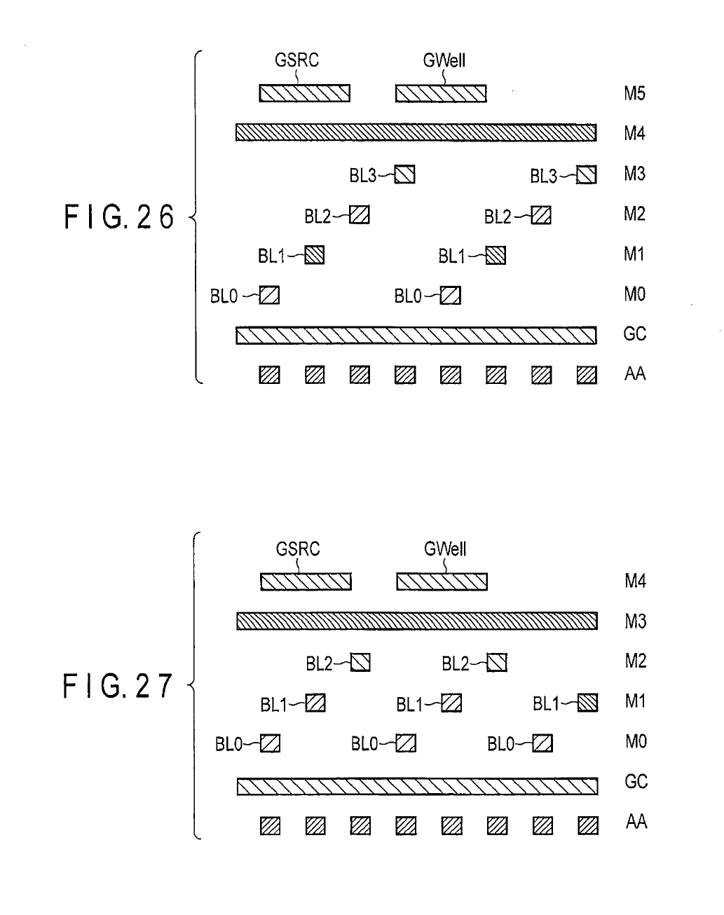

FIGS. 26, 27, and 28 show other modifications.

In the examples shown in FIGS. 26 and 27, the distance between bit lines BLO, the distance between bit lines BL1, the distance between bit lines BL2, and the distance between bit lines BL3 are equal to a distance obtained by adding the width of the active area AA and the quadruple or triple of the distance between the active areas AA. In these arrangements, the capacitance between the bit lines can further be reduced.

The example shown in FIG. 26 can be formed by further repeating the manufacturing steps shown in FIGS. 21A, 21B, 21C, 21D, 21E, 21F, 21G, 21H, 21I, and 21J.

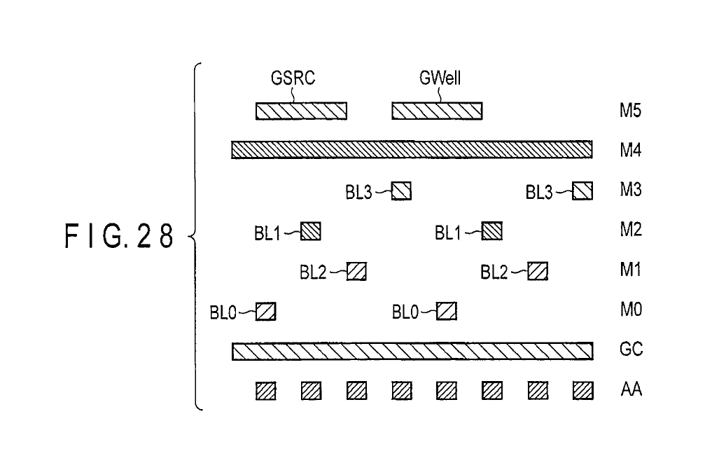

FIG. 28 shows a modification of FIG. 26. Referring to FIG. 28, the oblique distance between the bit lines BL0 and BL1 and the oblique distance between the bit lines BL2 and BL3, except for the bit lines BL1 and BL2, are longer than those in the example shown in FIG. 26. It is also possible to increase the distances between all the bit lines by making an interlayer dielectric film between the bit lines BL1 and BL2 thicker than those between other bit lines. This arrangement can further reduce the capacitance between the bit lines.

As shown in FIG. 3, bit lines BL(i−2)e and BL(i−2)o arranged in the same layer are connected to one data storage circuit 10, and bit lines BL(i−1)e and BL(i−1)o arranged in the same layer are connected to one data storage circuit 10.

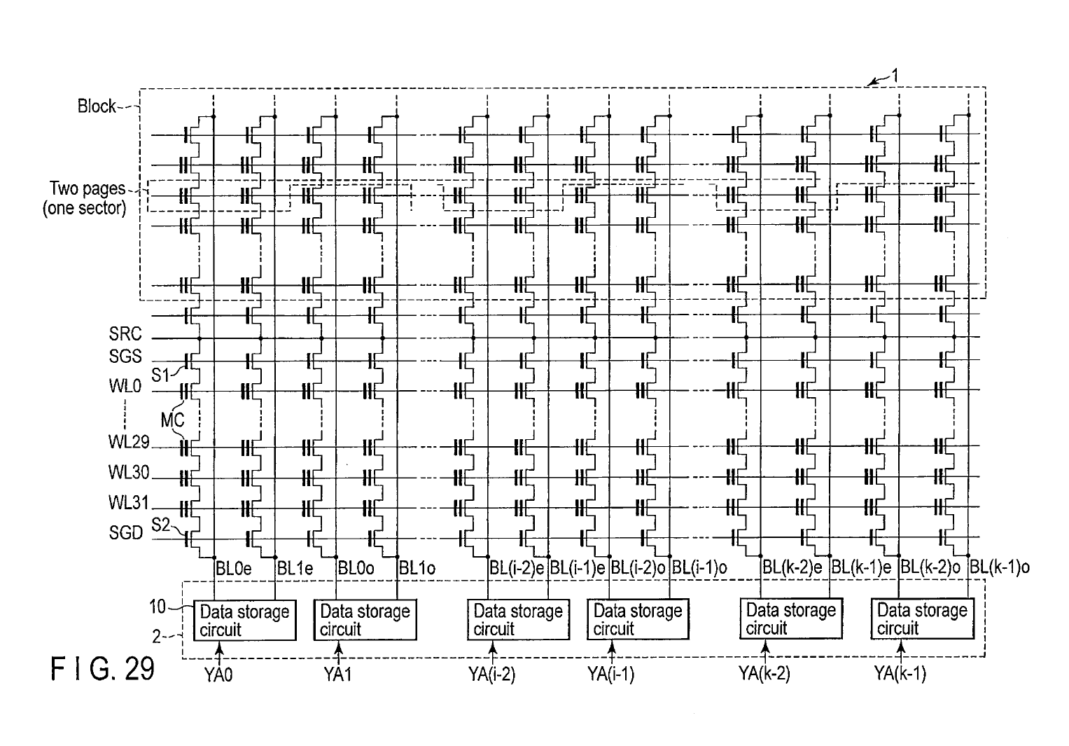

However, as shown in FIG. 29, it is possible to constitute bit lines. That is, for example, bit lines BL(i−2)e and BL(i−1)e arranged in different layers are connected to the data storage circuit 10, and bit lines BL(i−2)o and BL(i−1)o arranged in different layers are connected to the data storage circuit 10. In this case, when bit lines BL(i−2)e and BL(i−1)o are selected, bit lines BL(i−1)e and BL(i−2)o are unselected, and when bit lines BL(i−1)e and BL(i−2)o are selected, bit lines BL(i−2)e and BL(i−1)o are unselected.

Moreover, the configuration shown in FIG. 29 is that the bit line BL(i−1)e arranged in the different layer from the bit line BL(i−2)e is connected to one data storage circuit 10, and the bit line BL(i−1)o arranged in different layer from the bit line BL(1−2)o is connected to one data storage circuit 10. However, the configuration shown in FIG. 29 can be modified as follows. That is, bit lines BL0e, BL0o, BL2e, BL2o, . . . BL(i−2)e, and BL(i−2)o may be selected as one page, and bit lines BLie, BL1o, BL3e, BL3o, . . . BL(i−1)e, and BL(i−1)o . . . may be selected as another one page. In this configuration, since the adjacent bit lines on the same layer are selected simultaneously, these bit lines have no relation by which one of bit lines is selected and the other one of bit lines is unselected. However, these bit lines arranged in different layers are shielded mutually.

### Third Embodiment

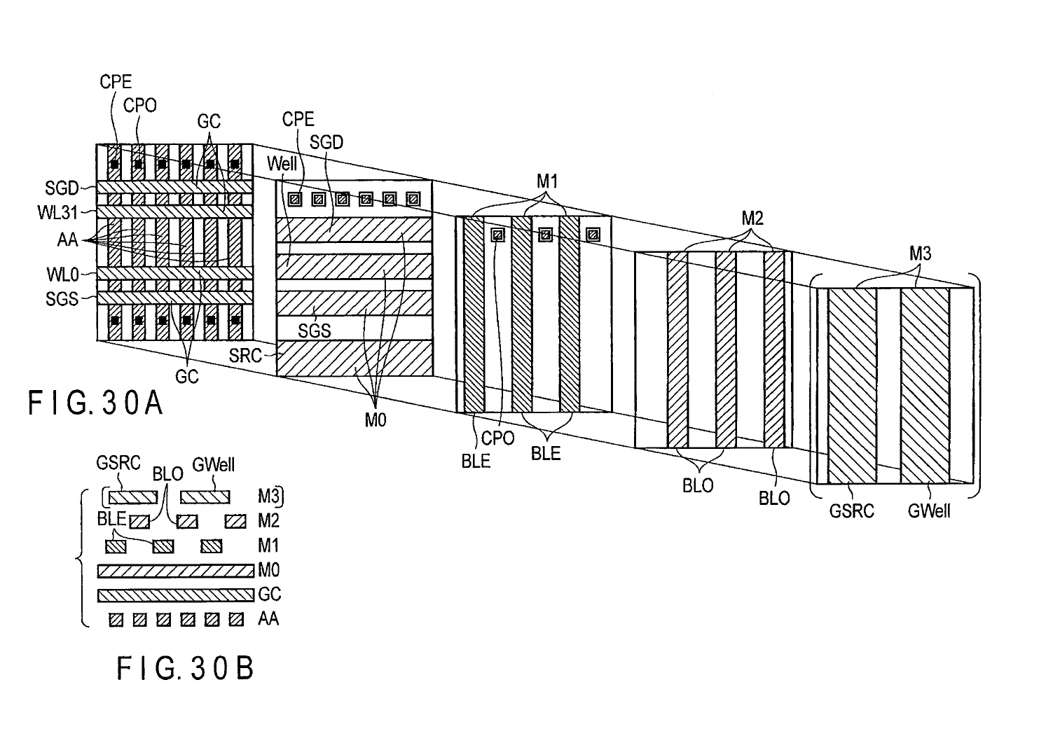

FIGS. 30A and 30B show the third embodiment, i.e., exemplarily depict the arrangement of memory cells and selection gates of a NAND flash memory. For the sake of explanation, an interlayer dielectric film and the like are omitted.

The third embodiment is a modification of the first embodiment, and the same reference numerals as in FIGS. 11A and 11B denote the same parts.

The difference of FIGS. 30A and 30B from FIGS. 11A and 11B is the width of an even-numbered bit line BLE and odd-numbered bit line BLO. That is, in the third embodiment, the width of the bit lines BLE and BLO is set larger than that of the bit lines BLE and BLO in the first embodiment.

In the first embodiment, the width of the bit lines BLE and BLO is the same as that of the active area AA. In this embodiment, the even-numbered bit lines BLE are formed by second metal interconnection layers M1, and the odd-numbered bit lines BLO are formed by third metal interconnection layers M2. Also, the width of the bit lines BLE and BLO is set about twice that of active layers AA. Furthermore, the interval between the bit lines BLE and that between the bit lines BLO are set about twice the width of the active layers AA. That is, the pitch of the bit lines BLE and that of the bit lines BLO are set twice that of the active layers AA.

As described above, the interval between the bit lines BLE and that between the bit lines BLO are almost equal to the width of the bit lines BLE and BLO, and contact plugs CPO can be formed between the bit lines BLE.

In the third embodiment, the width of the bit lines BLE and BLO can be made larger than that in the first embodiment. Therefore, the wiring resistance of the bit lines BLE and BLO can be decreased. In addition, the capacitance between the bit lines BLE and BLO can be decreased because the bit lines BLE and BLO are arranged in different interconnection layers. Accordingly, the CR time constant of the bit lines BLE and BLO can be decreased, so a signal transmission delay can be suppressed. This makes it possible to increase the read and write speeds of the NAND flash memory.

Also, processing is easy because the width of the bit lines BLE and BLO, the interval between the bit lines BLE, and the interval between the bit lines BLO are twice the width of the memory cell (the width of the active layer AA). Furthermore, the width of the memory cell is recently formed by so-called sidewall processing in some cases for the purpose of shrinking. When using this embodiment, however, the width of the bit lines BLE and BLO, the interval between the bit lines BLE, and the interval between the bit lines BLO are twice or a plurality of number of times larger than the width of the memory cell. It is not necessity to use sidewall interconnections when processing the bit lines, and facilitates the manufacture of the bit lines. In addition, even when processing the width of the memory cell by performing sidewall processing twice, the bit lines can be manufactured by performing sidewall processing once or without using any sidewall processing.

Furthermore, referring to FIGS. 30A and 30B, portions corresponding to the even-numbered bit lines BLE in the second metal interconnection layers M1 are positioned between the odd-numbered bit lines BLO in the third metal interconnection layers M2.

Also, portions corresponding to the odd-numbered bit lines BLO in the third metal interconnection layers M2 are intervals between the even-numbered bit lines BLE in the metal interconnection layers M1. Accordingly, the even-numbered bit lines BLE and odd-numbered bit lines BLO can be formed by performing lithography once.

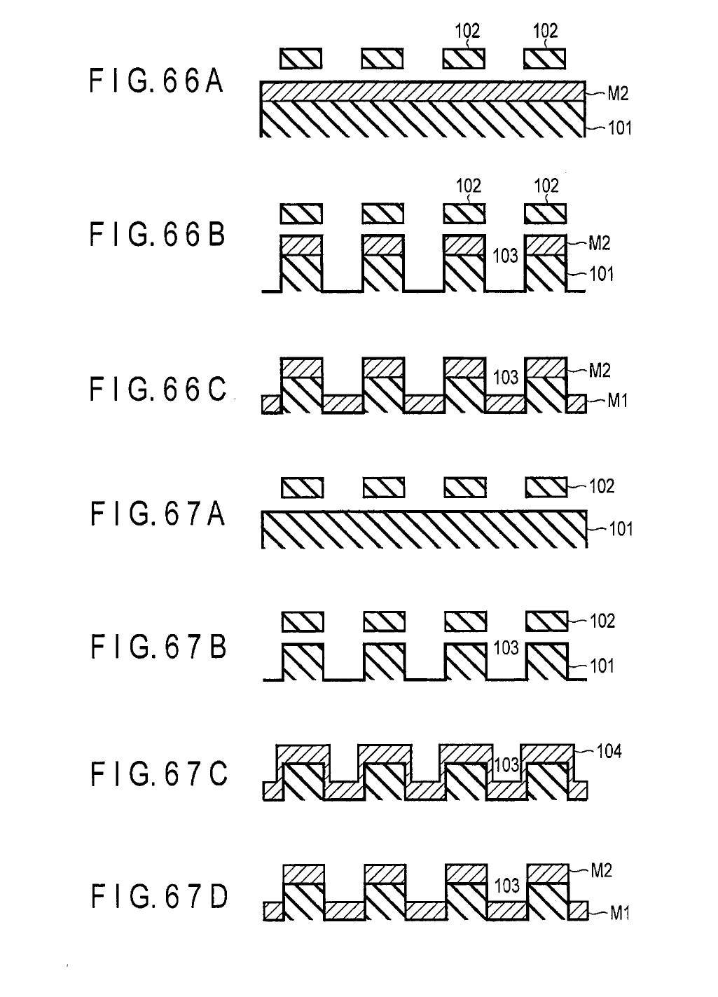

That is, as shown in FIG. 66A, after a third metal interconnection layer M2 is formed on an insulating film 101, a resist is applied above the metal interconnection layer M2, and resist patterns 102 are formed above the third metal interconnection layer M2 by lithography. The resist patterns 102 have a width corresponding to the odd-numbered bit line BLO, and an interval corresponding to the width of the even-numbered bit line BLE.

As shown in FIG. 66B, the resist patterns 102 are used as masks to etch the third metal interconnection layer M2 and insulating film 101, thereby forming odd-numbered bit lines BLO, and trenches 103 in the insulating film 101 between adjacent odd-numbered bit lines BLO.

As shown in FIG. 66C, second metal interconnection layers M1 are buried in the trenches 103 formed in the insulating film 101 by the above-mentioned etching, thereby forming even-numbered bit lines BLE.

Thus, the even-numbered bit lines BLE and odd-numbered bit lines BLO can be formed by performing lithography once.

The bit lines can also be manufactured by a method shown in FIGS. 67A, 67B, 67C, and 67D. That is, as shown in FIG. 67A, a resist is applied above an insulating film 101, and resist patterns 102 are formed by lithography. The resist patterns 102 have a width corresponding to an odd-numbered bit line BLO, and an interval corresponding to the width of an even-numbered bit line BLE.

As shown in FIG. 67B, trenches 103 are formed by etching the insulating film 101 by using the resist patterns 102 as masks.

As shown in FIG. 67C, a metal interconnection layer 104 is formed on the entire surface of the insulating film 101 after the resist patterns 102 are removed.

As shown in FIG. 67D, the metal interconnection layer 104 is etched to form second metal interconnection layers M1 in the trenches 103, and third metal interconnection layers M2 on the surfaces of the insulating films 101.

This manufacturing method can also simultaneously form the third metal interconnection layers M2 and second metal interconnection layers M1 by performing lithography once.

Note that in FIGS. 30A and 30B, a source line SRC and an interconnection Well for supplying a potential to a well, each of which is formed by a first metal interconnection layer M0, are set wider than word lines WL0 to WL31, thereby decreasing the wiring resistance. Therefore, a global source line GSRC and global interconnection Gwell formed by fourth metal interconnection layers M3 can be omitted.

### (Modifications)

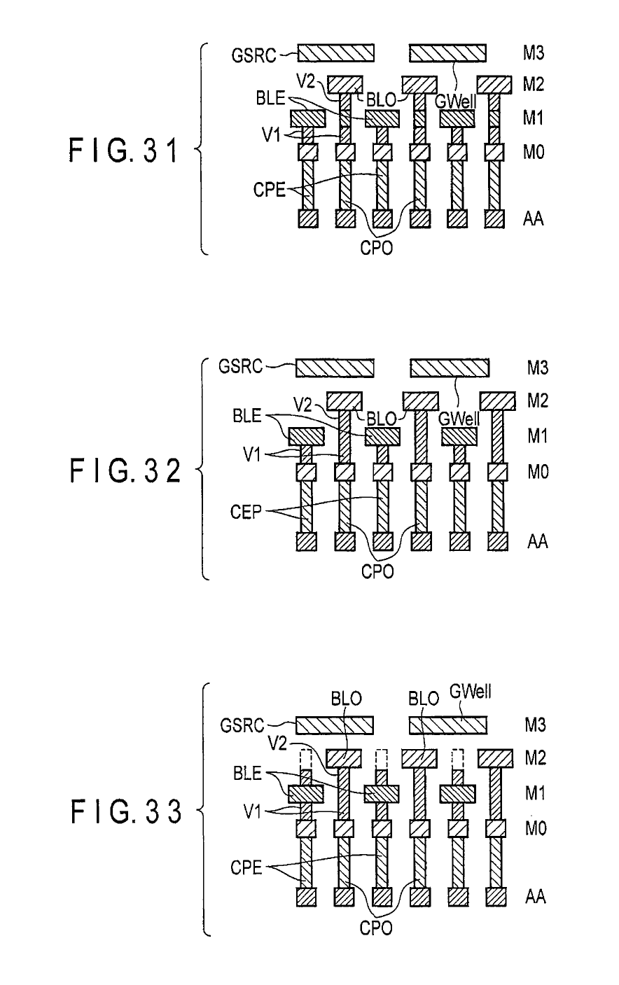

FIGS. 31, 32, 33, 34, and 35 illustrate modifications of the third embodiment. FIGS. 31, 32, and 33 are respectively modifications of FIGS. 14, 15, and 16. Referring to FIGS. 31, 32, and 33, the bit lines BLE and BLO have a width twice that of the bit lines BLE and BLO in FIGS. 14, 15, and 16.

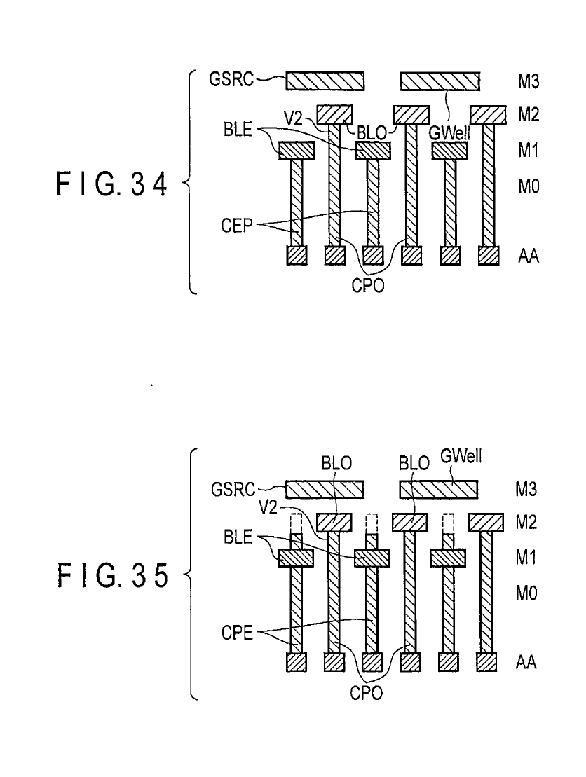

FIGS. 34 and 35 are respectively modifications of FIGS. 32 and 33. That is, the first metal interconnection layers M0 and vias V1 are omitted from the arrangements shown in FIGS. 32 and 33, and contact plugs CP connected to the bit lines BLE and BLO are formed.

More specifically, in FIG. 34, after contact plugs CP to be connected to, e.g., the bit lines BLE are formed, the bit lines BLE are formed, and, after contact plugs CP to be connected to the bit lines BLO are formed, the bit lines BLO are formed. Alternatively, it is also possible to simultaneously form the bit lines BLE and the contact plugs CP to be connected to the bit lines BLE by dual damascene, and simultaneously form the bit lines BLO and the contact plugs CP to be connected to the bit lines BLO by dual damascene.

Also, in FIG. 35, after the contact plugs CP to be connected to, e.g., the bit lines BLE are formed, the bit lines BLE are formed, and, after the contact plugs CP to be connected to the bit lines BLO are formed, the bit lines BLO are formed. Alternatively, after all the bit lines BLE and BLO are formed, the contact plugs CP to be connected to the bit lines BLE and BLO are formed at once.

These modifications can also achieve the same effects as those of the third embodiment.

### Fourth Embodiment

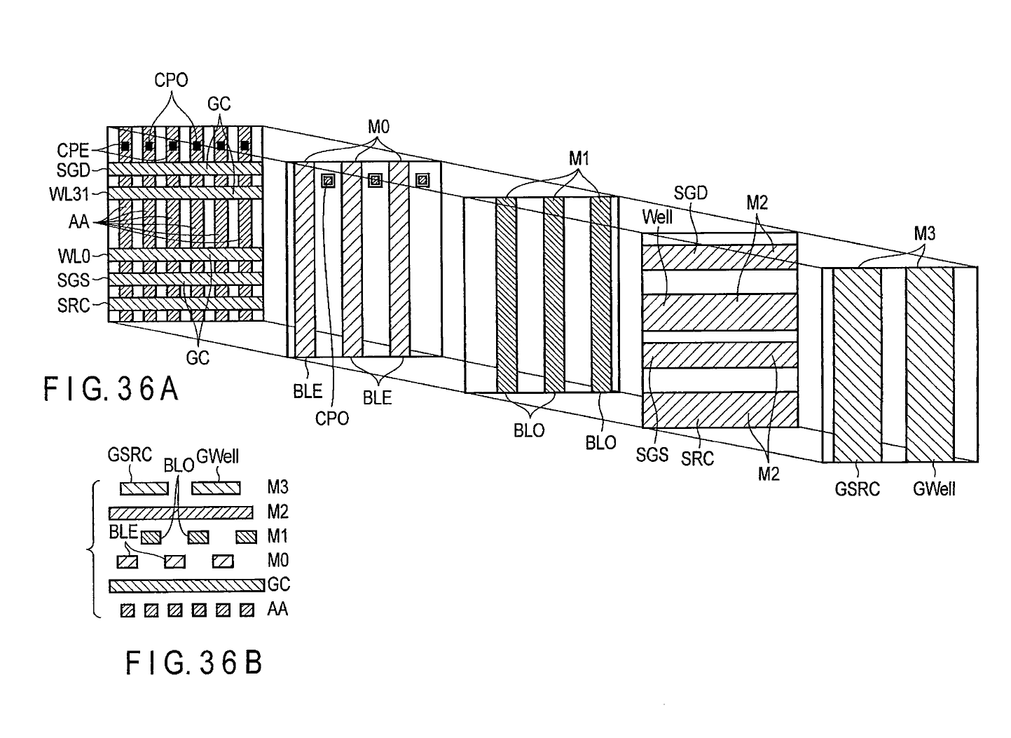

FIGS. 36A and 36B show the fourth embodiment. The fourth embodiment is a modification of the second embodiment shown in FIGS. 17A and 17B, and the same reference numerals as in FIGS. 17A and 17B denote the same parts.

In the fourth embodiment, even-numbered bit lines BLE are formed in first metal interconnection layers M0, and odd-numbered bit lines BLO are formed in second metal interconnection layers M1. A source line SRC, select lines SGS and SGD, and an interconnection Well for supplying power to a well are formed in third metal interconnection layers M2.

The difference of FIGS. 36A and 36B from FIGS. 17A and 17B is that the width of the even-numbered bit lines BLE and odd-numbered bit lines BLO is set twice that in the second embodiment. Also, the interval between the bit lines BLE is almost equal to their width. Furthermore, the interval between the bit lines BLO is almost equal to their width.

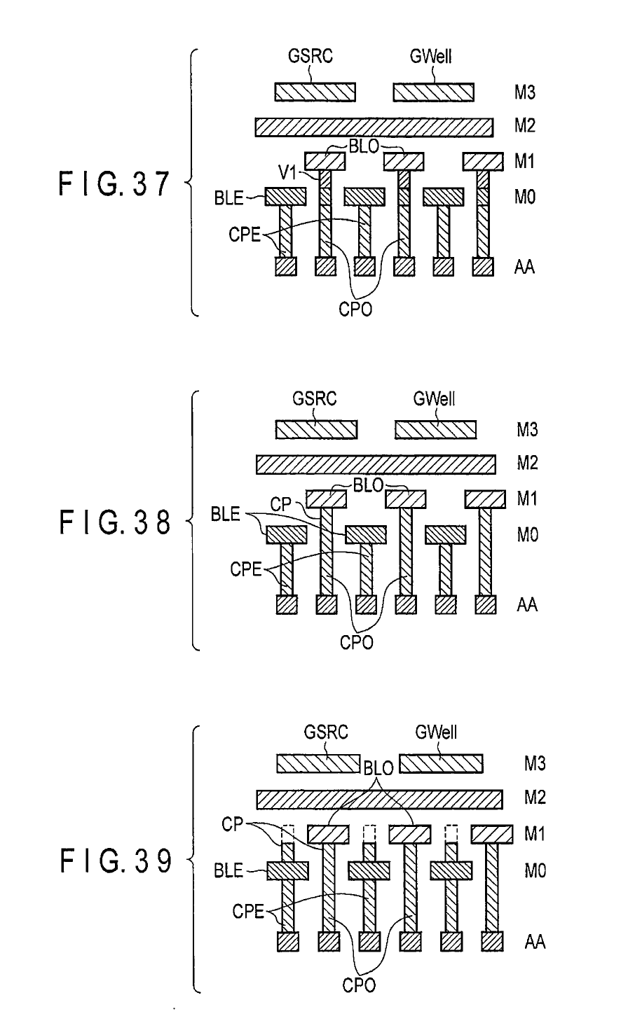

FIG. 37 shows the relationship between the bit lines BLO and BLE and contacts in the fourth embodiment. The even-numbered bit lines BLE are connected to active areas AA via contact plugs CP. The odd-numbered bit lines BLO are connected to active areas AA via contact plugs CP, the first metal interconnection layers M0, and first vias V1.

In the fourth embodiment, the width of the bit lines BLE and BLO is set twice that in the second embodiment. Therefore, the effects of the third embodiment can be obtained in addition to the effects of the second embodiment.

Also, it is possible in the fourth embodiment as well to form the even-numbered bit lines BLE and odd-numbered bit lines BLO by performing lithography once as shown in FIGS. 66A, 66B, 66C, 67A, 67B, 67C, and 67D of the third embodiment.

### (Modifications)

FIGS. 38 and 39 show modifications of the fourth embodiment, and respectively correspond to FIGS. 19 and 20. The difference of FIGS. 38 and 39 from FIGS. 19 and 20 is the width of the bit lines BLE and BLO; the width of the bit lines BLE and BLO shown in FIGS. 38 and 39 is set twice that of the bit lines BLE and BLO shown in FIGS. 19 and 20. Also, the interval between the bit lines BLE is almost equal to their width. Furthermore, the interval between the bit lines BLO is almost equal to their width.

The above-mentioned modifications can also achieve the same effects as those of the fourth embodiment.

### Fifth Embodiment

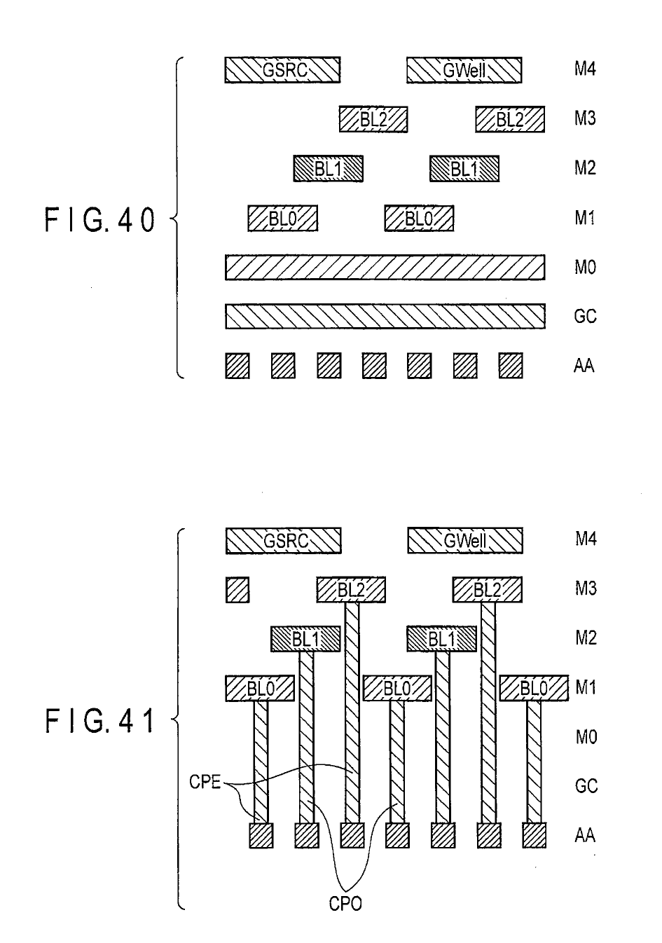

FIGS. 40 and 41 show the fifth embodiment, and

FIG. 40 shows a modification of, e.g., FIG. 27. In the fifth embodiment, bit lines have a three-layered structure, and the pitch of these bit lines is set three times that of memory cells.

That is, referring to FIGS. 40 and 41, bit lines BL0, BL1, and BL2 are respectively formed by second, third, and fourth metal interconnection layers M1, M2, and M3. The width of the bit lines BL0, BL1, and BL2 is set almost three times the width of an active area AA. The interval between the bit lines BLO is almost equal to their width. The interval between the bit lines BL1 is almost equal to their width. The interval between the bit lines BL2 is almost equal to their width. The pitch of the bit lines BL0, BL1, and BL2 is set almost three times that of the active areas AA. As shown in FIG. 41, the bit lines BL0, BL1, and BL2 are connected to the active areas AA via contact plugs CPE and CPO.

In the fifth embodiment, the bit lines BL0, BL1, and BL2 form a three-layered structure. Accordingly, the width of the bit lines BL0, BL1, and BL2 can be set almost three times that of the active areas AA, and the pitch of the bit lines BL0, BL1, and BL2 can be set almost three times that of the active areas AA. This makes it possible to further reduce the wiring resistance of the bit lines BLO, BL1, and BL2 and the capacitance between these bit lines, and decrease the CR time constant.

Furthermore, as will be described below, it is also possible to give the bit lines an n-layered structure (n is a natural number of 4 or more), and set the pitch of the bit lines n times that of memory cells, thereby further reducing the resistance and capacitance of the bit lines.

### Sixth Embodiment

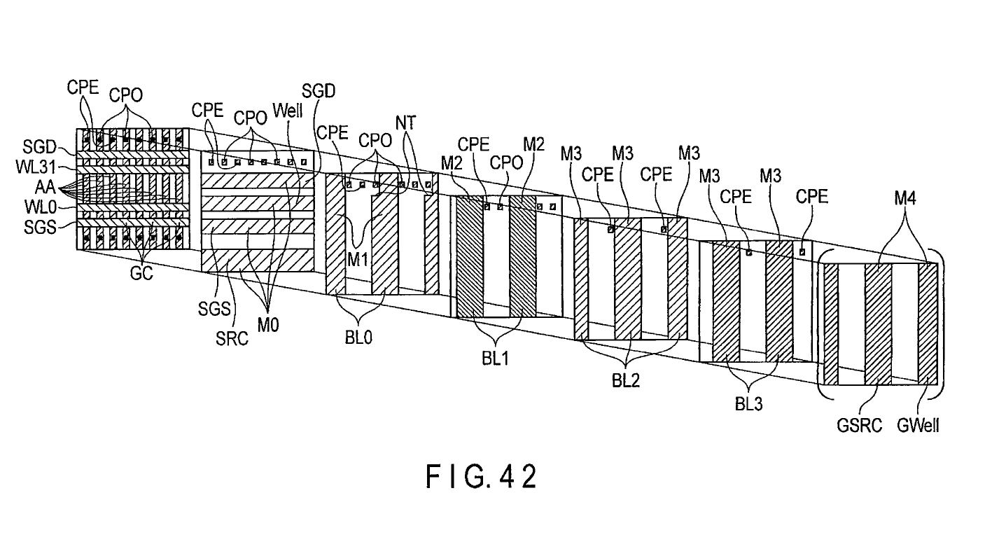

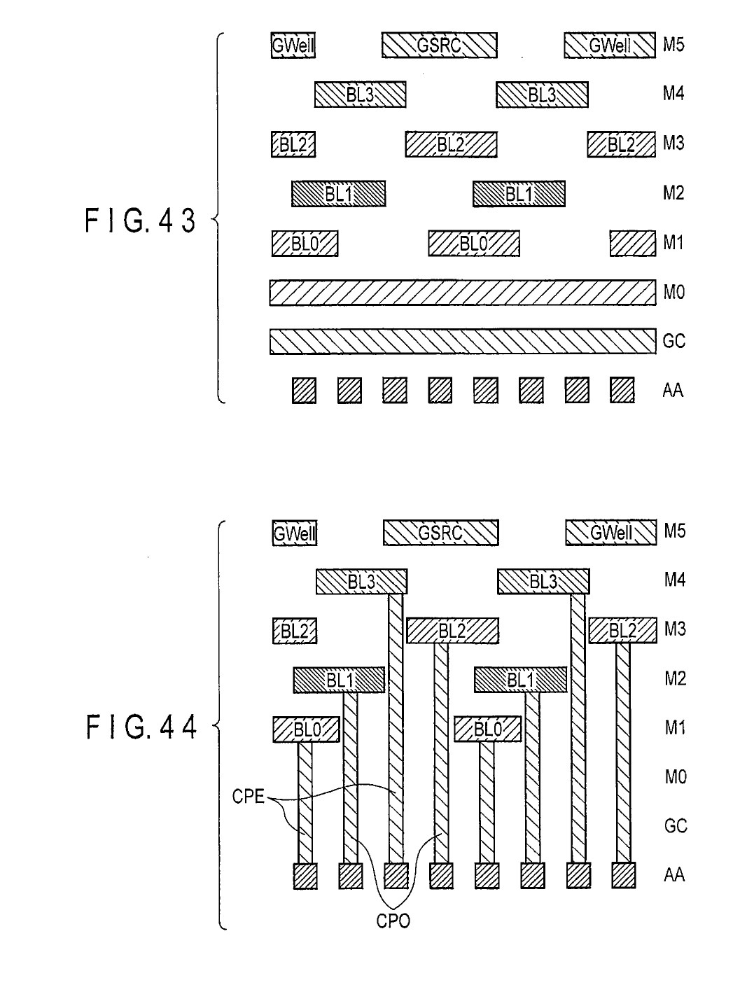

FIGS. 42, 43, and 44 show the sixth embodiment. The sixth embodiment is a modification of the third embodiment. In the sixth embodiment, bit lines have a four-layered structure, and the pitch of the bit lines is set four times that of memory cells.

Referring to FIGS. 42, 43, and 44, bit lines BL0, BL1, BL2, and BL3 are respectively formed by second, third, fourth, and fifth metal interconnection layers M1, M2, M3, and M4. The width of the bit lines BL0 to BL3 is set four times that of active areas AA. The interval between the bit lines BLO is almost equal to their width. The interval between the bit lines BL1 is almost equal to their width. The interval between the bit lines BL2 is almost equal to their width. The interval between the bit lines BL3 is almost equal to the width of the bit lines BL3. The pitch of the bit lines BLO, that of the bit lines BL1, that of the bit lines BL2, and that of the bit lines BL3 are set almost four times that of the active areas AA.

Also, as shown in FIG. 42, a notch NT is formed to secure the formation regions of contact plugs CPO to be connected to the active areas AA forming the memory cells and to the bit lines BL3. The notch NT in which, e.g., one contact plug CPO can be formed is formed in a portion of the bit line BLO formed of the second metal interconnection layer M1. Thus, it is possible to form the notch NT in the bit line BL0, and form the contact plug through the notch NT.

### (Modification)

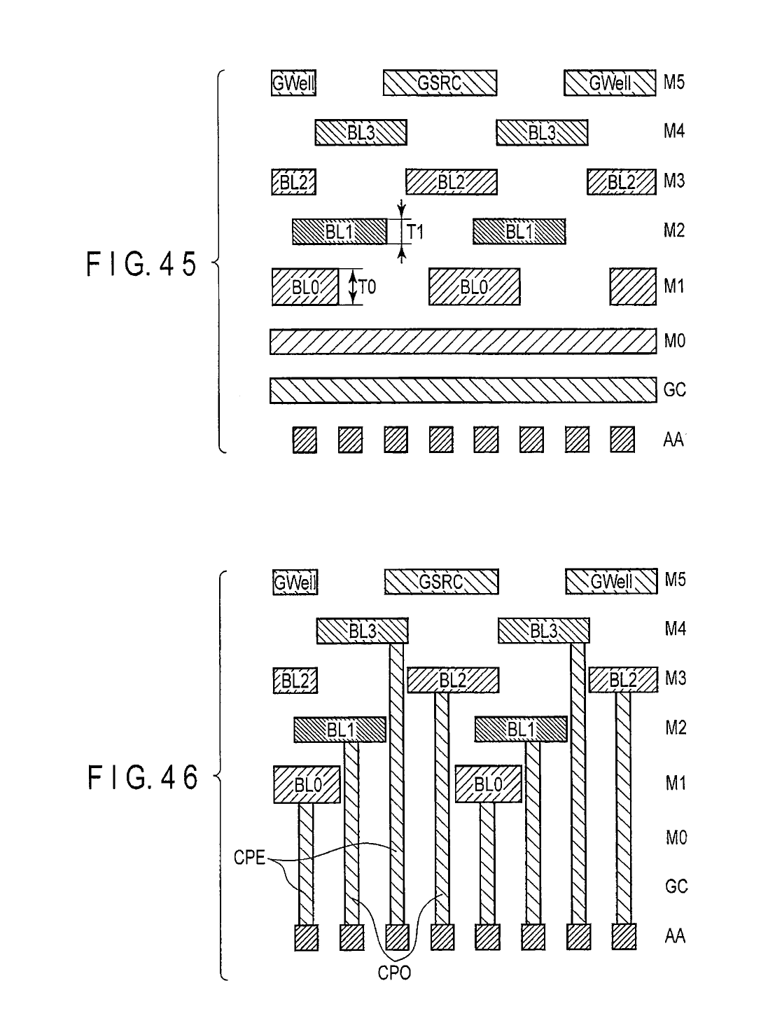

When the notch NT is formed in a portion of the bit line BL0 as described above, the wiring resistance of the bit lines BL0 may become higher than that of the bit lines BL1 to BL3. In addition, a step of processing the notch NT may be added. Accordingly, it is also possible to, e.g., make the bit line BL0 straight instead of forming the notch NT, and decrease the width of the bit line BL0 to a width with which, e.g., one contact plug CPO can be formed. However, the wiring resistance of the bit line BL0 may become higher than that of other bit lines. As shown in FIGS. 45 and 46, therefore, a film thickness TO of the bit line BL0 is set larger than a film thickness T1 of the bit lines BL1 to BL3. This can make the wiring resistance of the bit line BL0 almost equal to that of the bit lines BL1 to BL3.

Also, even when the notch NT is formed in the bit line BL0 as shown in FIG. 42, the film thickness of the bit line BL0 can be set larger than the film thickness T1 of the bit lines BL1 to BL3 in accordance with a resistance component increased by narrowing the interconnection by the notch NT.

Alternatively, contact plugs may be rearranged in gate electrodes GC or first metal interconnection layers M0 so as not to narrow the distance between the bit lines.

In this embodiment, the notch NT is formed in a portion of the bit line BL0 alone. If contact plugs cannot be formed between interconnections, however, the notches NT can also be formed in other bit lines, and each bit line in which the notch NT is formed may be made thicker in order to equalize the wiring resistances.

In the above-mentioned sixth embodiment, even when the bit lines is given the four-layered structure to set the width of the bit lines BL0 to BL3 four times that of the active areas AA and set the pitch of the bit lines four times that of the memory cells, contact plugs CPE and CPO can be formed by forming the notch NT in the bit line BL0, or making the width of the bit line BL0 smaller than that of the bit lines BL1 to BL3. Furthermore, the wiring resistance of the bit line BL0 can be made equal to that of the bit lines BL1 to BL3 by increasing the film thickness of the bit line BL0 by an amount corresponding to the decrease in width of the bit line BL0. Accordingly, the sixth embodiment can also decrease the CR time constant and increase the operating speed of a NAND flash memory.

### Seventh Embodiment

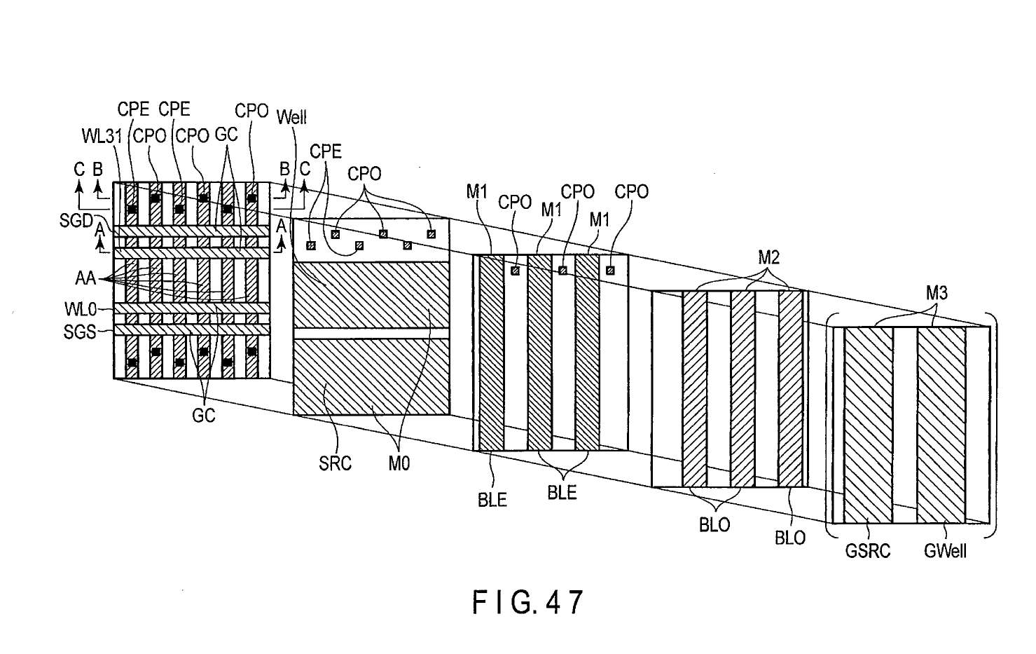

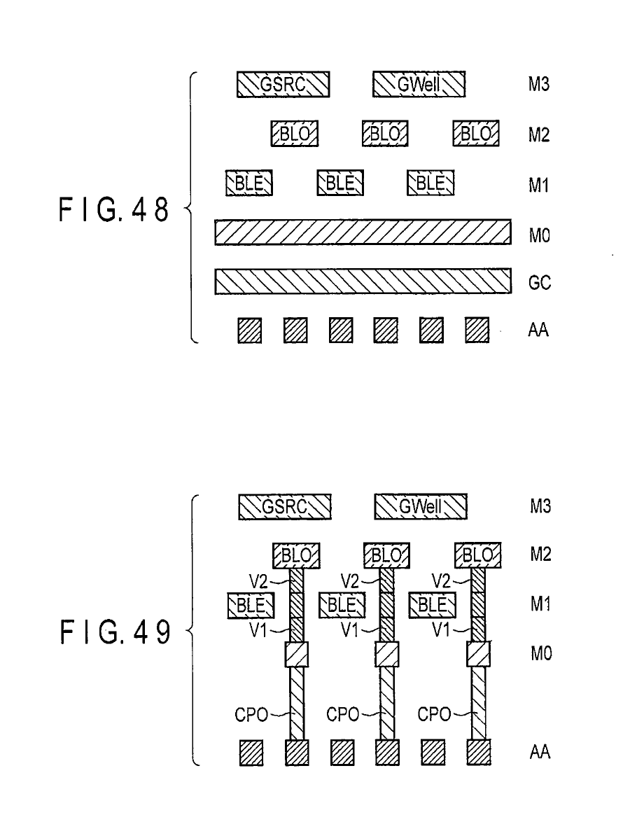

FIGS. 47 and 48 show the seventh embodiment. In the seventh embodiment as shown in FIG. 47, contact plugs CPE and CPO of bit lines are staggered. That is, the contact plugs CPE and CPO of bit lines BLE and BLO arranged in the word-line direction are alternately shifted in a direction perpendicular to word lines. The contact plugs CPE connect active areas AA to the bit lines BLE in second metal interconnection layers M1. The contact plugs CPO connect active areas AA to the bit lines BLO in third metal interconnection layers M2.

In the seventh embodiment, the contact plugs can easily be processed even when memory cells are shrunk and the distance between the bit lines is shortened.

The seventh embodiment is applicable to all the first to sixth embodiments.

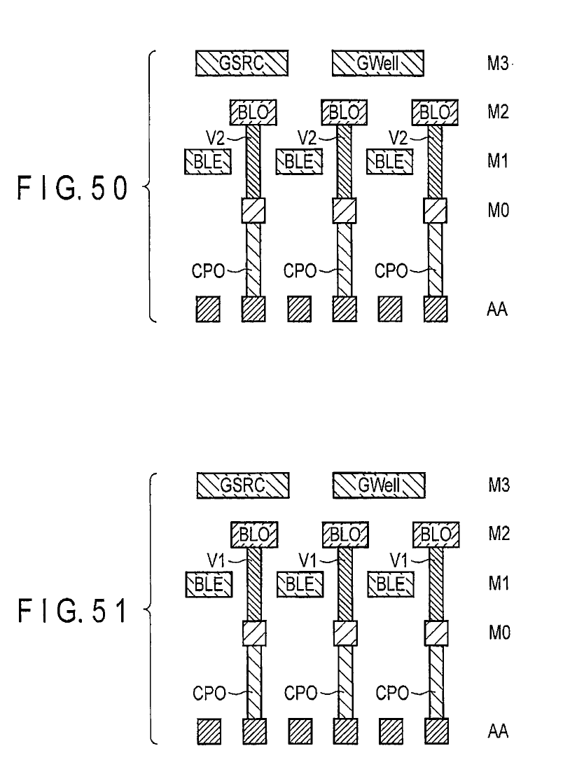

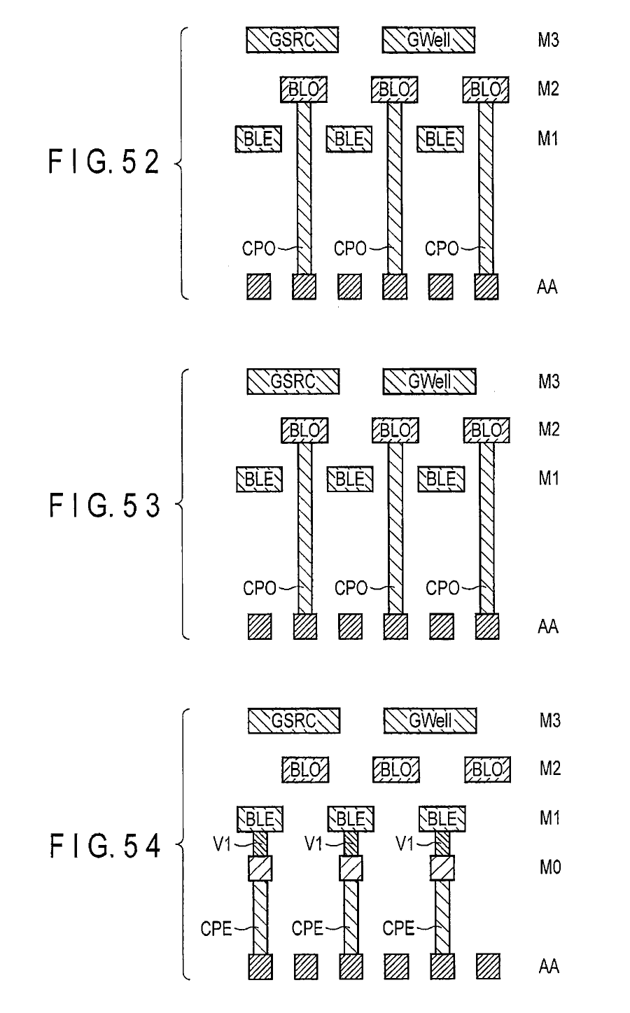

FIGS. 49, 50, 51, 52, and 53 illustrate examples of the contact plugs CPO and vias V1 and V2 for connecting the bit lines BLO and active areas AA. Since the contact positions of the bit lines BLO and BLE are staggered as described above, FIGS. 49, 50, 51, 52, and 53 do not show the contact plugs CPE and vias of the bit lines BLE. FIG. 48 is a sectional view taken along a line A-A in FIG. 47. FIGS. 49, 50, 51, 52, and 53 are sectional views taken along a line B-B in FIG. 47.

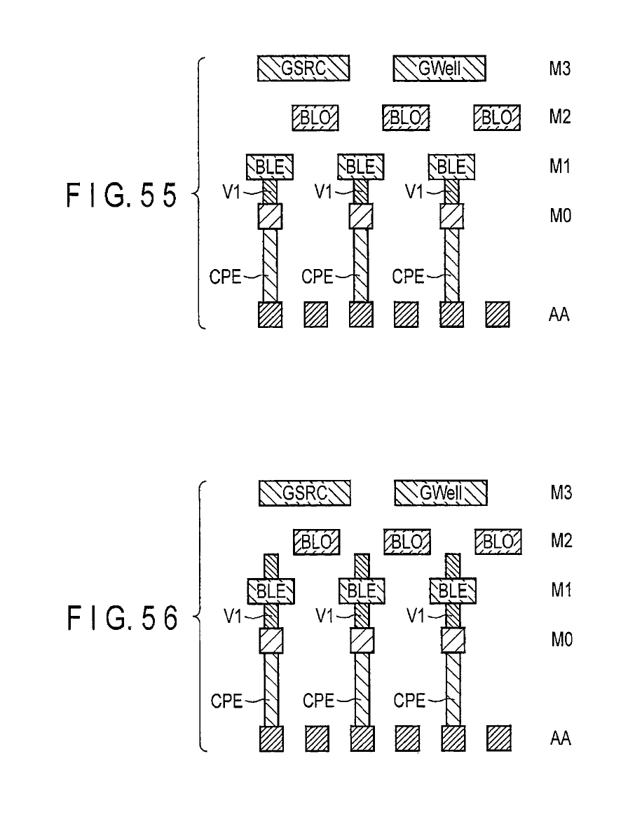

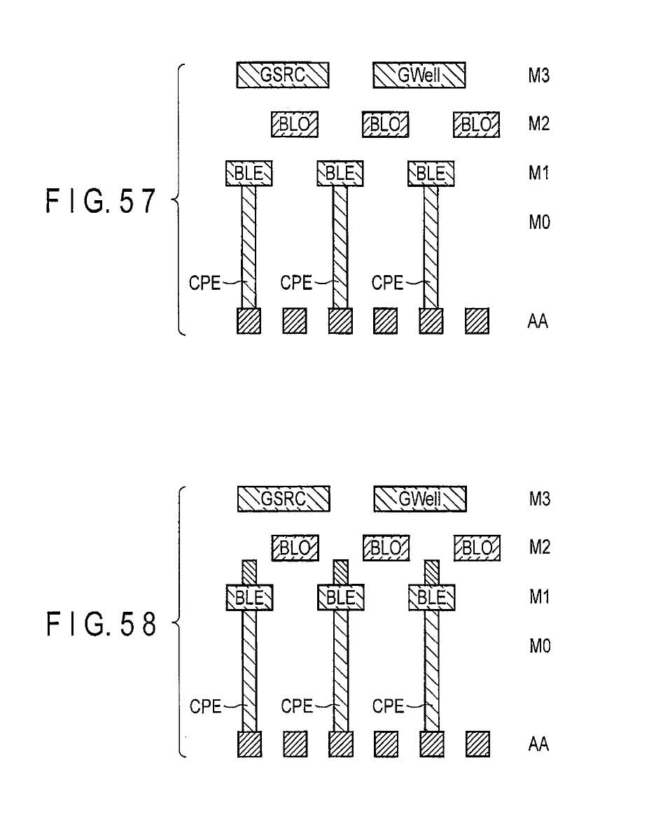

Also, FIGS. 54, 55, 56, 57, and 58 are sectional views taken along a line C-C in FIG. 47. These drawings illustrate examples of the contact plugs CPE and vias V1 and V2 for connecting the bit lines BLE and active areas AA. Since the contact positions of the bit lines BLO and BLE are staggered as described above, FIGS. 54, 55, 56, 57, and 58 do not show the contact plugs CPO and vias of the bit lines BLO.

### Eighth Embodiment

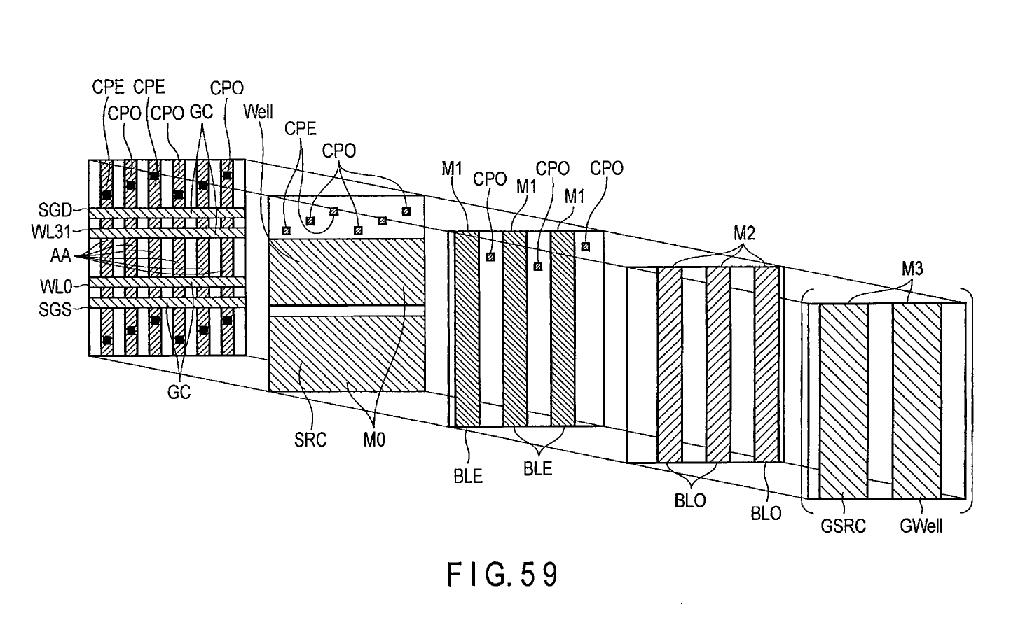

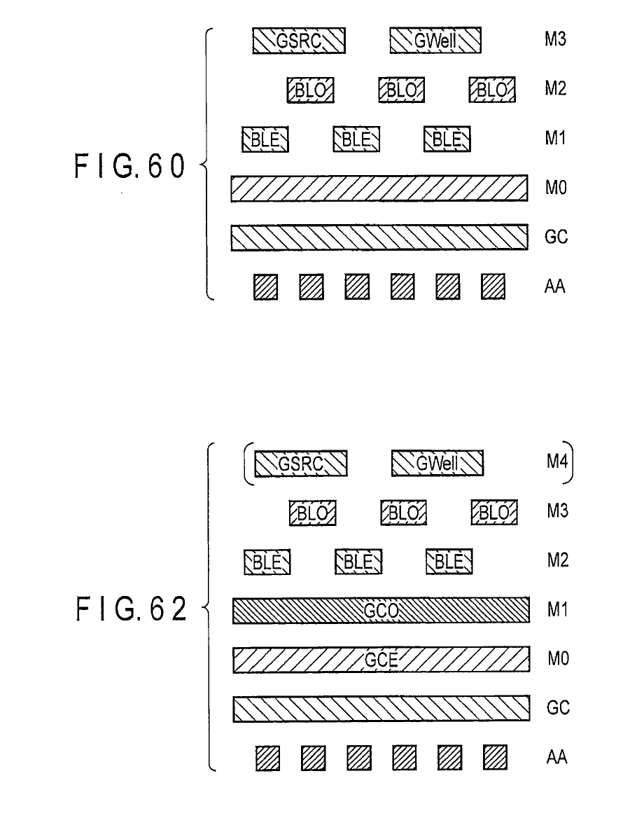

FIGS. 59 and 60 show the eight embodiment as a modification of the seventh embodiment. In the seventh embodiment, the contact plugs CPE and CPO of the bit lines BLE and BLO are alternately shifted in the direction perpendicular to the word lines.

By contrast, in the eighth embodiment shown in FIG. 59, every three contact plugs CPE of bit lines BLE and every three contact plugs CPO of bit lines BLO are alternately shifted in a direction perpendicular to word lines. The contact plugs CPE connect active areas AA and the bit lines BLE in second metal interconnection layers M1. The contact plugs CPO connect active areas AA and the bit lines BLO in third metal interconnection layers M2.

In the eighth embodiment, the contact plugs can easily be processed even when memory cells are shrunk and the distance between the bit lines is shortened, as in the seventh embodiment.

The eighth embodiment may be also applicable to all the first to sixth embodiments.

### Ninth Embodiment

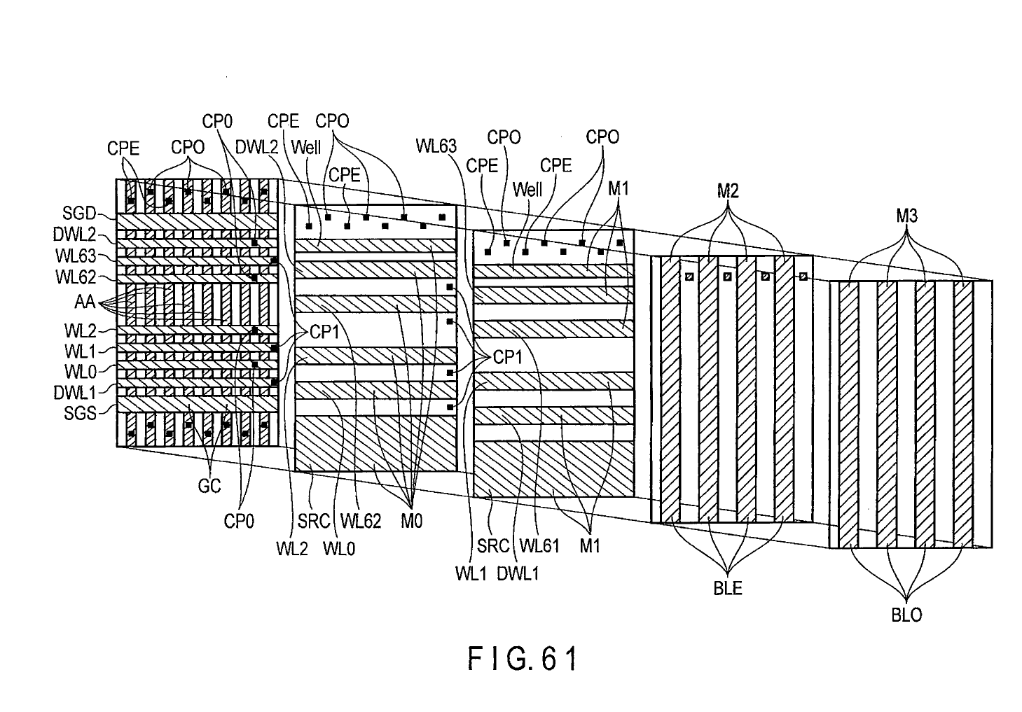

FIGS. 61 and 62 show the ninth embodiment. In the first to eighth embodiments, a plurality of metal interconnection layers are used as the bit lines in order to reduce the wiring capacitance, or the capacitance and resistance, of the bit lines. By contrast, in the ninth embodiment, a plurality of metal interconnection layers are used as word lines in order to reduce the wiring capacitance, or the capacitance and resistance, of the word lines, and these metal interconnection layers are connected to gate electrodes, thereby decreasing the wiring resistance of the gate electrodes.

That is, referring to FIG. 61, first metal interconnection layers M0 are interconnections (to be referred to as “first connecting lines” hereinafter) corresponding to even-numbered word lines WL0, WL2, . . . , WL62 and a dummy word line DWL2, and second metal interconnection layers M1 are interconnections (to be referred to as “second connecting lines” hereinafter) corresponding to a dummy word line DWL1 and odd-numbered word lines WL1, WL3, . . . , WL63. The width of the first and second connecting lines is, e.g., about twice that of the dummy word line DWL1, word lines WL0 to WL63, and dummy word line DWL2 connected to memory cells. The interval between the first connecting lines is almost equal to their width, and the interval between the second connecting lines is almost equal to their width. The pitch of the first connecting lines and that of the second connecting lines is set twice that of the dummy word line DWL1, word lines WL0 to WL63, and dummy word line DWL2.

The even-numbered word lines WL0, WL2, . . . , WL62 and dummy word line DWL2 connected to the memory cells are respectively connected to corresponding first connecting lines via contact plugs CP0. The dummy word line DWL1 and odd-numbered word lines WL1, WL3, . . . , WL63 connected to the memory cells are respectively connected to corresponding second connecting lines via contact plugs CP1.

To facilitate processing the contacts, the contact plugs CP0 and CP1 may also be staggered in a direction in which the word lines run.

In the above-mentioned ninth embodiment, the even-numbered word lines WL0, WL2, . . . , WL62 and dummy word line DWL2 connected to the memory cells are connected, via the contact plugs CP0, to the first connecting lines wider than the word lines WL0, WL2, . . . , WL62 and dummy word line DWL2. Also, the dummy word line DWL1 and odd-numbered word lines WL1, WL3, . . . , WL63 connected to the memory cells are connected, via the contact plugs CP1, to the second connecting lines wider than the dummy word line DWL1 and odd-numbered word lines WL1, WL3, . . . , WL63. This makes it possible to reduce the wiring resistance of the dummy word line DWL1, word lines WL0 to WL63, and dummy word line DWL2 connected to the memory cells. Since the voltage drop across the word lines can be suppressed, therefore, it is possible to increase the length of the word lines, and prevent so-called plane division of dividing a memory cell array into a plurality of portions.

Note that as shown in FIG. 61, a source line SRC can be formed of the first metal interconnection layer M0. The source line SRC can also be formed by using a plurality of metal interconnection layers. This makes it possible to decrease the resistance of the source line.

Note also that a plurality of metal interconnection layers are used for both the word lines and bit lines in the ninth embodiment, but it is also possible to apply a plurality of metal interconnection layers to the word lines alone. In addition, a plurality of metal interconnection layers can be used instead of two layers alone.

It is also possible to practice the first to ninth embodiments by combining a plurality of embodiments.

Furthermore, the first to ninth embodiments can be applied not only to a NAND flash memory that stores two bits in one memory cell, but also to a NAND flash memory that stores three or more bits in one cell.

In the third to ninth embodiments, the uppermost metal interconnection layers are used as the well and source line. Since, however, the first metal interconnection layers M0 or second metal interconnection layers M1 are also used as the well and source line, the uppermost metal interconnection layers are not always necessary and may also be omitted.

### (Modification)

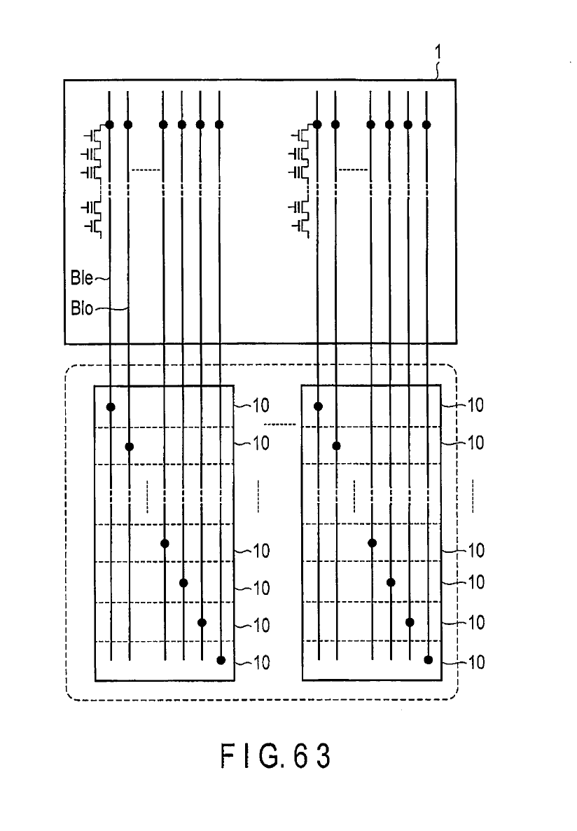

FIG. 63 shows details of the connections between the bit lines and data storage circuits shown in FIG. 2.

Referring to FIG. 2, the data storage circuits connected to the bit lines are preferable formed at the pitch of the bit lines, but this layout is difficult. As shown in FIG. 63, therefore, the data storage circuits 10 having an area corresponding to the pitch of a plurality of bit lines and being equal in number to a plurality of bit lines are arranged in the bit line direction.

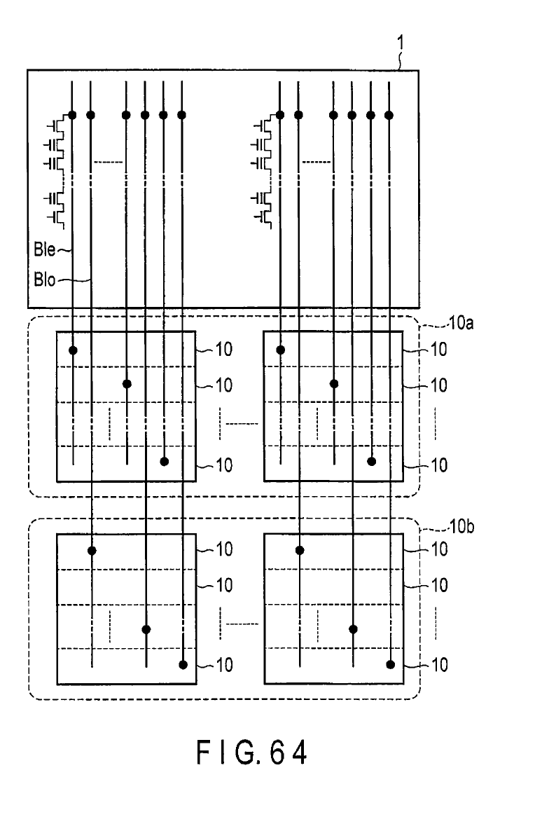

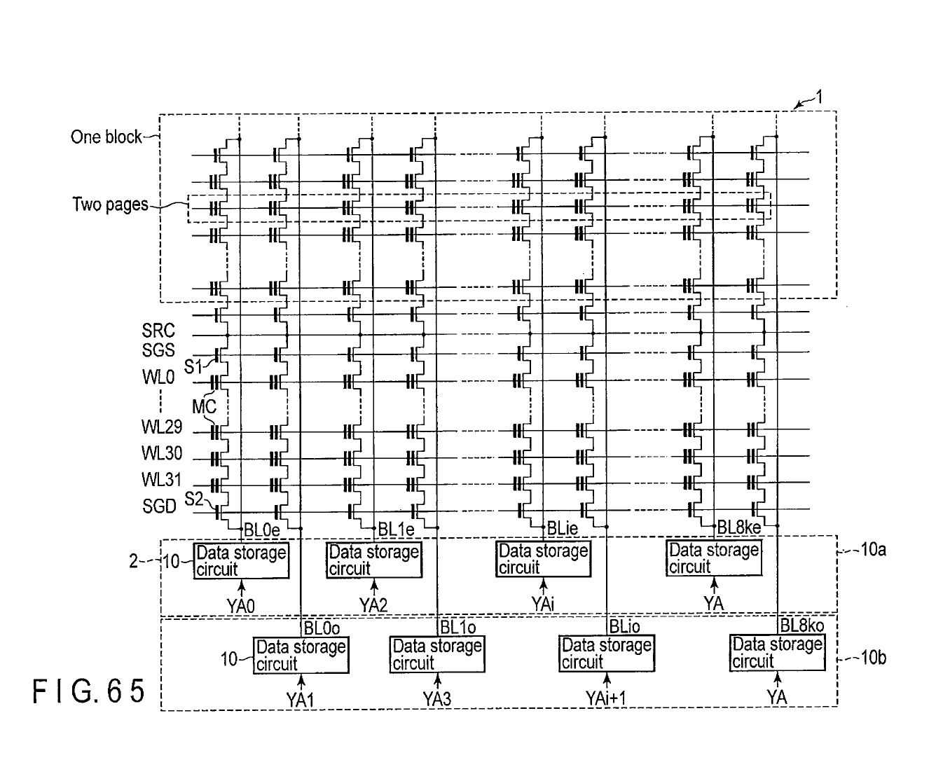

By contrast, the bit lines are formed by using two or more interconnection layers in each of the above-mentioned embodiments. Accordingly, the data storage circuits are arranged as shown in FIGS. 64 and 65.

That is, as shown in FIGS. 64 and 65, when bit lines are formed by two layers, a plurality of first data storage circuits 10 connected, as a first data storage circuit group 10a, to even-numbered bit lines (lower bit lines) BLe are arranged adjacent to a memory cell array 1, and a second data storage circuit group 10b connected to odd-numbered bit lines (upper bit lines) BLo is formed adjacent to the first data storage circuit group 10a. The first and second data storage circuit groups 10a and 10b each include a plurality of data storage circuits 10. The odd-numbered bit lines BLo are arranged to pass above the first data storage circuit group 10a connected to the even-numbered bit lines BLe.

This arrangement can facilitate the layout of the first and second data storage circuit groups 10a and 10b.

When using three layers of bit lines, first, second, and third data storage circuits connected to these bit line layers are arranged in order from the vicinity of the memory cell array 1. That is, a plurality of first data storage circuits connected to bit lines of a first layer as a lowermost layer are formed adjacent to the memory cell array, a plurality of second data storage circuits connected to bit lines of a second layer as an intermediate layer are arranged adjacent to the first data storage circuits, and a plurality of third data storage circuits connected to bit lines of a third layer as an uppermost layer are arranged adjacent to the second data storage circuits.

The bit lines of the first layer are connected to the plurality of first data storage circuits, and the bit lines of the second layer are connected to the second data storage circuits by passing above the plurality of first data storage circuits. The bit lines of the third layer are connected to the third data storage circuits by passing above the first and second data storage circuits.

This arrangement can facilitate the layout of the first, second, and third data storage circuits connected to the bit lines having the three-layered structure.

Furthermore, even when forming four or more layers of bit lines, the above-mentioned arrangement can facilitate the layout of a plurality of data storage circuits connected to these bit lines.

The data storage circuits can also be arranged for the bit line structures shown in FIGS. 3 and 29 by applying the same layout as described above.

Also, in each of the above-mentioned embodiments and modifications, the data storage circuits are arranged on one side of the memory cell array. However, if it is difficult to arrange the data storage circuits on one side of the memory cell array alone, it is also possible to arrange the data storage circuits on the two sides of the memory cell array in the bit line direction, connect half of the bit lines to the data storage circuits on one side of the memory cell array, and connect the other half of the bit lines to the data storage circuits on the other side of the memory cell array.

In this arrangement, of two layers of bit lines, for example, only first bit lines of the lower layer are connected to data storage circuits, and second bit lines of the upper layer are passed above the data storage circuits connected to the first bit lines, and connected to data storage circuits. This can facilitate the layout of the data storage circuits.

Note that the arrangements shown in FIGS. 64 and 65 may be applicable to all embodiments.

### (10th Embodiment)

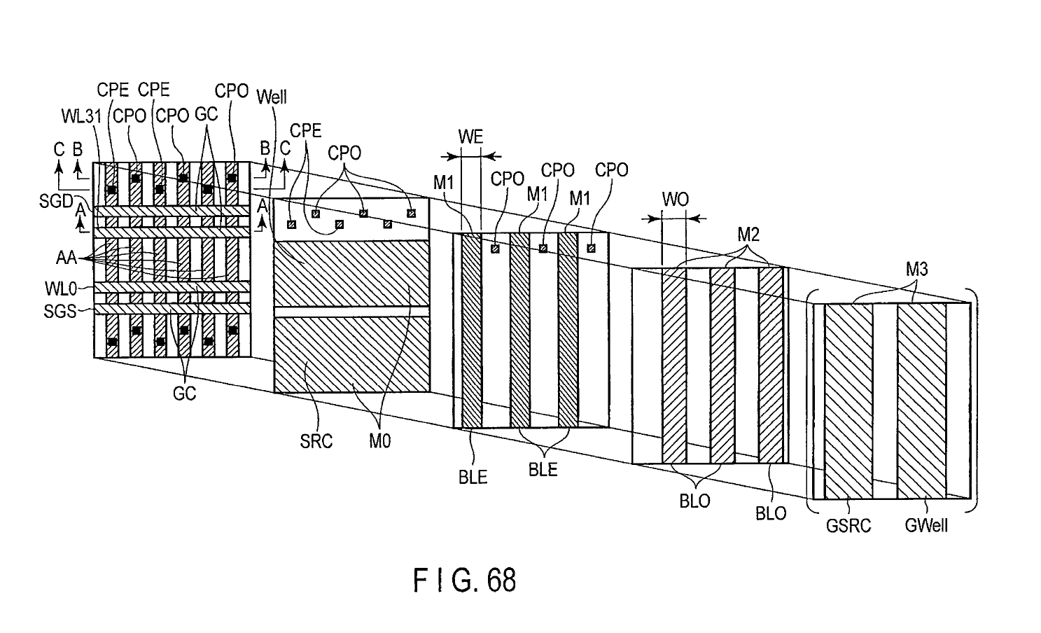

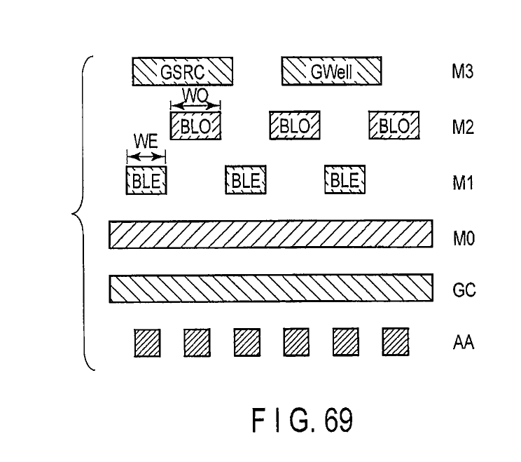

FIGS. 68 and 69 show the 10th embodiment. FIG. 69 is a sectional view taken along a line A-A in FIG. 68. The 10th embodiment is a modification of the third embodiment, and the same reference numerals as in the third embodiment denote the same parts.

In the third embodiment shown in FIGS. 30A and 30B and the seventh embodiment shown in FIG. 47, the width and space of the bit lines BLE formed by the second metal interconnection layers M1 are almost the same. Since, however, vias to be connected to the bit lines BLO of the third metal interconnection layers M2 is formed between the bit lines BLE formed by the second metal interconnection layers M1, it is preferable to widen the space between the bit lines BLE.

In the 10th embodiment as shown in FIGS. 68 and 69, therefore, a width WE of bit lines BLE formed by second metal interconnection layers M1 is made smaller than that in the third embodiment, thereby widening the space between adjacent bit lines BLE. In this case, a width WO of bit lines BLO formed by third metal interconnection layers M2 can be made larger than the width WE of the bit lines BLE. That is, the space between the bit lines BLO need not be widened because no via need be formed in this space. It is also possible to make the space between the bit lines BLO equal to the width WE of the bit lines BLE. In this case, width WO=space between bit lines BLE, and width WE=space between bit lines BLO. That is, the pitch of the bit lines BLE formed by the second metal interconnection layers M1 and that of the bit lines BLO formed by the third metal interconnection layers M2 can be made equal to each other.

When widening the space between the bit lines BLE and decreasing the width WE of the bit lines BLE of the second metal interconnection layers M1, processing for forming the second metal interconnection layers M1 and processing for forming the third metal interconnection layers M2 are used. However, the pitch of the second and third metal interconnection layers M1 and M2 is wider than that of diffusion layers AA. This can facilitate processing the second and third metal interconnection layers M1 and M2.

When the width WE of the bit lines BLE is made smaller than the width WO of the bit lines BLO, the time constant of the bit lines BLE becomes different from that of the bit lines BLO. That is, the resistance of the narrow width bit lines BLE is higher than that of the wide width bit lines BLO, so the time constant of the narrow width bit lines BLE is larger than that of the wide width bit lines BLO. In programming, read, and verify-read, therefore, when setting the bit lines BLE and bit lines BLO at any potential, the charge timing of the bit lines BLE lags behind that of the bit line BLO. Since this shifts current peaks when charging the bit lines BLE and bit lines BLO, the current peak of the semiconductor memory device can be suppressed.

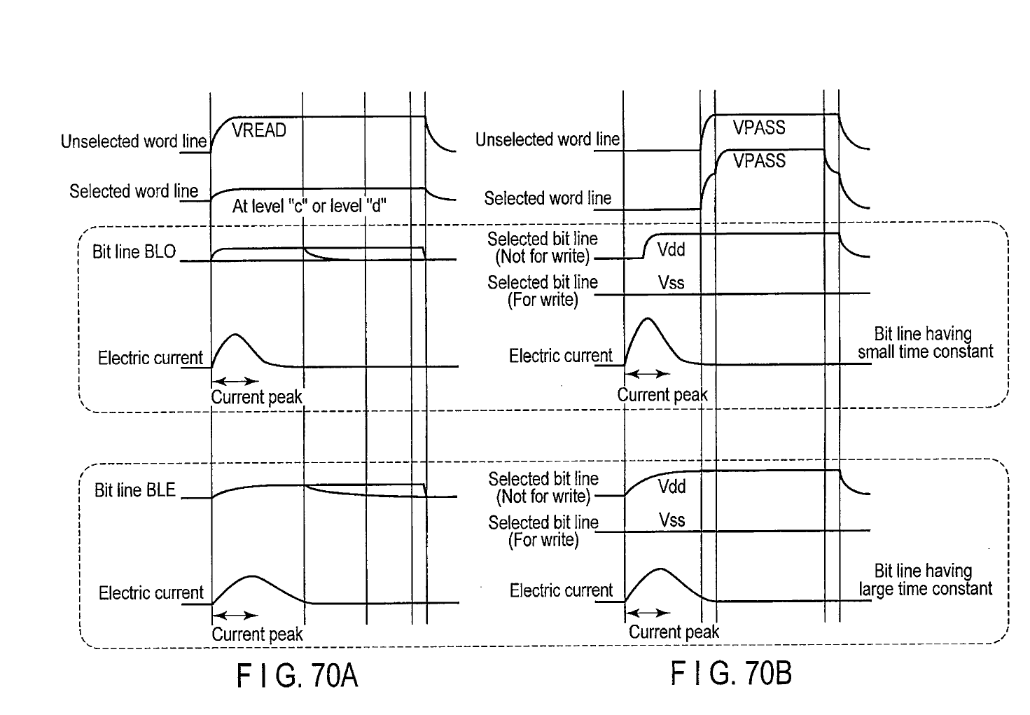

FIG. 70A shows the voltage waveforms of the individual parts in read-verify-read, and FIG. 70B shows the voltage waveforms of the individual parts in programming. Referring to FIGS. 70A and 70B, the bit lines BLE having a large time constant take a long time to reach the any potential, when compared to the bit lines BLO having a small time constant. Therefore, it is also possible to charge the bit lines BLE having a large time constant first, and, after time passes, charge the bit lines BLO having a small time constant. Furthermore, it is possible to change the start time of an operation of sensing the potentials of the bit lines BLO and bit lines BLE.

This can be achieved by changing the operation timings of signals connected to the data storage circuits 10, 10a, and 10b shown in FIGS. 2, 3, 29, 63, 64, and 65.

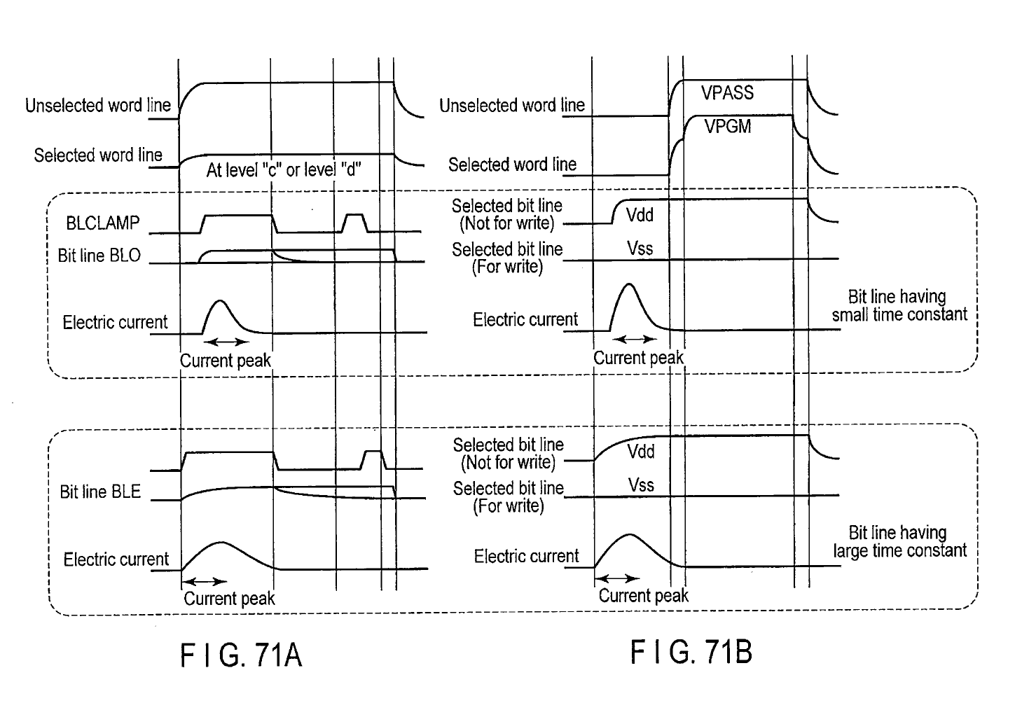

More specifically, in read-verify-read and programming as shown in FIGS. 71A and 71B, a signal BLCLAMP for connecting the data storage circuits 10, 10a, and 10b to the bit lines have different timings for the bit lines BLO having a small time constant and the bit lines BLE having a large time constant. That is, the signal BLCLAMP for connecting the bit lines BLO having a small time constant is changed to High level later than the signal BLCLAMP for connecting the bit lines BLE having a large time constant. By thus changing the activation timing of the signal BLCLAMP, the current peaks when charging the bit lines BLE and bit lines BLO can be shifted.

In the above-mentioned 10th embodiment, the width of the bit lines BLE formed by the second metal interconnection layers M1 is made smaller than that of the bit lines BLO formed by the third metal interconnection layers M2, thereby making the time constants of the bit lines BLE and bit lines BLO different. In addition, the activation timing of the signal BLCLAMP for connecting the bit lines BLO to the data storage circuits 10, 10a, and 10b is delayed from that of the signal BLCLAMP for connecting the bit lines BLE to the data storage circuits 10, 10a, and 10b. Since this makes it possible to shift current peaks when charging the bit lines BLE and bit lines BLO, the peak current of the semiconductor memory device can be suppressed.

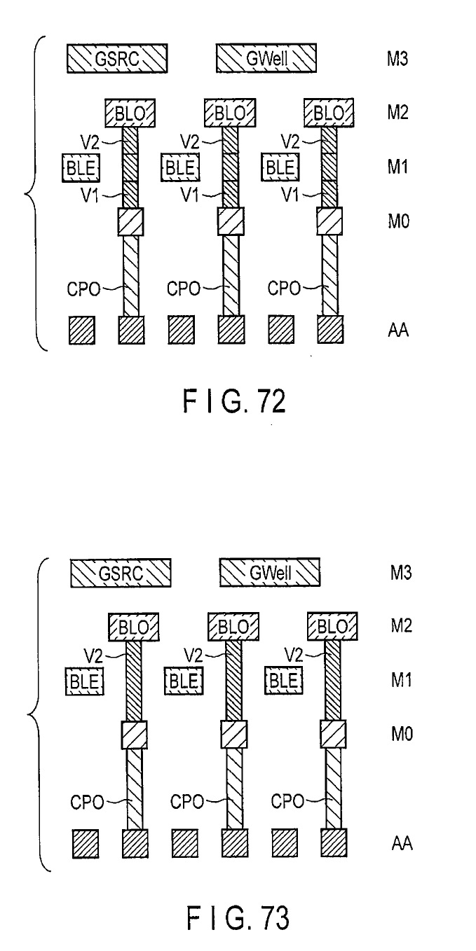

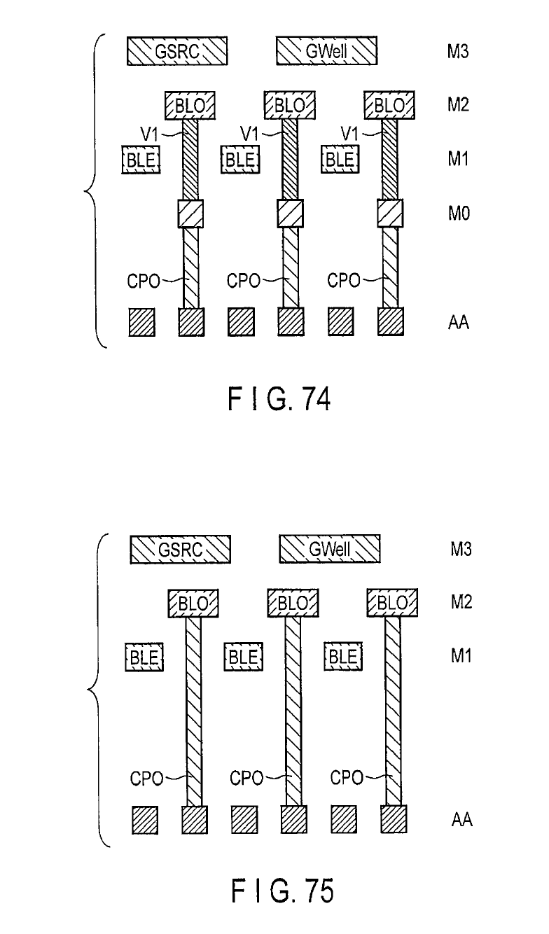

FIGS. 72, 73, 74, and 75 are sectional views taken along a line B-B in FIG. 68, and show examples of contact plugs CPO and vias V1 and V2 for connecting the bit lines BLO to the active areas AA. The contact positions of the bit lines BLO and bit lines BLE are staggered as in the seventh embodiment, so FIGS. 72, 73, 74, and 75 do not show the contact plugs and vias of the bit lines BLE.

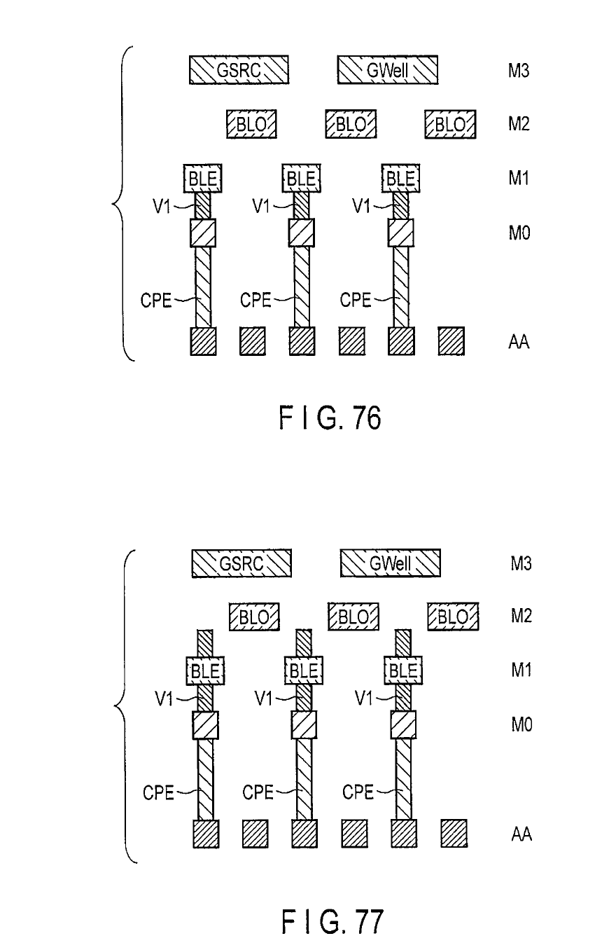

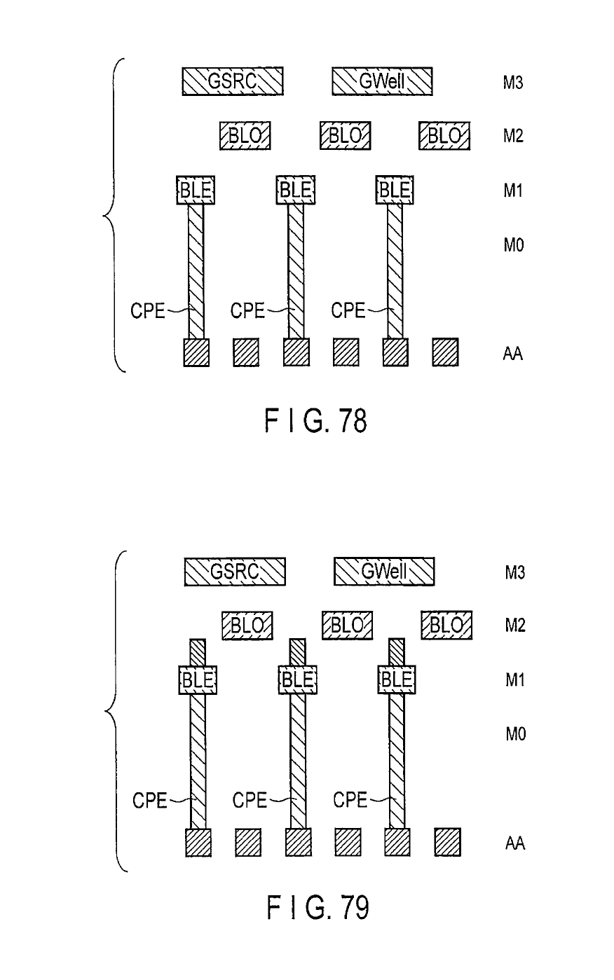

Also, FIGS. 76, 77, 78, and 79 are sectional views taken along a line C-C in FIG. 68, and show examples of contact plugs CPE and vias V1 and V2 for connecting the bit lines BLE to the active areas AA. Since the contact positions of the bit lines BLO and bit lines BLE are staggered as described above, FIGS. 76, 77, 78, and 79 do not show the contact plugs and vias of the bit lines BLO.

Note that in the 10th embodiment, the time constant of the bit lines BLE formed by the second metal interconnection layers M1 is made larger than that of the bit lines formed by the third metal interconnection layers M2. However, since the space between the bit lines formed by the second metal interconnection layers M1 is wide, the capacitance between the bit lines may be small, and the time constant may also be small. In this case, the operation timings of the signals to be connected to the data storage circuits 10, 10a, and 10b can properly be changed in accordance with these conditions.

Also, if, for the convenience of processing, the width of the bit lines BLE formed by the second metal interconnection layers M1 and that of the bit lines BLO formed by the third metal interconnection layers M2 have the relationship opposite to that of the embodiment, the operation timings of the signals can be changed in accordance with the time constants of the bit lines.

### (11th Embodiment)

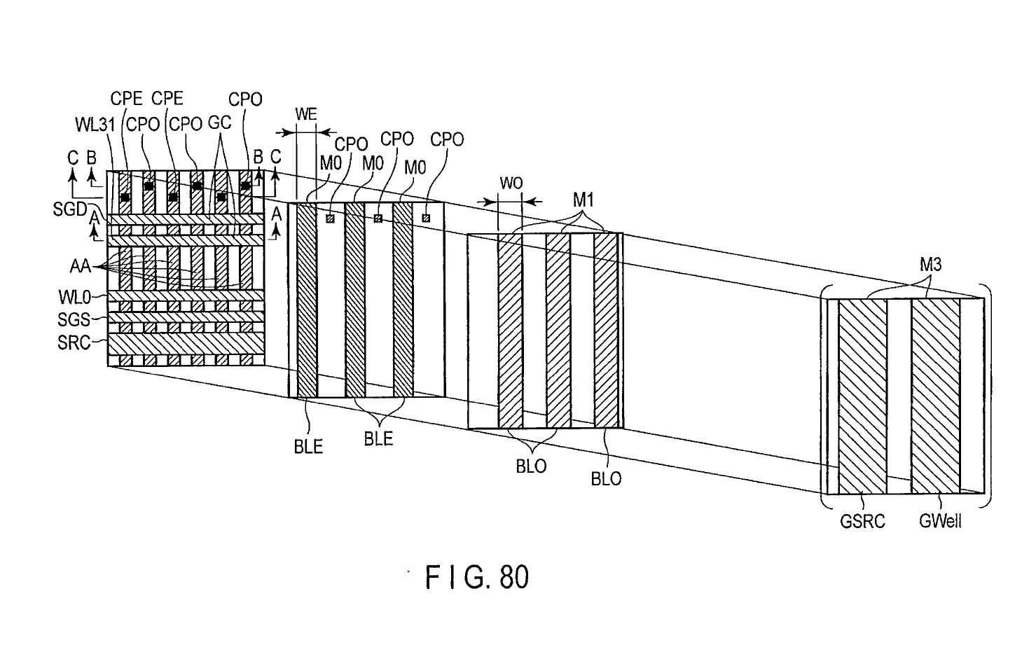

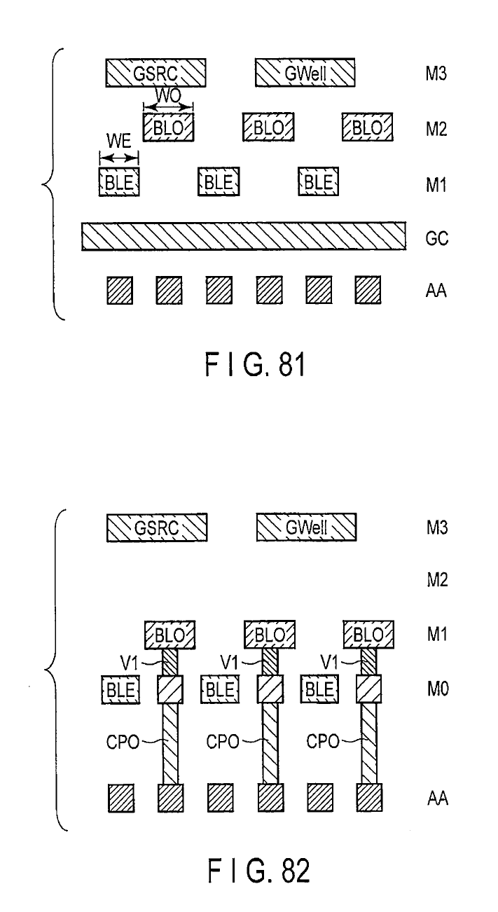

FIGS. 80 and 81 show the 11th embodiment. FIG. 81 is a sectional view taken along a line A-A in FIG. 80. The 11th embodiment is a modification of the fourth embodiment, and the same reference numerals as in the fourth embodiment denote the same parts.

In the fourth embodiment shown in FIG. 36, the width and space of the bit lines BLE formed by the first metal interconnection layers M0 are almost the same.

By contrast, in the 11th embodiment shown in FIGS. 80 and 81, a width WE of bit lines BLE formed by first metal interconnection layers M0 is made smaller than that in the fourth embodiment shown in FIG. 36, thereby widening the space between adjacent bit lines BLE. That is, the width WE of the bit lines BLE is set smaller than a width WO of bit lines BLO. This widens a space for arranging contact plugs CPO to be connected to the bit lines BLO formed by second metal interconnection layers M1.

Although a width of the bit lines BLO can also be narrowed like a width of the bit lines BLE, it is unnecessary to widen the space by decreasing the width of the bit lines BLO because no vias need be formed between them. It is also possible to make the space between the bit lines BLO equal to the width WE of the bit lines BLe. In this case, width WO=space between bit lines BLE, and width WE=space between bit lines BLO. That is, it is possible to make the pitch of the bit lines BLE formed by the second metal interconnection layers M1 equal to that of the bit lines BLO formed by third metal interconnection layers M2.

When decreasing the width WE of the bit lines BLE of the first metal interconnection layers M0 by widening the space between the bit lines BLE, processing of forming the first metal interconnection layers M0 and processing of forming the second metal interconnection layers M1 are used. However, the pitch of the first and second metal interconnection layers M0 and M1 is wider than that of diffusion layers AA. This makes it possible to facilitate processing the second and third metal interconnection layers M1 and M2.

When the width WE of the bit lines BLE is made smaller than the width WO of the bit lines BLO as described above, the time constants of the bit lines BLE and BLO become different from each other as in the 10th embodiment. As in the 10th embodiment, therefore, in programming, read, and verify-read, a signal BLCLAMP for connecting the bit lines BLO having a small time constant is set at High level after a signal BLCLAMP for connecting the bit lines BLE having a large time constant. By thus shifting the activation timings of the signals BLCLAMP, a current peak when charging the bit lines BLE and that when charging the bit lines BLO can be shifted. This makes it possible to suppress the peak current of the semiconductor memory device.

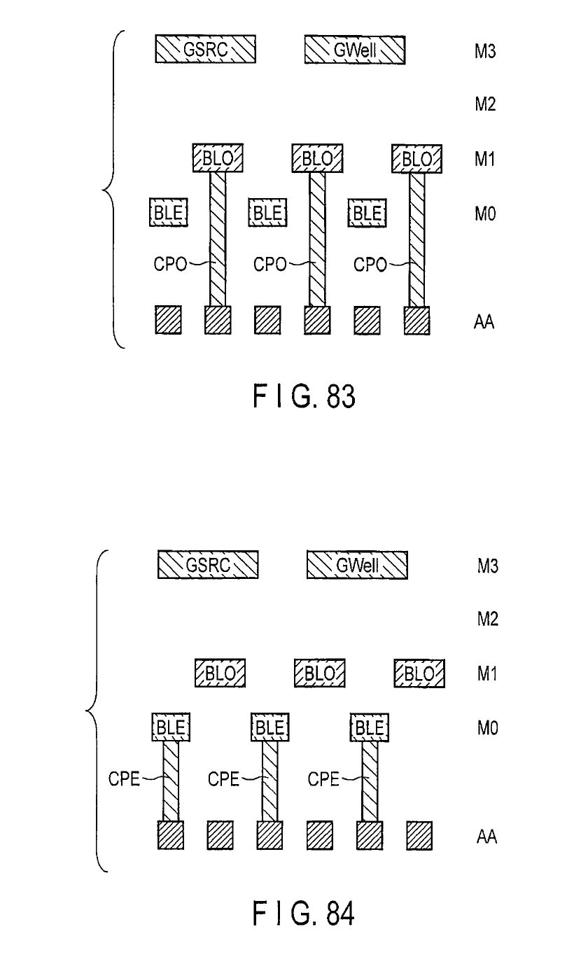

FIGS. 82 and 83 are sectional views taken along a line B-B in FIG. 80, and illustrate examples of contact plugs CPO and vias V1 for connecting the bit lines BLO and active areas AA. Since the contact positions of the bit lines BLO and those of the bit lines BLE are staggered as in the seventh and 10th embodiments, FIGS. 82 and 83 do not show contact plugs CPE and vias of the bit lines BLE.

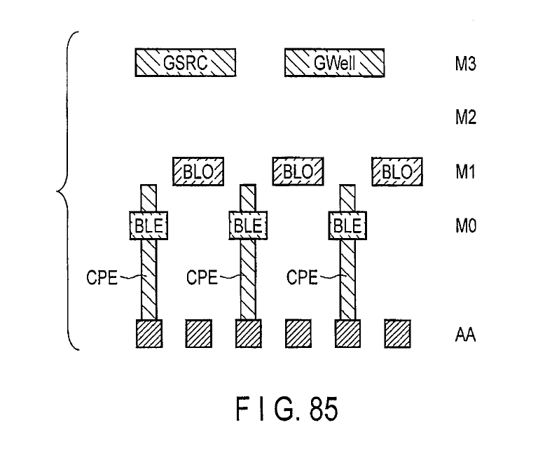

Also, FIGS. 84 and 85 are sectional views taken along a line C-C in FIG. 80, and illustrate examples of contact plugs CPE for connecting the bit lines BLE and active areas AA. Since the contact positions of the bit lines BLE and those of the bit lines BLO are staggered as described above, FIGS. 84 and 85 do not show the contact plugs CPO and vias V1 of the bit lines BLO.

The 11th embodiment described above can also achieve the same effects as those of the 10th embodiment.

Note that in the 11th embodiment, the time constant of the bit lines BLE formed by the first metal interconnection layers M0 is made larger than that of the bit lines formed by the second metal interconnection layers M1. Since, however, the space between the bit lines formed by the first metal interconnection layers M0 is wide, the capacitance between the bit lines is small, and the time constant is also small in some cases. In this case, the operation timings of signals connected to data storage circuits 10, 10a, and 10b can appropriately be changed in accordance with these conditions.

Note also that if, for the convenience of processing, the width of the bit lines BLE formed by the first metal interconnection layers M0 and that of the bit lines BLO formed by the second metal interconnection layers M1 have an opposite relationship, the operation timings of the signals can be changed in accordance with the time constants of the bit lines.

### (12th Embodiment)

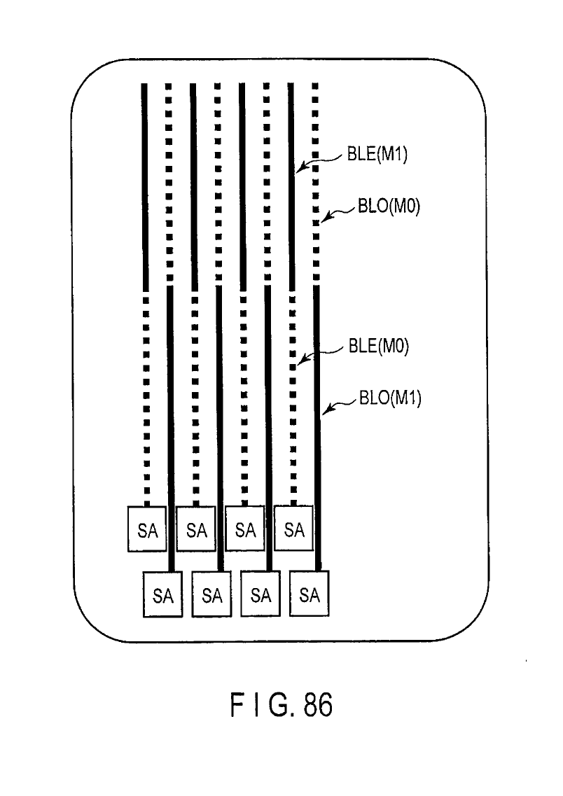

FIG. 86 shows the 12th embodiment.

When forming even-numbered bit lines BLE and odd-numbered bit lines BLO in different metal interconnections as in each of the above-mentioned embodiments, the line widths or line heights of the even-numbered bit lines BLE and odd-numbered bit lines BLO may become different due to processing variations or the like. This sometimes makes the signal delay of the bit lines BLE in the first layer and that of the bit lines BLO in the second layer different.

As shown in FIG. 86, therefore, first metal interconnection layers M0 and second metal interconnection layers M1 of the even-numbered bit lines BLE and odd-numbered bit lines BLO are switched in the central portions of the bit lines in the longitudinal direction.

More specifically, half portions of the even-numbered bit lines BLE on the side of sense amplifiers SA (data storage circuits) are formed by the first metal interconnection layers M0, and the other half portions on the side away from the sense amplifiers SA are formed by the second metal interconnection layers M1. Also, half portions of the odd-numbered bit lines BLO on the side of the sense amplifiers SA are formed by the second metal interconnection layers M1, and the other half portions on the side away from the sense amplifiers SA are formed by the first metal interconnection layers M0. In the even-numbered bit lines BLE and odd-numbered bit lines BLO, the first metal interconnection layers M0 and second metal interconnection layers M1 are connected by contacts (not shown).

Note that the combination of the metal interconnection layers is not limited to M0 and M1 and may also be M1 and M2.

In the 12th embodiment, both the even-numbered bit lines BLE and odd-numbered bit lines BLO are formed by the first metal interconnection layers M0 and second metal interconnection layers M1. Therefore, the characteristics (wiring resistances and inter-line capacitances) of the odd-numbered bit lines BLE and odd-numbered bit lines BLO connected to the sense amplifiers SA can almost be matched. This makes it possible to almost equalize the signal transmission delays of the even-numbered bit lines BLE and odd-numbered bit lines BLO, and increase the read and write speeds of the NAND flash memory.

### (13th Embodiment)

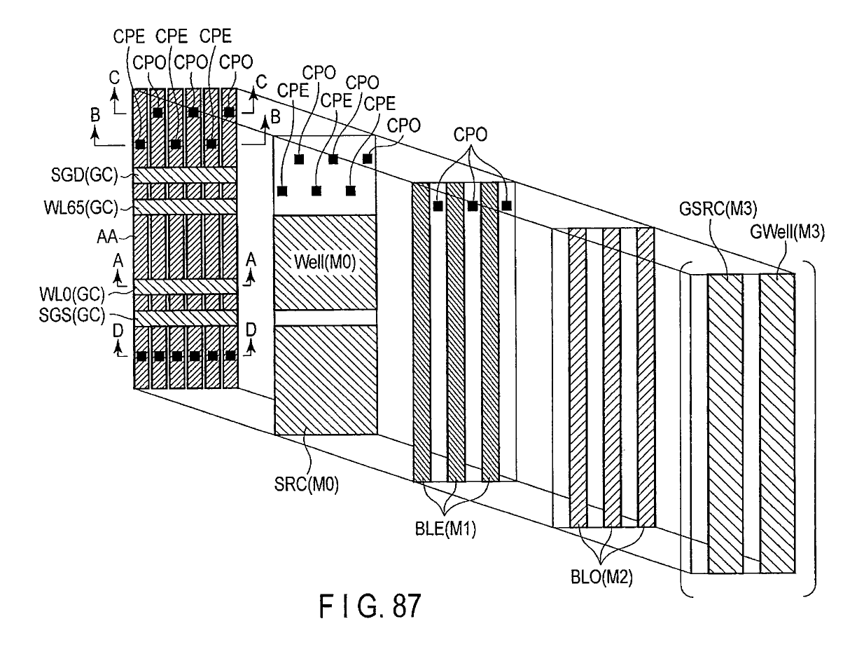

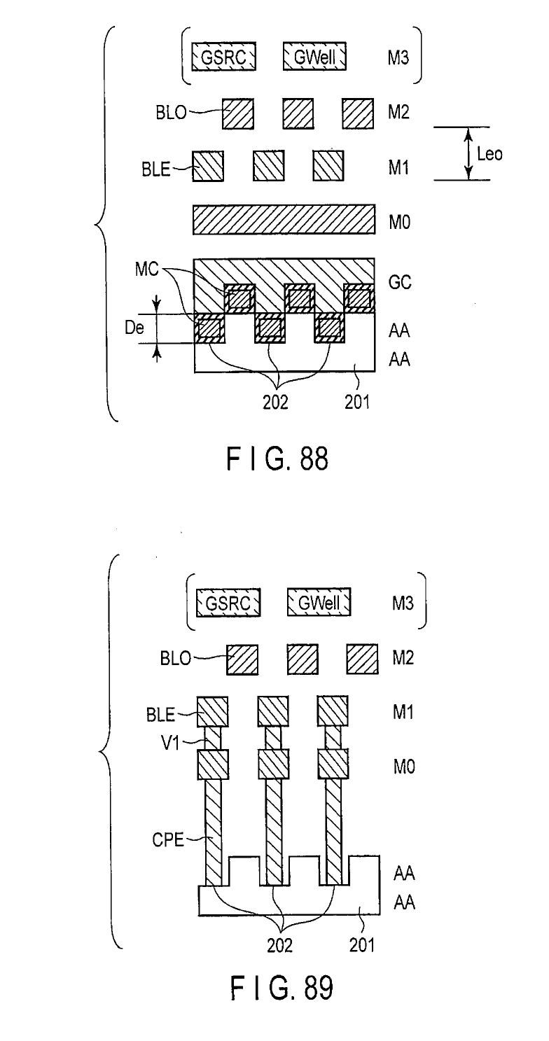

FIGS. 87, 88, 89, 90, 91, and 92 show the 13th embodiment. FIGS. 88, 89, 90, 91, and 92 are respectively sectional views taken along lines A-A, B-B, C-C, and D-D in FIG. 87.

In the above-mentioned 12th embodiment, the characteristics of the even-numbered bit lines BLE and odd-numbered bit lines BLO can almost be matched by forming the even-numbered bit lines BLE and odd-numbered bit lines BLO by the second metal interconnection layers M1 and third metal interconnection layers M2.

By contrast, in the 13th embodiment, the integration degree of a memory is increased by forming memory cells in element isolation trenches between memory cells, although element isolation films (STI) are conventionally formed in the element isolation trenches between memory cells. It is also possible to equalize the average lengths of contact plugs CPE and CPO by making the distance from a semiconductor substrate to even-numbered bit lines BLE equal to that from the semiconductor substrate to odd-numbered bit lines BLO.

That is, as shown in FIGS. 87 and 88, the even-numbered bit lines BLE are formed by, e.g., second metal interconnection layers M1, and the odd-numbered bit lines BLO are formed by, e.g., third metal interconnection layers M2. A global source line GSRC and global interconnection GWell are formed by fourth metal interconnection layers M3.

Trenches 202 are formed in the surface of a semiconductor substrate 201 in one-to-one correspondence with, e.g., the even-numbered bit lines BLE. The trenches 202 are formed along element isolation films (STI) (not shown). A depth De of the trenches 202 is made almost equal to a distance Leo in the direction of height between the even-numbered bit lines BLE and odd-numbered bit lines BLO. The trenches 202 and the surface of the semiconductor substrate 201 are used as active areas AA, and memory cells MC are formed on the active areas AA. Referring to FIG. 88, the memory cells MC are simplified.

As shown in FIG. 89, the even-numbered bit lines BLE are connected to memory cells formed in the trenches 202 via vias V1, first metal interconnection layers M0, and contact plugs CPE.

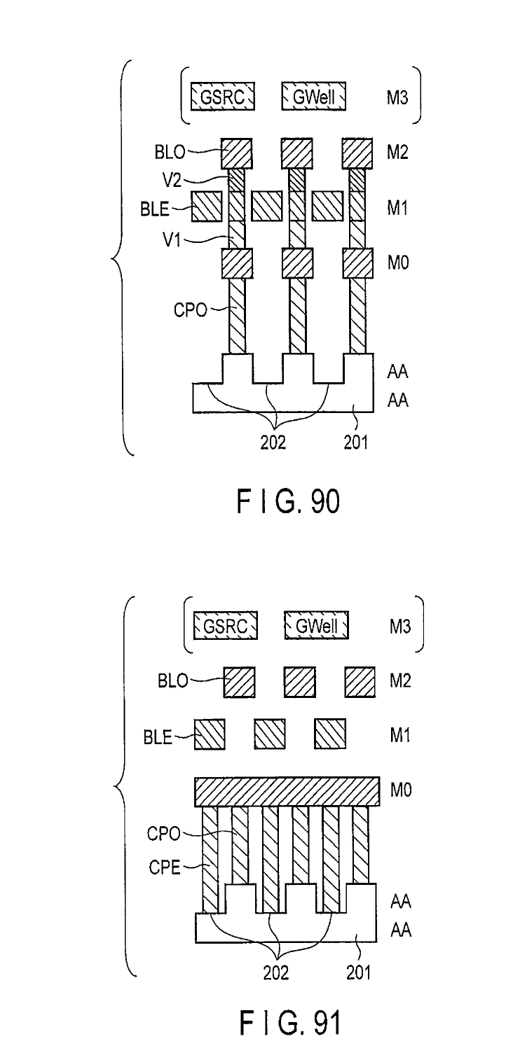

Also, as shown in FIG. 90, the odd-numbered bit lines BLO are connected to memory cells formed on the surface of the semiconductor substrate 201 via vias V2, the second metal interconnection layers M1, vias V1, the first metal interconnection layers M0, and contact plugs CPO.

FIG. 91 shows the contact between a source line SRC formed by the first metal interconnection layer M0 and a source.

In the 13th embodiment described above, the bit lines BLE of the first layer are formed by the second metal interconnection layers M1, the bit lines BLO of the second layer are formed by the third metal interconnection layers M2, the trenches 202 are formed in those portions of the semiconductor substrate 201, which correspond to the bit lines BLE of the first layer, memory cells are formed in the trenches 202, and memory cells are formed on those portions of the surface of the semiconductor substrate 201, which correspond to the bit lines BLO of the second layer. This makes it possible to, e.g., almost double the integration degree. It is also possible to make the distance between the bit lines BLE of the first layer and the memory cell almost equal to that between the bit lines BLO of the second layer and the memory cells. This makes it possible to almost equalize the signal transmission delays of the even-numbered bit lines BLE and odd-numbered bit lines BLO, and increase the read and write speeds of the NAND flash memory.

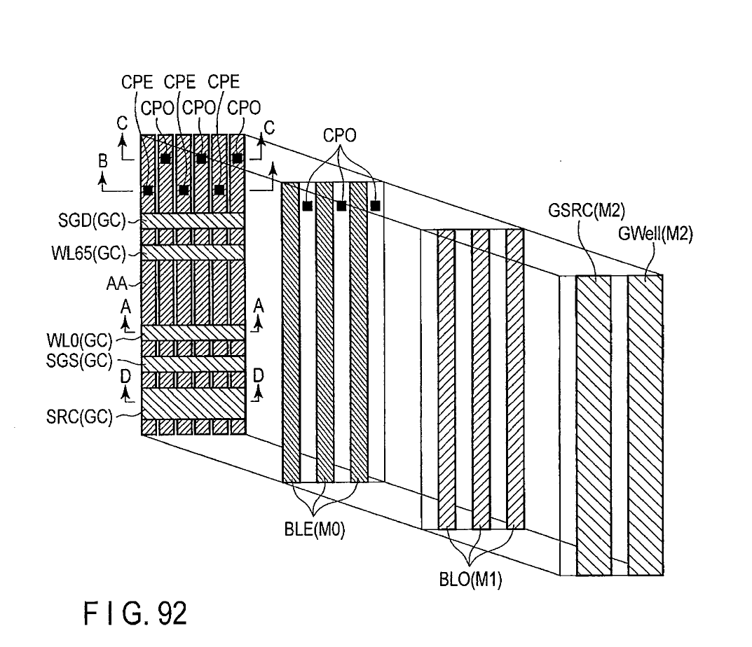

(14th Embodiment) FIGS. 92, 93, 94, 95, and 96 show the 14th embodiment. The 14th embodiment is a modification of the 13th embodiment, and the same reference numerals as in the 13th embodiment denote the same parts.

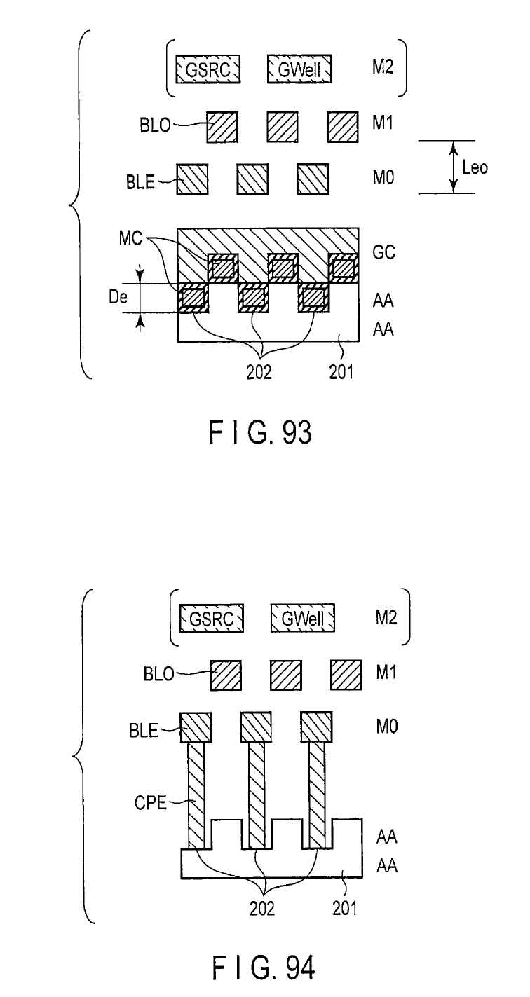

In the 14th embodiment as shown in FIGS. 92 and 93, a source line SRC is formed by, e.g., a polysilicon layer similar to word lines of memory cells, bit lines BLE of the first layer are formed by first metal interconnection layers M0, and bit lines BLO of the second layer are formed by second metal interconnection layers M1. A global source line GSRC and global interconnection GWell are formed by third metal interconnection layers M2.

Trenches 202 are formed in the surface of a semiconductor substrate 201 in one-to-one correspondence with, e.g., the bit lines BLE of the first layer. The trenches 202 are formed along element isolation insulating films (STI) (not shown). A depth De of the trenches 202 can also be made almost equal to a distance Leo in the direction of height between the bit lines BLE of the first layer and the bit lines BLO of the second layer. The trenches 202 and the surface of the semiconductor substrate 201 are used as active areas AA, and memory cells MC are formed on the active areas AA. The memory cells MC are simplified in FIG. 93.

As shown in FIG. 94, the bit lines BLE of the first layer are connected to memory cells formed in the trenches 202 via contact plugs CPE.

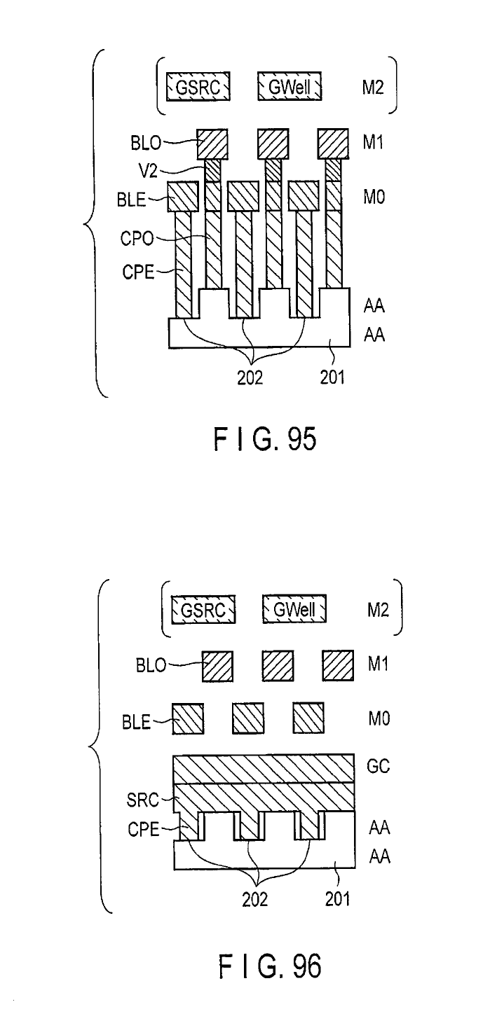

Also, as shown in FIG. 95, the bit lines BLO of the second layer are connected to memory cells formed on the surface of the semiconductor substrate 201 via vias V2, the second metal interconnection layers M1, and contact plugs CPO.

FIG. 96 shows the contact between the source line SRC and a source.

In the above-mentioned 14th embodiment, the bit lines BLE of the first layer are formed by the first metal interconnection layers M0, the bit lines BLO of the second layer are formed by the second metal interconnection layers M1, the trenches 202 are formed in those portions of the semiconductor substrate 201, which correspond to the bit lines BLE of the first layer, memory cells are formed in the trenches 202, and memory cells are formed on those portions of the surface of the semiconductor substrate 201, which correspond to the bit lines BLO of the second layer. Accordingly, the degree of integration can be increased. Also, when the distance between the bit lines BLE of the first layer and the memory cells is made almost equal to that between the bit lines BLO of the second layer and the memory cells, it is possible to almost equalize the signal transmission delays of the bit lines BLE of the first layer and the bit lines BLO of the second layer, and increase the read and write speeds of the NAND flash memory.

### (15th Embodiment)

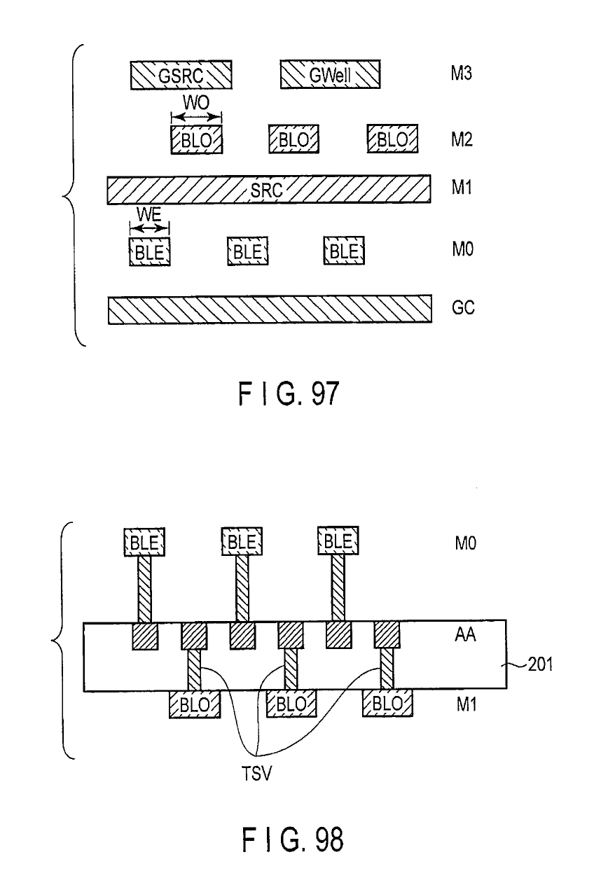

FIG. 97 shows the 15th embodiment. The 15th embodiment is a modification of the 10th embodiment shown in FIGS. 68 and 69.

In the 15th embodiment as shown in FIG. 97, bit lines BLE of the first layer are formed by first metal interconnection layers M0, and bit lines BLO of the second layer are formed by third metal interconnection layers M2. A source line SRC is formed by a second metal interconnection layer M1. The bit lines BLE of the first layer are connected to memory cells formed in active areas AA via contact plugs (not shown). The bit lines BLO of the second layer are connected to memory cells formed in active areas AA via vias or contact plugs formed through the second metal interconnection layers M1.

In the above-mentioned 15th embodiment, the source line SRC formed by the second metal interconnection layer M1 exists between the bit lines BLE of the first layer and the bit lines BLO of the second layer. Accordingly, the coupling capacitance between the bit lines BLE of the first layer and the bit lines BLO of the second layer can be reduced. This makes it possible to reduce the signal transmission delays of the bit lines BLE of the first layer and the bit lines BLO of the second layer, and increase the read and write speed of the NAND flash memory.

### (16th Embodiment)

In each of the above embodiments, the even-numbered bit lines BLE and odd-numbered bit lines BLO are arranged on one surface of the semiconductor substrate. By contrast, in the 16th embodiment, bit lines are arranged on the upper and lower surfaces of a semiconductor substrate.

That is, as shown in FIG. 98, even-numbered bit lines BLE are formed on the upper surface of a semiconductor substrate 201, and odd-numbered bit lines BLO are formed on the lower surface of the semiconductor substrate 201. The even-numbered bit lines BLE are formed by, e.g., first metal interconnection layers M0, and the odd-numbered bit lines BLO are formed by, e.g., second metal interconnection layers M1. The even-numbered bit lines BLE are connected to memory cells (not shown) formed in active areas AA of the surface of the semiconductor substrate 201 by, e.g., contact plugs CPE. The odd-numbered bit lines BLO are connected to memory cells (not shown) formed in active areas AA of the surface of the semiconductor substrate 201 via, e.g., TSVs (Through Silicon Vias).

In the above-mentioned 16th embodiment, the even-numbered bit lines BLE are formed on the upper surface of the semiconductor substrate 201, and the odd-numbered bit lines BLO are formed on the lower surface of the semiconductor substrate 201. Therefore, the coupling capacitance between the even-numbered bit lines BLE and the odd-numbered bit lines BLO can be reduced. This makes it possible to reduce the signal transmission delays of the even-numbered bit lines BLE and the odd-numbered bit lines BLO, and increase the read and write speed of the NAND flash memory.

Note that not only the bit lines but also the memory cells or circuits may also be formed on the lower surface of the semiconductor substrate 201.

### (17th Embodiment)

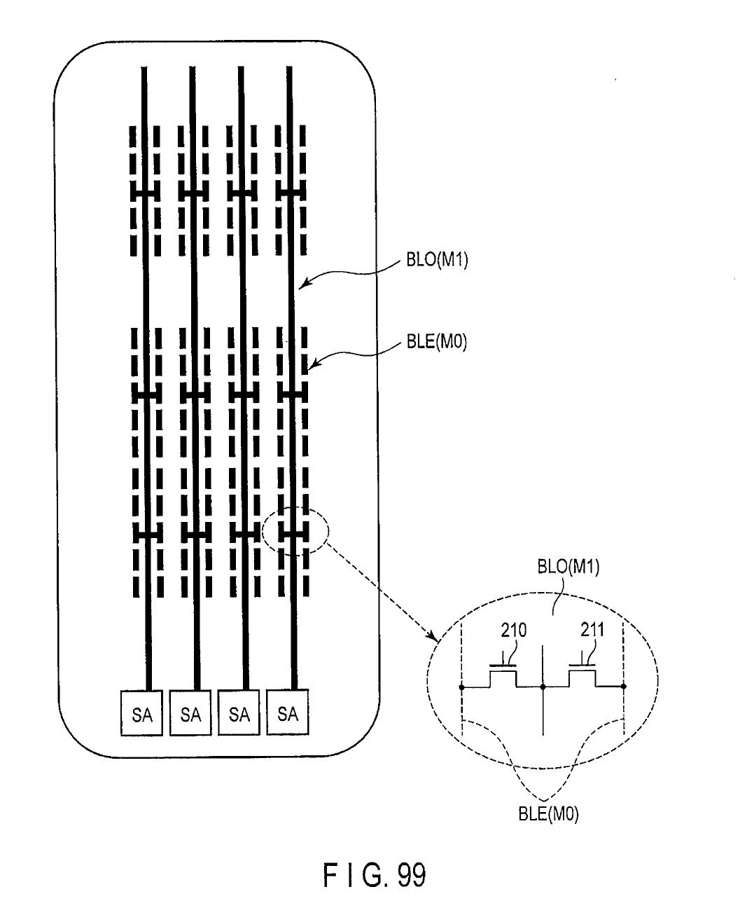

FIG. 99 shows the 17th embodiment.

In each of the above embodiments, the space between the bit lines BLE of the first layer and that between the bit lines BLO of the second layer are set equal.

By contrast, in the 17th embodiment as shown in FIG. 99, the space between bit lines BLO of the second layer is set, e.g., twice that between bit lines BLE of the first layer. That is, the bit lines BLO of the second layer are arranged between the bit lines BLE of the first layer. The bit lines BLE of the first layer and the bit lines BLO of the second layer are connected to memory cells via contact plugs (not shown).

Note that the space between the bit lines BLO of the second layer is not limited to twice but can be n times (n is a natural number of 2 or more) the space between the bit lines BLE of the first layer.

Also, the bit lines BLO of the second layer are connected to sense amplifiers SA (data storage circuits), and the bit lines BLE of the first layer are connected to the sense amplifiers SA via the bit lines BLO of the second layer. That is, transistors 210 and 211 are connected between the bit lines BLE of the first layer and the bit lines BLO of the second layer. By selecting one of the transistors 210 and 211, one of a pair of bit lines BLE of the first layer is connected to the sense amplifier SA via the bit line BLO of the second layer. The transistors 210 and 211 may be formed in wells in which memory cells are formed.

In the above-mentioned arrangement, one of a pair of bit lines BLE of the first layer can be connected to the sense amplifier SA via the bit line BLO of the second layer by selecting one of the transistors 210 and 211. Accordingly, a write or read operation can be performed for a memory cell connected to the selected bit line BLE of the first layer. On the other hand, On the other hand, when the write operation is performed, the voltage to which the memory cell can not write is supplied to the memory cell connected to the unselected bit line BLE of the first layer, from the source line. Moreover, when the read operation is performed, a specific voltage can be supplied to the memory cell connected to the unselected bit line BLE of the first layer, from the source line. By doing so, the bit line under the read operation can be shielded.

Furthermore, a write or read operation can be performed for a memory cell connected to the bit line BLO of the second layer by selecting neither of the transistors 210 and 211 in the unselected block.

In the above-mentioned 17th embodiment, the space between the bit lines BLO of the second layer connected to the sense amplifiers SA may be set twice or more that between the bit lines BLE of the first layer. This makes it possible to reduce the coupling capacitance between the bit lines BLO of the second layer, and reduce the signal transmission delays. Accordingly, the read and write speeds of the NAND flash memory can be increased.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A semiconductor memory device comprising:
a plurality of memory cells arranged in a matrix;
a plurality of word lines configured to select the plurality of memory cells; and
a plurality of bit lines configured to select the plurality of memory cells,
wherein first bit lines and second bit lines included in the plurality of bit lines are arranged in different layers.

2. The device according to claim 1, wherein the first bit lines are arranged in a first interconnection layer, and the second bit lines are arranged in a second interconnection layer.

3. The device according to claim 2, further comprising:
a first data storage circuit connected to a pair of first bit lines arranged in the first interconnection layer; and
a second data storage circuit connected to a pair of second bit lines arranged in the second interconnection layer.

4. The device according to claim 2, wherein upper surfaces of the first bit lines arranged in the first interconnection layer are substantially leveled with lower surfaces of the second bit lines arranged in the second interconnection layer.

5. The device according to claim 2, wherein upper surfaces of the first bit lines arranged in the first interconnection layer are higher than lower surfaces of the second bit lines arranged in the second interconnection layer.

6. A semiconductor memory device comprising:
a plurality of memory cells arranged in a matrix;
a plurality of word lines configured to select the plurality of memory cells; and
a plurality of bit lines configured to select the plurality of memory cells,
wherein among a first bit line, a second bit line, a third bit line, and a fourth bit line adjacent to each other in the plurality of bit lines, the first bit line and the third bit line are formed in a first interconnection layer, and the second bit line and the fourth bit line are formed in a second interconnection layer.

7. The device according to claim 6, wherein the first bit line and the second bit line are simultaneously set in a selected state, and the third bit line and the fourth bit line are simultaneously set in an unselected state.

8. The device according to claim 6, further comprising:
a first data storage circuit connected to the first bit line and the third bit line; and
a second data storage circuit connected to the second bit line and the fourth bit line.

9. The device according to claim 6, wherein upper surfaces of the first bit line and the third bit line arranged in the first interconnection layer are substantially leveled with lower surfaces of the second bit line and the fourth bit line arranged in the second interconnection layer.

10. The device according to claim 6, wherein upper surfaces of the first bit line and the third bit line arranged in the first interconnection layer are higher than lower surfaces of the second bit line and the fourth bit line arranged in the second interconnection layer.

11. A semiconductor memory device manufacturing method comprising:
forming, on a first insulating film, a first film having a width larger than a width of a bit line to be formed;
forming a second film by slimming the first film into the width of the bit line to be formed;
forming second insulating films on sidewalls of the second film;
forming a first trench having a first depth in the first insulating film by using the second film and the second insulating films as masks;
forming a first bit line in the first trench by using a first conductive material;
filling the first trench with a third insulating film;
removing the second film;
forming a second trench shallower than the first depth in the first insulating film by using the second insulating films as masks; and
forming a second bit line in the second trench by using a second conductive material.

12. The method according to claim 11, wherein
when filling the first trench with the third insulating film, the third insulating film is buried in the first trench except for a via formation region, and
when forming the second bit line, a via is formed in the region by using the second conductive material.

13. The device according to claim 1, wherein a width of the first bit lines and the second bit lines is n times (n is a natural number of no less than 2) that of active areas forming the memory cells.

14. The device according to claim 13, wherein a width of at least some of the first bit lines is smaller than that of the second bit lines, and a film thickness of the first bit lines is larger than that of the second bit lines.

15. The device according to claim 14, wherein a pitch of the first bit lines and the second bit lines is n times (n is a natural number of not less than 2) that of the active areas forming the memory cells.

16. The device according to claim 6, wherein a width of the first interconnection layers and the second interconnection layers is n times (n is a natural number of no less than 2) that of active areas forming the memory cells.

17. The device according to claim 16, wherein a width of at least some of the first interconnection layers is smaller than that of the second interconnection layers, and a film thickness of the first interconnection layers is larger than that of the second interconnection layers.

18. The device according to claim 17, wherein a pitch of the first interconnection layers and the second interconnection layers is n times (n is a natural number of not less than 2) that of the active areas forming the memory cells.
